(19) United States
(12) Patent Application Publication
(10) Pub. No.: US 2024/0423027 A1
(43) Pub. Date: Dec. 19, 2024

(54) DISPLAY DEVICE AND METHOD FOR MANUFACTURING DISPLAY DEVICE

(71) Applicant: Semiconductor Energy Laboratory Co., Ltd., Atsugi-shi, Kanagawa-ken (JP)

(72) Inventors: Daiki NAKAMURA, Atsugi (JP); Nozomu SUGISAWA, Isehara (JP); Masahiro KATAYAMA, Isehara (JP); Naoto GOTO, Tochigi (JP); Kenichi OKAZAKI, Atsugi (JP)

(21) Appl. No.: 18/706,407

(22) PCT Filed: Nov. 7, 2022
(86) PCT No.: PCT/IB2022/060668

§ 371 Date: May 1, 2024

(30) Foreign Application Priority Data
Nov. 18, 2021 (JP) 2021-188125

(51) Int. Cl. H10K 59/122; H10K 59/12; H10K 59/38; H10K 71/60; H10K 102/00

(52) U.S. Cl. CPC H10K 59/122; H10K 59/1201; H10K 59/38; H10K 71/60; H10K 2102/351

(57) ABSTRACT

A display device with high display quality is provided. The display device includes a first organic insulating layer, a first inorganic insulating layer and a second inorganic insulating layer over the first organic insulating layer, a first light-emitting element, a second light-emitting element, and a second organic insulating layer. The first light-emitting element includes a first pixel electrode over the first inorganic insulating layer, a first EL layer over the first pixel electrode, and a common electrode over the first EL layer. The second light-emitting element includes a second pixel electrode over the second inorganic insulating layer, a second EL layer over the second pixel electrode, and the common electrode over the second EL layer. The second organic insulating layer is provided between the first EL layer and the second EL layer, and the common electrode is provided over the second organic insulating layer. The first organic insulating layer includes a depressed portion in a region overlapping with the second organic insulating layer, the first inorganic insulating layer includes a first projecting portion overlapping with the depressed portion, and the second inorganic insulating layer includes a second projecting portion overlapping with the depressed portion.

### TECHNICAL FIELD

One embodiment of the present invention relates to a display device, a display module, and an electronic device. One embodiment of the present invention relates to a method for manufacturing a display device.

Note that one embodiment of the present invention is not limited to the above technical field. Examples of the technical field of one embodiment of the present invention include a semiconductor device, a display device, a light-emitting apparatus, a power storage device, a memory device, an electronic device, a lighting device, an input device (e.g., a touch sensor), an input/output device (e.g., a touch panel), a method for driving any of them, and a method for manufacturing any of them.

### BACKGROUND ART

Display devices have been expected to be applied to a variety of uses. Usage examples of large-sized display devices include a television device for home use (also referred to as TV or television receiver), digital signage, and a PID (Public Information Display). In addition, a smartphone and a tablet terminal each including a touch panel, and the like, are being developed as portable information terminals.

Light-emitting apparatuses including light-emitting elements (also referred to as light-emitting devices) have been developed as display devices, for example. In particular, light-emitting elements (also referred to as EL elements or EL devices)utilizing an electroluminescence (EL) phenomenon have features such as ease of reduction in thickness and weight, high-speed response to an input signal, and driving with a direct-constant voltage source, and have been applied to display devices. For example, Patent Document 1 discloses a flexible light-emitting apparatus including an organic EL element (also referred to as an organic EL device).

### REFERENCE

### Patent Document

[Patent Document 1] Japanese Published Patent Application No. 2014-197522

### SUMMARY OF THE INVENTION

### Problems to be Solved by the Invention

For example, a coloring layer is provided to overlap with a light-emitting element emitting white light, so that a display device performing color display can be provided. In a display device provided with a coloring layer to perform color display, all light-emitting elements are allowed to emit light of the same color, which enables the light-emitting elements to share a light-emitting layer of a continuous film. However, in the case where the light-emitting layer is shared by the light-emitting elements, leakage current is generated between the light-emitting elements in some cases. The leakage current causes crosstalk which is a phenomenon in which adjacent light-emitting elements unintentionally emit light, in some cases. By occurrence of crosstalk, the display quality of the display device may be degraded.

An object of one embodiment of the present invention is to provide a display device in which a light-emitting layer is divided between light-emitting elements. Another object of one embodiment of the present invention is to provide a display device in which occurrence of crosstalk is suppressed. Another object of one embodiment of the present invention is to provide a display device with high display quality. Another object of one embodiment of the present invention is to provide a high-resolution display device. Another object of one embodiment of the present invention is to provide a high-definition display device. Another object of one embodiment of the present invention is to provide a highly reliable display device. Another object of one embodiment of the present invention is to provide a novel display device.

Another object of one embodiment of the present invention is to provide a method for manufacturing a display device in which a light-emitting layer is divided between light-emitting elements. Another object of one embodiment of the present invention is to provide a method for manufacturing a display device with a small number of processing steps. Another object of one embodiment of the present invention is to provide a method for manufacturing a display device in which occurrence of crosstalk is suppressed. Another object of one embodiment of the present invention is to provide a method for manufacturing a display device with high display quality. Another object of one embodiment of the present invention is to provide a method for manufacturing a high-resolution display device. Another object of one embodiment of the present invention is to provide a method for manufacturing a high-definition display device. Another object of one embodiment of the present invention is to provide a method for manufacturing a highly reliable display device. Another object of one embodiment of the present invention is to provide a method for manufacturing a novel display device.

Note that the description of these objects does not preclude the existence of other objects. One embodiment of the present invention does not need to achieve all of these objects. Other objects can be derived from the description of the specification, the drawings, and the claims.

### Means for Solving the Problems

One embodiment of the present invention is a display device including a first organic insulating layer, a first inorganic insulating layer and a second inorganic insulating layer over the first organic insulating layer, a first light-emitting element, a second light-emitting element, and a second organic insulating layer. The first light-emitting element includes a first pixel electrode over the first inorganic insulating layer, a first EL layer over the first pixel electrode, and a common electrode over the first EL layer. The second light-emitting element includes a second pixel electrode over the second inorganic insulating layer, a second EL layer over the second pixel electrode, and the common electrode over the second EL layer. The second organic insulating layer is provided between the first EL layer and the second EL layer. The common electrode is provided over the second organic insulating layer. The first organic insulating layer has a depressed portion in a region overlapping with the second organic insulating layer. The first inorganic insulating layer has a first projecting portion overlapping with the depressed portion. The second inorganic insulating layer has a second projecting portion overlapping with the depressed portion.

Furthermore, in the above embodiment, a ratio of a width of the first projecting portion to a thickness of the first EL layer may be greater than or equal to 0.3, and a ratio of a width of the second projecting portion to a thickness of the second EL layer may be greater than or equal to 0.3.

Furthermore, in the above embodiment, the first EL layer may include the same material as the second EL layer, and the first EL layer may be separated from the second EL layer.

Furthermore, in the above embodiment, the organic layer may be included, the organic layer may be provided in the depressed portion, and the second organic insulating layer may be provided over the organic layer.

Furthermore, in the above embodiment, the organic layer may be separated from the first EL layer and the second EL layer.

Furthermore, in the above embodiment, the first EL layer may cover at least a part of a side surface of the first pixel electrode, and the second EL layer may cover at least a part of a side surface of the second pixel electrode.

Furthermore, in the above embodiment, a third inorganic insulating layer may be included, and the third inorganic insulating layer may be provided between the second organic insulating layer and the first organic insulating layer, the first EL layer, and the second EL layer.

Furthermore, in the above embodiment, a common layer may be included, and the common layer may be provided between the common electrode and the first EL layer, the second EL layer, and the second organic insulating layer.

Furthermore, in the above embodiment, a first coloring layer and a second coloring layer may be included, the first coloring layer may have a region overlapping with the first light-emitting element, the second coloring layer may have a region overlapping with the second light-emitting element, and a color of light transmitted through the first coloring layer may be different from a color of light transmitted through the second coloring layer.

Another embodiment of the present invention is a method for manufacturing a display device including steps of forming a first organic insulating layer, an inorganic insulating film, and a conductive film in this order; removing a part of the conductive film, so that a first pixel electrode and a second pixel electrode are formed; removing a part of the inorganic insulating film, so that a first inorganic insulating layer below the first pixel electrode and a second inorganic insulating layer below the second pixel electrode are formed; forming a depressed portion in a region which is of the first organic insulating layer and is between the first inorganic insulating layer and the second inorganic insulating layer in a plan view, so that a first projecting portion overlapping with the depressed portion is formed in the first inorganic insulating layer and a second projecting portion overlapping with the depressed portion is formed in the second inorganic insulating layer; forming a first EL layer over the first pixel electrode and a second EL layer over the second pixel electrode; forming a second organic insulating layer between the first EL layer and the second EL layer to have a region overlapping with the depressed portion; and forming a common electrode over the first EL layer, the second EL layer, and the second organic insulating layer.

Furthermore, in the above embodiment, a ratio of a width of the first projecting portion to a thickness of the first EL layer may be greater than or equal to 0.3, and a ratio of a width of the second projecting portion to a thickness of the second EL layer may be greater than or equal to 0.3.

Furthermore, in the above embodiment, the second EL layer may be separated from the first EL layer, and the second EL layer may include the same material as the first EL layer.

Furthermore, in the above embodiment, an organic layer may be formed in the depressed portion at the time of forming the first EL layer and the second EL layer, and the second organic insulating layer may be formed over the organic layer.

Furthermore, in the above embodiment, the organic layer may be separated from the first EL layer and the second EL layer.

Furthermore, in the above embodiment, the depressed portion may be formed by ashing.

Furthermore, in the above embodiment, the second organic insulating layer may be formed by a photolithography method.

Furthermore, in the above embodiment, the first EL layer may be formed to cover at least a part of a side surface of the first pixel electrode, and the second EL layer may be formed to cover at least a part of a side surface of the second pixel electrode.

Furthermore, in the above embodiment, after formation of the second organic insulating layer, a common layer may be formed over the first EL layer after the second organic insulating layer is formed, the second EL layer, and the second organic insulating layer, and the common electrode may be formed over the common layer.

Furthermore, in the above embodiment, after formation of the common electrode, a first coloring layer including a region overlapping with the first pixel electrode and the first EL layer and a second coloring layer including a region overlapping with the second pixel electrode and the second EL layer may be formed after the common electrode layer is formed, and a color of light transmitted through the first coloring layer may be different from a color of light transmitted through the second coloring layer.

### Effect of the Invention

According to one embodiment of the present invention, a display device in which a light-emitting layer is divided between light-emitting elements can be provided. Furthermore, according to one embodiment of the present invention, a display device in which occurrence of crosstalk is suppressed can be provided. Furthermore, according to one embodiment of the present invention, a display device with high display quality can be provided. Furthermore, according to one embodiment of the present invention, a high-resolution display device can be provided. Furthermore, according to one embodiment of the present invention, a high-definition display device can be provided. Furthermore, according to one embodiment of the present invention, a highly reliable display device can be provided. Furthermore, according to one embodiment of the present invention, a novel display device can be provided.

Furthermore, according to one embodiment of the present invention, a method for manufacturing a display device in which a light-emitting layer is divided between light-emitting elements can be provided. Furthermore, according to one embodiment of the present invention, a method for manufacturing a display device with a small number of processing steps can be provided. Furthermore, according to one embodiment of the present invention, a method for manufacturing a display device in which occurrence of crosstalk is suppressed can be provided. Furthermore, according to one embodiment of the present invention, a method for manufacturing a display device with high display quality can be provided. Furthermore, according to one embodiment of the present invention, a method for manufacturing a high-resolution display device can be provided. Furthermore, according to one embodiment of the present invention, a method for manufacturing a high-definition display device can be provided. Furthermore, according to one embodiment of the present invention, a method for manufacturing a highly reliable display device can be provided. Furthermore, according to one embodiment of the present invention, a method for manufacturing a novel display device can be provided.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIG. 1A is a plan view illustrating an example of a display device. FIG. 1B is a cross-sectional view illustrating an example of the display device.

FIG. 2A and FIG. 2B are cross-sectional views each illustrating an example of a display device.

FIG. 3A and FIG. 3B are cross-sectional views each illustrating an example of a display device.

FIG. 4A and FIG. 4B are cross-sectional views each illustrating an example of a display device.

FIG. 5A and FIG. 5B are cross-sectional views illustrating an example of a display device.

FIG. 6A and FIG. 6B are cross-sectional views illustrating an example of a display device.

FIG. 7A and FIG. 7B are cross-sectional views each illustrating an example of a display device.

FIG. 8A and FIG. 8B are cross-sectional views each illustrating an example of a display device.

FIG. 9A and FIG. 9B are cross-sectional views illustrating an example of a method for manufacturing a display device.

FIG. 10A1, FIG. 10A2, and FIG. 10B are cross-sectional views illustrating an example of a method for manufacturing a display device.

FIG. 11A and FIG. 11B are cross-sectional views illustrating an example of a method for manufacturing a display device.

FIG. 12A to FIG. 12C are cross-sectional views illustrating an example of a method for manufacturing a display device.

FIG. 13A1, FIG. 13A2, and FIG. 13B are cross-sectional views illustrating an example of a method for manufacturing a display device.

FIG. 14A1, FIG. 14A2, and FIG. 14B are cross-sectional views illustrating an example of a method for manufacturing a display device.

FIG. 15A to FIG. 15G are views each illustrating an example of a pixel.

FIG. 16A to FIG. 16K are views each illustrating an example of a pixel.

FIG. 17 is a perspective view illustrating an example of a display device.

FIG. 18A is a cross-sectional view illustrating an example of a display device. FIG. 18B and FIG. 18C are cross-sectional views illustrating an example of a transistor.

FIG. 19 is a cross-sectional view illustrating an example of a display device.

FIG. 20A to FIG. 20F are diagrams each illustrating a structure example of a light-emitting element.

FIG. 21A to FIG. 21C are diagrams each illustrating a structure example of a light-emitting element.

FIG. 22A to FIG. 22F are diagrams illustrating examples of electronic devices.

FIG. 23A to FIG. 23G are diagrams illustrating examples of electronic devices.

FIG. 24 is a cross-sectional view illustrating a structure of a sample fabricated in Example.

FIG. 25A and FIG. 25B are cross-sectional STEM images of a sample fabricated in Example.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that in structures of the invention described below, the same reference numerals are commonly used for the same portions or portions having similar functions in different drawings, and a repeated description thereof is omitted. The same hatching pattern is used for portions having similar functions, and the portions are not especially denoted by reference numerals in some cases.

The position, size, range, or the like of each component illustrated in drawings does not represent the actual position, size, range, or the like in some cases for easy understanding. Therefore, the disclosed invention is not necessarily limited to the position, size, range, or the like disclosed in drawings.

In this specification and the like, terms for describing positioning, such as “over,” “under,” “above,” and “below,” are sometimes used for convenience to describe the positional relation between components with reference to drawings. The positional relationship between components is changed as appropriate in accordance with a direction in which each component is described. Thus, the positional relation is not limited to the terms described in this specification and the like, and can be described with another term as appropriate depending on the situation. For example, the expression “an insulating layer positioned over a conductive layer” can be replaced with the expression “an insulating layer positioned under a conductive layer” when the direction of a drawing illustrating these components is rotated by 180°.

Note that the term “film” and the term “layer” can be interchanged with each other depending on the case or circumstances. For example, the term “conductive layer” can be changed into the term “conductive film” in some cases. For another example, the term “insulating film” can be changed into the term “insulating layer” in some cases.

### Embodiment 1

In this embodiment, a display device of one embodiment of the present invention will be described with reference to drawings.

In a display portion included in the display device of one embodiment of the present invention, pixels are arranged in a matrix, and each pixel includes a plurality of subpixels. Each subpixel includes a light-emitting element and a coloring layer. The light-emitting element includes an EL layer between a pair of electrodes. In this specification and the like, one of the pair of electrodes may be referred to as a pixel electrode and the other may be referred to as a common electrode.

The EL layer includes at least a light-emitting layer. Examples of layers included in the EL layer include a light-emitting layer, a carrier-injection layer, a carrier-transport layer, and a carrier-blocking layer. Here, a layer other than the light-emitting layer among the layers included in the EL layer is referred to as a functional layer.

In this specification and the like, a hole or an electron is sometimes referred to as a “carrier”. Specifically, a hole-injection layer or an electron-injection layer may be referred to as a “carrier-injection layer”, a hole-transport layer or an electron-transport layer may be referred to as a “carrier-transport layer”, and a hole-blocking layer or an electron-blocking layer may be referred to as a “carrier-blocking layer”. Note that the above-described carrier-injection layer, carrier-transport layer, and carrier-blocking layer cannot be distinguished from each other in some cases by the cross-sectional shape, the characteristics, or the like. Furthermore, one layer may have two or three functions of the carrier-injection layer, the carrier-transport layer, and the carrier-blocking layer in some cases.

The display device of one embodiment of the present invention can have a structure where a plurality of subpixels included in one pixel include light-emitting elements emitting light of the same color, for example, white light. In addition, coloring layers transmitting light of different colors are provided for the respective subpixels in regions overlapping with the light-emitting elements. Thus, the display device of one embodiment of the present invention can perform full-color display.

When a plurality of subpixels included in one pixel include light-emitting elements emitting light of the same color, an EL layer can be common to the light-emitting elements in the plurality of subpixels. Thus, the plurality of subpixels can share a continuous film. However, when the plurality of subpixels share one continuous film, leakage current may be generated between the subpixels. This might cause crosstalk between adjacent subpixels and accordingly degrade display quality of the display device, for example.

The display device of one embodiment of the present invention includes an island-shaped EL layer for each light-emitting element. When the EL layers are separated between the light-emitting elements, occurrence of crosstalk between adjacent subpixels can be inhibited. Therefore, the display device of one embodiment of the present invention can have high display quality.

In this specification and the like, the term “island shape” refers to a state where two or more layers formed using the same material in the same step are physically separated from each other. For example, the term “island-shaped EL layer” refers to a state where the EL layer and its adjacent EL layer are physically separated from each other.

For example, an island-shaped EL layer can be formed by a vacuum evaporation method using a metal mask. However, this method causes a deviation from the designed shape and position of an island-shaped EL layer due to various influences such as a low accuracy of the metal mask, positional deviation between the metal mask and a substrate, a warp of the metal mask, and expansion of the outline of a formed film, for example. Thus, it is difficult to increase the resolution and increase the aperture ratio of the display device. In addition, the outline of the layer might blur during evaporation, so that the thickness of an end portion might be reduced. That is, the thickness of the island-shaped EL layer formed using a metal mask may vary. In the case of manufacturing a display device with a large size, high definition, or high resolution, the manufacturing yield might be reduced because of low dimensional accuracy of the metal mask and deformation due to heat or the like.

Thus, when the display device of one embodiment of the present invention is manufactured, an island-shaped EL layer is formed without using a shadow mask such as a metal mask. Specifically, first, an organic insulating layer over a substrate, an inorganic insulating layer over the organic insulating layer, and a conductive layer over the inorganic insulating layer are formed in this order. Next, part of the conductive layer is removed to form a plurality of pixel electrodes. Then, a region of the inorganic insulating layer that does not overlap with the pixel electrode is removed, so that the inorganic insulating layer is divided. Then, a depressed portion is formed in the organic insulating layer at a position between inorganic insulating layers obtained by the division of the inorganic insulating layer. Here, the depressed portion is formed so that end portions of the inorganic insulating layers overlap with the depressed portion of the organic insulating layer. In other words, the depressed portion is formed so that the inorganic insulating layers each include a projecting portion overlapping with the depressed portion of the organic insulating layer.

The conductive layer and the inorganic insulating layer can be processed by etching after a pattern is formed by a photolithography method, for example. The organic insulating layer is processed by a method facilitating isotropic processing more easily than a processing method of the inorganic insulating layer. For example, the organic insulating layer is processed by ashing using oxygen plasma. Thus, the depressed portion can be formed in the organic insulating layer so that the inorganic insulating layer includes the above projecting portion.

In this specification and the like, ashing refers to a removal of at least part of an organic insulating layer by making an active oxygen molecule, an ozone molecule, or an oxygen atom, which is generated by discharging, chemically act on the organic insulating layer.

In this specification and the like, processing of the layer or film refers to a removal of a desired region of the layer or the film. Here, the processing of a film allows the film to be divided and results in formation of a plurality of layers.

In this specification and the like, a horizontal direction refers to the direction horizontal to a substrate surface, for example. A perpendicular direction refers to the direction perpendicular to the substrate surface, for example. Note that, for example, the direction horizontal to a flat portion of a layer provided over the substrate is referred to as a horizontal direction, and the direction perpendicular to the flat portion is referred to as a perpendicular direction in some cases. Note that the substrate surface, the flat portion of the layer, and the like are not necessarily completely flat and may be substantially flat with a slight curvature or substantially flat with slight unevenness.

Next, an EL layer is formed across a plurality of pixel electrodes. When the EL layer is formed, the EL layer is divided into island shapes by the projecting portion of the inorganic insulating layer, and one island-shaped EL layer is formed for one pixel electrode. That is, an island-shaped EL layer can be formed for each subpixel.

When the EL layer is formed into an island shape, functional layers other than a light-emitting layer (e.g., a carrier-injection layer, a carrier-transport layer, and a carrier-blocking layer, more specifically, a hole-injection layer, a hole-transport layer, and an electron-blocking layer) are also formed into an island shape. Processing the functional layers into an island shape can reduce leakage current (sometimes referred to as horizontal-direction leakage current, horizontal leakage current, or lateral leakage current) that might be generated between adjacent subpixels. For example, in the case where the hole-injection layer is shared by adjacent subpixels, horizontal leakage current might be generated due to the hole-injection layer. Meanwhile, in the display device of one embodiment of the present invention, the hole-injection layer can be processed into an island shape; hence, horizontal leakage current between adjacent subpixels is not substantially generated or horizontal leakage current can be extremely small.

In this specification and the like, a device fabricated using a metal mask or an FMM (fine metal mask) is sometimes referred to as a device having an MM (metal mask) structure. In this specification and the like, a device fabricated without using a metal mask or an FMM is sometimes referred to as a device having an MML (metal maskless) structure.

Here, when steps performed after formation of the EL layer are performed at temperature higher than the upper temperature limit of the EL layer, deterioration of the EL layer proceeds, which might result in a decrease in the emission efficiency and reliability of the light-emitting element.

Thus, in one embodiment of the present invention, the upper temperature limits of compounds contained in the light-emitting element is preferably higher than or equal to 100° C. and lower than or equal to 180° C. or higher than or equal to 120° C. and lower than or equal to 180° C., further preferably higher than or equal to 140° C. and lower than or equal to 180° C.

Examples of indicators of the upper temperature limit include the glass transition point (Tg), the softening point, the melting point, the thermal decomposition temperature, and the 5% weight loss temperature. For example, as an indicator of the upper temperature limit of a layer included in the EL layer, a glass transition point of a material contained in the layer can be used. In the case where the layer is a mixed layer formed of a plurality of materials, a glass transition point of a material contained in the highest proportion can be used, for example. Alternatively, the lowest temperature among the glass transition points of the materials may be used.

In particular, the upper temperature limits of functional layers provided over the light-emitting layer are preferably high. It is further preferable that the upper temperature limit of the functional layer provided over and in contact with the light-emitting layer be high. When such a functional layer has high heat resistance, the light-emitting layer can be effectively protected, resulting in less damage to the light-emitting layer.

In addition, it is particularly preferable that the upper temperature limit of the light-emitting layer be high. In this case, the light-emitting layer can be inhibited from being damaged by heating and being decreased in emission efficiency and lifetime.

Increasing the upper temperature limit of the light-emitting element can improve the reliability of the light-emitting element. Furthermore, the allowable temperature range in the manufacturing process of the display device can be widened, thereby improving the manufacturing yield and the reliability.

In this embodiment, a display device of one embodiment of the present invention will be described.

### <Structure Example>

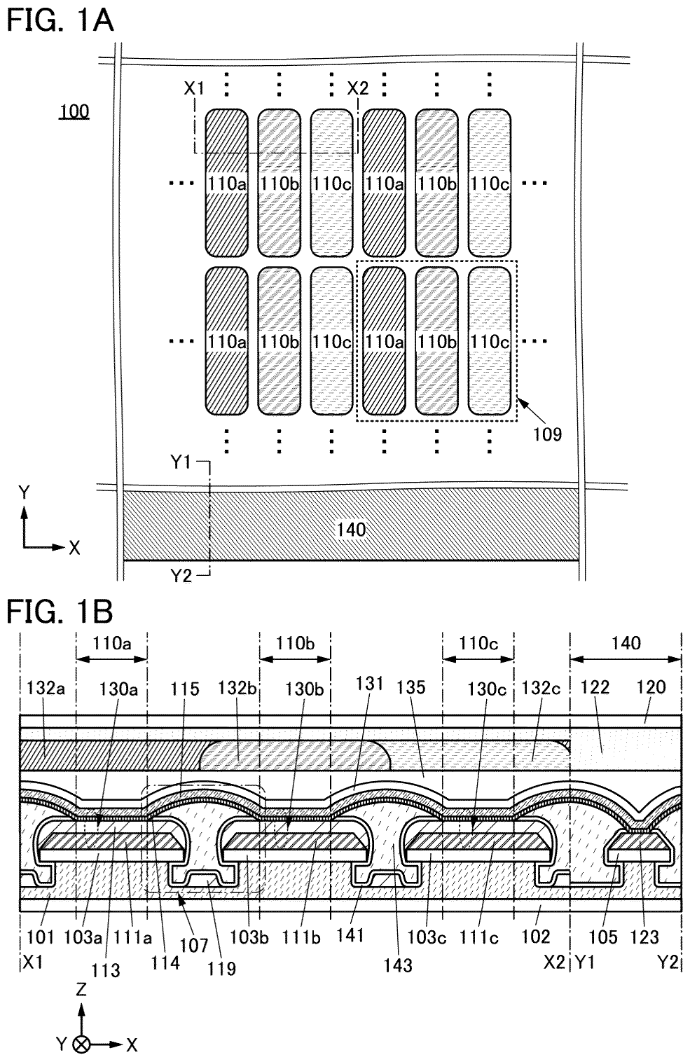

FIG. 1A is a plan view illustrating a display device 100 of one embodiment of the present invention. Note that FIG. 1A is also referred to as a top view of the display device 100. The display device 100 includes a display portion in which a plurality of pixels 109 are arranged in a matrix and a connection portion 140 outside the display portion. The pixels 109 each include a plurality of subpixels. FIG. 1A illustrates the pixels 109 in two rows and two columns. As the structure where the pixels 109 each include three subpixels (a subpixel 110a, a subpixel 110b, and a subpixel 110c), the subpixels in two rows and six columns are illustrated.

Each of the subpixels includes a light-emitting element. Top surface shapes of the subpixels in FIG. 1A correspond to top surface shapes of light-emitting regions of the light-emitting elements. The top surface shape of the subpixel can be a triangle, a tetragon (including a rectangle and a square), an elliptical shape, or a circular shape, for example. Alternatively, the top surface shape of the subpixel can be, for example, a polygonal shape such as a pentagon or a polygonal shape with rounded corners.

The subpixels each include a pixel circuit that has a function of controlling the light-emitting element. The pixel circuits are not necessarily placed in the ranges of the subpixels illustrated in FIG. 1A and may be placed outside the subpixels. For example, transistors included in the pixel circuit of the subpixel 110a may be positioned in the range of the subpixel 110b illustrated in FIG. 1A. Furthermore, for example, some or all of components such as transistors included in the pixel circuit of the subpixel 110a may be positioned outside the range of the subpixel 110a in a plan view.

Although the subpixel 110a, the subpixel 110b, and the subpixel 110c have the same or substantially the same aperture ratio (also referred to as size or size of a light-emitting region) in FIG. 1A, one embodiment of the present invention is not limited thereto. The aperture ratio of each of the subpixel 110a, the subpixel 110b, and the subpixel 110c can be determined as appropriate. The subpixel 110a, the subpixel 110b, and the subpixel 110c may have different aperture ratios, or two or more of the subpixel 110a, the subpixel 110b, and the subpixel 110c may have the same or substantially the same aperture ratio.

The pixel 109 illustrated in FIG. 1A employs stripe arrangement. The pixel 109 illustrated in FIG. 1A is composed of three subpixels: the subpixel 110a, the subpixel 110b, and the subpixel 110c. The subpixel 110a, the subpixel 110b, and the subpixel 110c exhibit light of different colors. The subpixel 110a, the subpixel 110b, and the subpixel 110c can be subpixels of three colors of red (R), green (G), and blue (B) or subpixels of three colors of yellow (Y), cyan (C), and magenta (M), for example. The number of colors of subpixels is not limited to three and may be four or more. As the subpixels of four colors, subpixels of four colors of R, G, B, and white (W), subpixels of four colors of R, G, B, and Y, or four subpixels of R, G, B, and infrared light (IR) can be given, for example.

Here, red light can be, for example, light with a peak wavelength greater than or equal to 630 nm and less than or equal to 780 nm. The green light can be, for example, light with a peak wavelength greater than or equal to 500 nm and less than 570 nm. Furthermore, blue light can be, for example, light with a peak wavelength greater than or equal to 450 nm and less than 480 nm.

In this specification and the like, the direction perpendicular to the side of the pixel or the subpixel is referred to as an X direction and an Y direction in some cases. The X direction and the Y direction intersect with each other and are perpendicular to each other, for example. FIG. 1A illustrates an example where subpixels 110 of different colors are arranged in the X direction and subpixels 110 of the same color are arranged in the Y direction.

Although FIG. 1A shows an example where the connection portion 140 is positioned on the lower side of the display portion in the plan view, there is no particular limitation on the position of the connection portion 140. The connection portion 140 only needs to be provided on at least one of the upper side, the right side, the left side, and the lower side of the display portion, and may be provided to surround the four sides of the display portion in the top view. The top surface shape of the connection portion 140 is not particularly limited and can be a belt-like shape, an L shape, a U shape, a frame-like shape, or the like. The number of the connection portions 140 can be one or more.

FIG. 1B is a cross-sectional view along dashed-dotted line X1-X2 and dashed-dotted line Y1-Y2 in FIG. 1A. The cross-sectional view in FIG. 1B is on the XZ plane. Note that cross-sectional views, other than FIG. 1B, between the dashed-dotted line X1-X2 and the dashed-dotted line Y1-Y2 in FIG. 1A also have the XZ plane. An example of a structure in which the subpixel 110a emits red light, the subpixel 110b emits green light, and the subpixel 110c emits blue light is described below.

In this specification and the like, the X direction may be referred to as the horizontal direction, and the Z direction may be referred to as the height direction or the vertical direction. Alternatively, the Y direction may be referred to as the horizontal direction. The X direction, Y direction, and Z direction can be perpendicular to each other to express a three-dimensional space. Here, the XY plane can be referred to as a plane or a top surface, and the XZ plane and the YZ plane can be each referred to as a cross section.

The subpixel 110a includes a light-emitting element 130a and a coloring layer 132a. The light-emitting element 130a has a function of emitting white light, for example. The coloring layer 132a has a region overlapping with the light-emitting element 130a, and has higher transmittance of red light than those of the other colors, for example. Thus, light emitted by the light-emitting element 130a is extracted as red light to the outside of the display device through the coloring layer 132a.

The subpixel 110b includes a light-emitting element 130b and a coloring layer 132b. The light-emitting element 130b has a function of emitting white light, for example. The coloring layer 132b has a region overlapping with the light-emitting element 130b. The coloring layer 132b allows transmission of light of a color different from the color of light transmitted through the coloring layer 132a. The coloring layer 132b has higher transmittance of green light than those of the other colors, for example. Thus, light emitted by the light-emitting element 130b is extracted as green light to the outside of the display device through the coloring layer 132b.

The subpixel 110c includes a light-emitting element 130c and a coloring layer 132c. The light-emitting element 130c has a function of emitting white light, for example. The coloring layer 132c has a region overlapping with the light-emitting element 130c. The coloring layer 132c allows transmission of light of a color different from the colors of light transmitted through the coloring layer 132a and the coloring layer 132b. The coloring layer 132c has higher transmittance of blue light than those of the other colors, for example. Thus, light emitted by the light-emitting element 130c is extracted as blue light to the outside of the display device through the coloring layer 132c.

Here, the expression “a color of light transmitted is different” means that a wavelength with the highest transmittance is different. For example, in the case where the coloring layer 132a has the highest transmittance of light (red light) with a wavelength greater than or equal to 630 nm and less than or equal to 780 nm among visible light and the coloring layer 132b has the highest transmittance of light (green light) with a wavelength greater than or equal to 500 nm and less than 570 nm among visible light, it can be said that the color of light transmitted through the coloring layer 132a is different from the color of light transmitted through the coloring layer 132b.

In this specification and the like, visible light refers to light at a wavelength greater than or equal to 380 nm and less than or equal to 780 nm.

Note that in the case of describing matters common to the light-emitting element 130a, the light-emitting element 130b, and the light-emitting element 130c, these light-emitting elements are sometimes referred to as a light-emitting element 130 by omitting the alphabets that distinguish them from each other. Similarly, in the description of matters common to components that are distinguished from each other using alphabets, such as the coloring layer 132a, the coloring layer 132b, and the coloring layer 132c, reference numerals without alphabets are sometimes used.

As illustrated in FIG. 1B, the display device 100 includes an insulating layer 101 over a substrate 102; and an insulating layer 103a, an insulating layer 103b, and an insulating layer 103c over the insulating layer 101. The light-emitting element 130a is provided over the insulating layer 103a, the light-emitting element 130b is provided over the insulating layer 103b, and the light-emitting element 130c is provided over the insulating layer 103c. A protective layer 131 is provided to cover the light-emitting element 130a, the light-emitting element 130b, and the light-emitting element 130c, and a protective layer 135 is provided over the protective layer 131. The coloring layer 132a, the coloring layer 132b, and the coloring layer 132c are provided over the protective layer 135, and a substrate 120 is attached onto the coloring layers with an adhesive layer 122. Although not illustrated in FIG. 1B, a transistor is provided between the substrate 102 and the insulating layer 101, for example. An insulating layer including a material different from that in the insulating layer 101 can be provided between the substrate 102 and the insulating layer 101, for example.

An insulating layer 141 is provided between adjacent light-emitting elements 130, and an insulating layer 143 is provided over the insulating layer 141. Note that FIG. 1B illustrates a plurality of cross sections of the insulating layer 141 and a plurality of cross sections of the insulating layer 143; however, in a plan view, the insulating layer 141 can have a structure as one continuous layer and the insulating layer 143 can have a structure as one continuous layer. In other words, the display device 100 can have a structure including one insulating layer 141 and one insulating layer 143, for example. Note that the display device 100 may include a plurality of insulating layers 141 which are separated from each other and a plurality of insulating layers 143 which are separated from each other.

In the case of providing a subpixel that emits white light, a structure provided with a coloring layer through which white light is transmitted or a structure provided with no coloring layer may be employed.

The display device of one embodiment of the present invention can have any of the following structures: a top-emission structure in which light is emitted in a direction opposite to a substrate where a light-emitting element is formed, a bottom-emission structure in which light is emitted toward a substrate where a light-emitting element is formed, and a dual-emission structure where light is emitted toward both surfaces.

For each of the substrate 102 and the substrate 120, glass, quartz, ceramic, sapphire, a resin, a metal, an alloy, a semiconductor, or the like can be used. The substrate on the side where light from the light-emitting element 130 is extracted is formed using a material that transmits the light. In other words, in the case where the display device 100 has a top-emission structure, at least the substrate 120 is formed using a material that transmits light emitted by the light-emitting element 130, and in the case where the display device 100 has a bottom-emission structure, at least the substrate 102 is formed using a material that transmits light emitted by the light-emitting element 130. In the case where the display device 100 has a dual-emission structure, a material that transmits light emitted by the light-emitting element 130 is used for both the substrate 102 and the substrate 120. When a flexible material is used for the substrate 102 and the substrate 120, the flexibility of the display device 100 can be increased. Furthermore, a polarizing plate may be used as the substrate 102 and the substrate 120.

For each of the substrate 102 and the substrate 120, any of the following can be used, for example: polyester resins such as polyethylene terephthalate (PET) and polyethylene naphthalate (PEN), a polyacrylonitrile resin, an acrylic resin, a polyimide resin, a polymethyl methacrylate resin, a polycarbonate (PC) resin, a polyethersulfone (PES) resin, polyamide resins (e.g., nylon and aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, and cellulose nanofiber. Glass that is thin enough to have flexibility may be used for the substrate 102 and the substrate 120.

As the light-emitting element 130, an OLED (Organic Light Emitting Diode) or a QLED (Quantum-dot Light Emitting Diode) is preferably used, for example. Examples of a light-emitting substance contained in the light-emitting element 130 include a substance exhibiting fluorescence (a fluorescent material), a substance exhibiting phosphorescence (a phosphorescent material), an inorganic compound (e.g., a quantum dot material), and a substance exhibiting thermally activated delayed fluorescence (a TADF material). An LED such as a micro-LED (Light Emitting Diode) can be used as the light-emitting element 130.

A conductive film that transmits visible light can be used for one of a pair of electrodes of the light-emitting element 130 through which light is extracted, and a conductive film that reflects visible light can be used for the other of the pair of electrodes through which light is not extracted. A conductive film that transmits visible light may be used also for the electrode through which light is not extracted. In that case, a conductive film that transmits visible light is preferably provided between a conductive film that reflects visible light and the EL layer.

One electrode of the pair of electrodes included in the light-emitting element 130 functions as an anode, and the other of the electrodes functions as a cathode. The case where the pixel electrode functions as an anode and the common electrode functions as a cathode will be described below as an example in some cases unless otherwise specified.

The light-emitting element 130a includes a pixel electrode 111a over the insulating layer 103a, an island-shaped EL layer 113 over the pixel electrode 111a, a common layer 114 over the EL layer 113, and a common electrode 115 over the common layer 114. The light-emitting element 130b includes a pixel electrode 111b over the insulating layer 103b, another island-shaped EL layer 113 over the pixel electrode 111b, the common layer 114 over the EL layer 113, and the common electrode 115 over the common layer 114. The light-emitting element 130c includes a pixel electrode 111c over the insulating layer 103c, another island-shaped EL layer 113 over the pixel electrode 111c, the common layer 114 over the EL layer 113, and the common electrode 115 over the common layer 114. Note that the EL layer 113 and the common layer 114 can be collectively referred to as an EL layer.

The display device of one embodiment of the present invention includes the island-shaped EL layer 113 provided for each of the light-emitting elements 130. Specifically, the light-emitting element 130a, the light-emitting element 130b, and the light-emitting element 130c each include the EL layer 113, and the EL layers 113 do not include regions overlapping with each other and are separated. Providing the island-shaped EL layer 113 for each of the light-emitting elements 130 can inhibit leakage current between the adjacent light-emitting elements 130. Thus, it is possible to prevent crosstalk due to unintended light emission, so that a display device with extremely high contrast can be achieved. Specifically, a display device having high current efficiency at low luminance can be achieved.

The EL layers 113 can be formed using the same material in the same step. When a structure of the EL layer 113 included in the light-emitting element 130a, a structure of the EL layer 113 included in the light-emitting element 130b, and a structure of the EL layer 113 included in the light-emitting element 130c are the same as each other, the number of manufacturing steps of the display device can be reduced. Accordingly, the manufacturing cost of the display device can be reduced and the manufacturing yield can be improved.

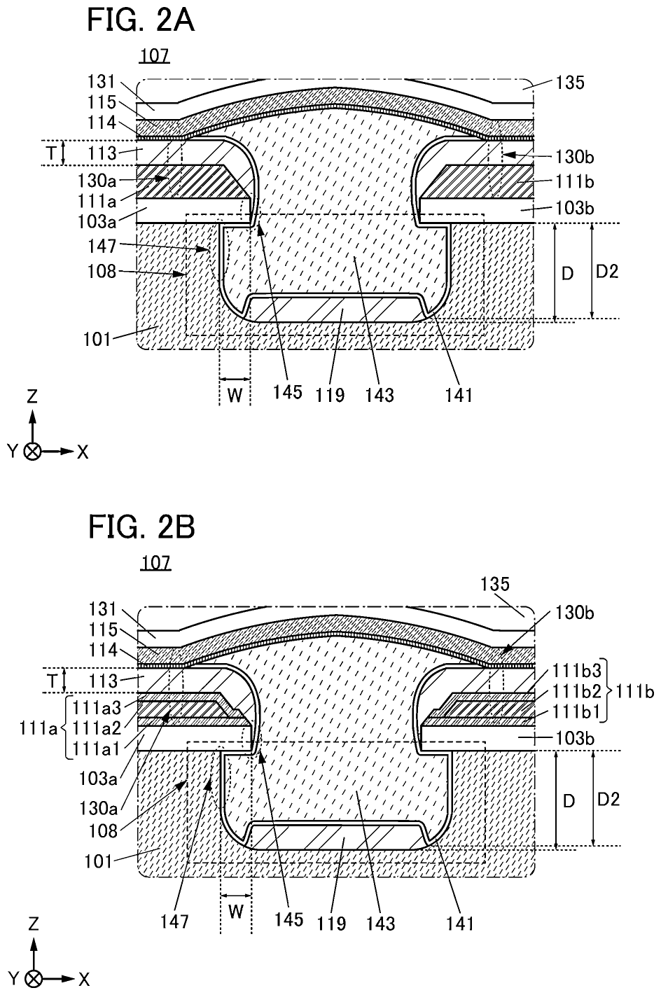

FIG. 2A shows an enlarged view of a region 107 including a region between the light-emitting element 130a and the light-emitting element 130b and a periphery region thereof. As illustrated in FIG. 2A, the insulating layer 101 includes a depressed portion 108. The depressed portion 108 is provided between adjacent light-emitting elements 130. Part of the insulating layer 103 overlaps with the depressed portion 108; specifically, an end portion 145 of the insulating layer 103 overlaps with the depressed portion 108. That is, the insulating layer 103 includes a projecting portion overlapping with the depressed portion 108.

A surface where the EL layer 113 is formed has a step caused by the projecting portion of the insulating layer 103. The step lowers the coverage with the EL layer 113, which causes division of the EL layer 113 when the EL layer 113 s formed. In other words, disconnection is generated in the EL layer 113. Thus, a region where the EL layer 113 is not formed is generated.

In this specification and the like, disconnection refers to a phenomenon in which a layer, a film, an electrode, or the like is split because of the shape of the formation surface (e.g., a level difference). In this specification and the like, a region where the EL layer 113 is not formed due to disconnection is referred to as a disconnection region.

In this structure, the disconnection is easily generated in the EL layer 113 in accordance with an increase in a width W of the projecting portion of the insulating layer 103 that overlaps with the depressed portion 108. Thus, the EL layer 113 is easily divided for each light-emitting element 130, which is preferable. For example, the ratio of the width W of the projecting portion of the insulating layer 103 to a thickness T of the EL layer 113 (W/T) is preferably greater than or equal to 0.3, further preferably greater or equal to 0.5, further preferably greater than 0.7, still further preferably greater than or equal to 0.9, yet still further preferably greater or equal to 1.0. By contrast, when the width W of the projecting portion of the insulating layer 103 is too large, the productivity of the display device may be reduced, for example. Furthermore, the projecting portion of the insulating layer 103 is likely to collapse, and the manufacturing yield of the display device decreases in some cases. Therefore, the ratio of the width W of the projecting portion of the insulating layer 103 to the thickness T of the EL layer 113 (W/T) is preferably less than or equal to 10.0, further preferably less than or equal to 5.0.

Here, the width W of the projecting portion of the insulating layer 103 is preferably greater than or equal to 20 nm, further preferably greater than or equal to 50 nm, further preferably greater than or equal to 80 nm, still further preferably greater than or equal to 110 nm, yet further preferably greater than or equal to 140 nm, yet still further preferably greater than or equal to 160 nm, yet still further preferably greater than or equal to 180 nm. In addition, the width W of the projecting portion of the insulating layer 103 is preferably less than or equal to 2000 nm, further preferably less than or equal to 1000 nm.

Note that the width W of the projecting portion of the insulating layer 103 indicates, seen from the XZ plane or the YZ plane, the distance of the bottom surface of the insulating layer 103 which is between the end portion 145 of the insulating layer 103 and an end portion 147 of the depressed portion 108, for example. That is, the width W refers to, for example, the distance between the lower end portion of the insulating layer 103, which is the lower end of the end portion 145, and the upper end portion of the depressed portion 108, which is the upper end of the end portion 147, when seen from the XZ plane or the YZ plane. The thickness T of the EL layer 113 refers to, for example, a difference between the top surface position of the EL layer 113 and the bottom surface position of the EL layer 113 in a region where the EL layer 113 overlaps with the top surface of the pixel electrode 111 when seen from the XZ plane or the YZ plane. Alternatively, the thickness T may be set to a distance between the top surface of the pixel electrode 111 and the bottom surface of the common layer 114 or the common electrode 115 in the Z direction.

In addition, the disconnection is easily generated in the EL layer 113 as a depth D of the depressed portion 108 is deeper, that is, the length in the Z direction of the depressed portion 108 is increased, which is preferable. For example, the ratio of the depth D of the depressed portion 108 to the thickness T of the EL layer 113 (D/T) is preferably greater than or equal to 1.0, further preferably greater than or equal to 2.0, further preferably greater than or equal to 3.0, still further preferably greater than or equal to 3.5, yet still further preferably greater than or equal to 4.0. By contrast, when the depth D of the depressed portion 108 is too deep, the productivity of the display device may be reduced, for example. Thus, the ratio of the depth D of the depressed portion 108 to the thickness T of the EL layer 113 (D/T) is preferably less than or equal to 50.0, further preferably less than or equal to 30.0, still further preferably less than or equal to 20.0.

Here, the depth D of the depressed portion 108 is preferably greater than or equal to 50 nm, further preferably greater than or equal to 150 nm, further preferably greater than or equal to 300 nm, still further preferably greater than or equal to 450 nm, yet still further preferably greater than or equal to 600 nm, yet still further preferably greater than or equal to 700 nm. In addition, the depth D of the depressed portion 108 is preferably less than or equal to 10 μm, further preferably less than or equal to 5 μm, still further preferably less than or equal to 4 μm, yet still further preferably less than or equal to 3 μm.

Note that the depth D of the depressed portion 108 indicates the distance between the bottom surface of the insulating layer 103 and the bottom portion of the depressed portion 108 in the Z direction when seen from the XZ plane or the YZ plane, for example. Specifically, the depth D of the depressed portion 108 is represented by the difference between the height at the bottom surface of the insulating layer 103 from the substrate 102 and the height at the deepest portion of the depressed portion 108 from the substrate 102 in the cross section when seen from the XZ plane or the YZ plane, for example. In other words, the depth D of the depressed portion 108 is represented by the difference between the height at the bottom surface of the insulating layer 103 from the substrate 102 and the height at the portion, whose height from the substrate 102 is the lowest, of the depressed portion 108 in the cross section when seen from the XZ plane or the YZ plane, for example.

In this specification and the like, the height of A from B refers to the distance from A to B in the Z direction.

The width W, the thickness T, and the depth D can be measured by, for example, a scanning electron microscopy (SEM) image, a transmission electron microscope (TEM) image, or a scanning transmission electron microscopy (STEM) image of a cross section of the light-emitting element 130.

The insulating layer 101, a film to be the insulating layer 103, and a film to be the pixel electrode 111 are formed and then processed, whereby the pixel electrode 111 and the insulating layer 103 are formed. In addition, the depressed portion 108 is formed in the insulating layer 101.

In this specification and the like, “deposition of a film” is sometimes referred to as “formation of a film”.

For example, in the case where an organic material is used for the insulating layer 101 and an inorganic material is used for the insulating layer 103, the film to be the pixel electrode 111 and the film to be the insulating layer 103 are processed by an etching method after patterning is performed by a photolithography method, so that the pixel electrode 111 and the insulating layer 103 can be formed. When the insulating layer 101 is processed by a method enabling isotopic processing more easily than a method for processing the film to be the insulating layer 103, the depressed portion 108 is formed so that the insulating layer 103 has a projecting portion. The insulating layer 101 may be processed by ashing using oxygen plasma, for example. Alternatively, the insulating layer 101 can be processed using an oxygen gas and CF₄, C₄F₈, SF₆, CHF₃, Cl₂, H₂O, BCl₃, or a Group 18 element. He can be used as the Group 18 element, for example. Alternatively, the insulating layer 101 may be processed by etching or wet etching, for example.

The insulating layer 101 can be an organic insulating layer. The insulating layer 103 can be an inorganic insulating layer. Note that as long as the depressed portion 108 can be formed so that the insulating layer 103 has a projecting portion, it is not necessary that the insulating layer 101 is an organic insulating layer and the insulating layer 103 is an inorganic insulating layer. For example, both the insulating layer 101 and the insulating layer 103 may be an inorganic insulating layer.

In this specification and the like, an insulating layer including an organic material is referred to as an organic insulating layer, and an insulating layer including an inorganic material is referred to as an inorganic insulating layer.

The insulating layer 101 can be formed using a resin material, for example. As the insulating layer 101, an acrylic resin, a polyimide resin, an epoxy resin, a polyamide resin, a polyimide-amide resin, a siloxane resin, a benzocyclobutene-based resin, a phenol resin, a precursor of any of these resins, or the like can be used, for example.

For example, one or more of an oxide, a nitride, an oxynitride, and a nitride oxide can be used for the insulating layer 103. Examples of the oxide include a silicon oxide, an aluminum oxide, a magnesium oxide, an indium gallium zinc oxide, a gallium oxide, a germanium oxide, an yttrium oxide, a zirconium oxide, a lanthanum oxide, a neodymium oxide, a hafnium oxide, and a tantalum oxide. Examples of the nitride include a silicon nitride and an aluminum nitride. Examples of the oxynitride include a silicon oxynitride and an aluminum oxynitride. Examples of the nitride oxide include a silicon nitride oxide and an aluminum nitride oxide.

Note that in this specification and the like, oxynitride refers to a material that contains more oxygen than nitrogen in its composition, and nitride oxide refers to a material that contains more nitrogen than oxygen in its composition. For example, in the case where silicon oxynitride is described, it refers to a material that contains more oxygen than nitrogen in its composition. In the case where silicon nitride oxide is described, it refers to a material that contains more nitrogen than oxygen in its composition.

An organic layer 119 may be provided in the depressed portion 108. The organic layer 119 is formed when the material of the EL layer 113 reaches the inside of the depressed portion 108 in the formation of the EL layer 113. That is, the organic layer 119 is formed using the same material in the same step as the EL layer 113. FIG. 2A illustrates an example in which the organic layer 119 is provided over the insulating layer 101 in the bottom portion of the depressed portion 108.

When the organic layer 119 includes a region in contact with the EL layer 113, the EL layers 113 included in the adjacent light-emitting elements 130 are connected through the organic layer 119 and leakage current is generated in some cases. Thus, it is preferable that the organic layer 119 not include a region in contact with the EL layer 113. In other words, it is preferable that the organic layer 119 is separated from the EL layer 113. In the case where the distance between the side surfaces of adjacent pixel electrodes 111 is short, for example, the organic layer 119 is not formed in some cases.

In particular, in the case where the insulating layer 101 is an organic insulating layer, the boundary between the insulating layer 101 and the organic layer 119 cannot be clearly observed in some cases. In the case where the boundary between the insulating layer 101 and the organic layer 119 cannot be clearly observed, for example, the depth of the depressed portion 108 can be the difference between the height at the bottom surface of the insulating layer 103 from the substrate 102 and the height at the deepest portion, from the substrate 102, of the depressed portion 108 as far as it is clearly observed in the cross section, when seen from the XZ plane or the YZ plane. For example, the depth of the depressed portion 108 can be represented by a depth D2 that is a difference between the height at the bottom surface of the insulating layer 103 from the substrate 102 and the height at the portion, whose height from the substrate 102 is the lowest, on the bottom surface of the insulating layer 141 in the cross section when seen from the XZ plane or the YZ plane.

FIG. 1B and FIG. 2A illustrate a structure in which the EL layer 113 covers the top surface of the pixel electrode 111 and at least part of a side surface thereof. With such a structure, the entire region overlapping with the top surface of the pixel electrode 111 in a plan view can be used as a light-emitting region. Thus, the aperture ratio of the display device can be increased as compared with a structure in which the island-shaped EL layer 113 does not cover the side surface of the pixel electrode 111. Note that as illustrated in FIG. 1B and FIG. 2A, the EL layer 113 covers not only the side surface of the pixel electrode 111 but also a side surface of the insulating layer 103 in some cases.

Here, the side surfaces of the pixel electrode 111a, the pixel electrode 111b, and the pixel electrode 111c may each have a tapered shape. Specifically, the end portions of the pixel electrode 111a, the pixel electrode 111b, and the pixel electrode 111c may each have a tapered shape with a taper angle less than 90° when seen from the XZ plane or the YZ plane, for example. In that case, the coverage of the pixel electrode 111 with the EL layer 113 can be increased compared with the case where the side surface of the pixel electrode 111 is perpendicular. Note that a conductive layer 123 provided in the connection portion 140 described later can be formed in the same step as the pixel electrode 111a, the pixel electrode 111b, and the pixel electrode 111c. Thus, in the case where the side surfaces of the pixel electrode 111a, the pixel electrode 111b, and the pixel electrode 111c each have a tapered shape, the conductive layer 123 may also have a tapered shape.

In this specification and the like, a tapered shape indicates a shape in which at least part of a side surface of a structure is inclined to a substrate surface. For example, a tapered shape preferably includes a region where the angle formed by the inclined side surface and the substrate surface (such an angle is also referred to as a taper angle) is less than 90°. Note that the side surface of the component and the substrate surface are not necessarily completely flat and may be substantially flat with a slight curvature or substantially flat with slight unevenness.

Note that the side surfaces of the insulating layer 103a, the insulating layer 103b, and the insulating layer 103c may each have a tapered shape with a taper angle less than 90° when seen from the XZ or the YZ plane, for example. The side surface of the depressed portion 108 in the insulating layer 101 may have a tapered shape with a taper angle less than 90° when seen from the XZ plane or the YZ plane, for example. Note that an insulating layer 105 provided in the connection portion 140 described later can be formed in the same step as the insulating layer 103a, the insulating layer 103b, and the insulating layer 103c. Thus, when the side surfaces of the insulating layer 103a, the insulating layer 103b, and the insulating layer 103c have a tapered shape, the insulating layer 105 can also have a tapered shape.

Here, the taper angle of the side surface of the insulating layer 103 and the taper angle of the side surface of the insulating layer 101 in the depressed portion 108 are not necessarily equal to the taper angle of the side surface of the pixel electrode 111. For example, at least one of the taper angle of the side surface of the insulating layer 103 and the taper angle of the side surface of the insulating layer 101 in the depressed portion 108 is greater (steeper taper angle) than the taper angle of the side surface of the pixel electrode 111. Similarly, the taper angle of the side surface of the insulating layer 105 is not necessarily equal to the taper angle of the side surface of the conductive layer 123, and may be greater than the taper angle of the side surface of the conductive layer 123, for example.

In FIG. 1B and FIG. 2A, the upper end portion of the side surface of the insulating layer 103 and the lower end portion of the side surface of the pixel electrode 111 are aligned with each other, and the upper end portion of the side surface of the insulating layer 105 and the lower end portion of the side surface of the conductive layer 123 are aligned with each other; however, they are not necessarily aligned with each other. For example, the lower end portion of the side surface of the pixel electrode 111 may be located inward from the upper end portion of the side surface of the insulating layer 103, and the lower end portion of the side surface of the conductive layer 123 may be located inward from the upper end portion of the side surface of the insulating layer 105.

As illustrated in FIG. 1B and FIG. 2A, for example, an insulating layer covering the end portion of the top surface of the pixel electrode 111 is not provided between the pixel electrode 111 and the EL layer 113 in the display device of one embodiment of the present invention. This allows the distance between adjacent light-emitting elements 130 to be extremely short. Accordingly, the display device can have high resolution or high definition. In addition, a mask for forming the insulating layer is not needed, which leads to a reduction in manufacturing cost of the display device.

Light emitted from the EL layer 113 can be extracted efficiently with a structure where an insulating layer covering the end portion of the top surface of the pixel electrode 111 is not provided between the pixel electrode 111 and the EL layer 113, i.e., a structure where an insulating layer is not provided between the pixel electrode 111 and the EL layer 113. Therefore, the viewing angle dependence of the display device of one embodiment of the present invention can be extremely small. A reduction in the viewing angle dependence leads to an increase in visibility of an image on the display device. For example, in the display device of one embodiment of the present invention, the viewing angle (the maximum angle with a certain contrast ratio maintained when a screen is seen from an oblique direction) can be greater than or equal to 100° and less than 180°, preferably greater than or equal to 150° and less than or equal to 170°. Note that the above viewing angle refers to that in both the vertical direction and the horizontal direction.

For the light-emitting element 130, a single structure (a structure including only one light-emitting unit) or a tandem structure (a structure including a plurality of light-emitting units) may be employed. The light-emitting unit includes at least one light-emitting layer.

The EL layer 113 includes at least a light-emitting layer. In addition, the EL layer 113 may include one or more of a hole-injection layer, a hole-transport layer, a hole-blocking layer, a charge-generation layer, an electron-blocking layer, an electron-transport layer, and an electron-injection layer.

For example, the EL layer 113 can contain a light-emitting substance emitting blue light and a light-emitting substance emitting visible light having a longer wavelength than blue light. For example, a structure containing a light-emitting substance emitting blue light and a light-emitting substance emitting yellow light, or a structure containing a light-emitting substance emitting blue light, a light-emitting substance emitting green light, and a light-emitting substance emitting red light can be used for the EL layer 113.

As each of the light-emitting device 130a, the light-emitting device 130b, and the light-emitting device 130c, for example, a single-structure light-emitting element including two light-emitting layers, which are a light-emitting layer emitting yellow (Y) light and a light-emitting layer emitting blue (B) light, or a single-structure light-emitting element including three light-emitting layers, which are a light-emitting layer emitting red (R) light, a light-emitting layer emitting green (G) light, and a light-emitting layer emitting blue light, can be used. As examples of the number of stacked light-emitting layers and the order of colors thereof, a three-layer structure of R, G, and B and a three-layer structure of R, B, and G from the anode side can be given. Another layer (also referred to as a buffer layer) may be provided between two light-emitting layers.

In the case where the light-emitting element 130 having a tandem structure is used, examples of applicable structures are as follows: a two-unit tandem structure including a light-emitting unit that emits yellow light and a light-emitting unit that emits blue light; a two-unit tandem structure including a light-emitting unit that emits red light and green light and a light-emitting unit that emits blue light; and a three-unit tandem structure in which a light-emitting unit that emits blue light, a light-emitting unit that emits yellow, yellow-green, or green light and red light, and a light-emitting unit that emits blue light are stacked in this order. Examples of the number of stacked light-emitting units and the order of colors from an anode side include a two-unit structure of B and Y; a two-unit structure of B and X; and a three-unit structure of B, X, and B. Examples of the number of light-emitting layers stacked in the light-emitting unit X and the order of colors from the anode side include a two-layer structure of R and Y; a two-layer structure of R and G; a two-layer structure of G and R; a three-layer structure of G, R, and G; and a three-layer structure of R, G, and R. Another layer may be provided between two light-emitting layers.

In the case where the light-emitting element 130 having a tandem structure is used, the EL layer 113 includes a plurality of light-emitting units. A charge-generation layer is preferably provided between the light-emitting units.

For example, when emission colors of the plurality of light-emitting units are complementary to each other, the light-emitting element 130 can emit white light. The light-emitting unit may include one or more of a hole-injection layer, a hole-transport layer, a hole-blocking layer, an electron-blocking layer, an electron-transport layer, and an electron-injection layer.

The EL layer 113 may include a hole-injection layer, a hole-transport layer, a light-emitting layer, and an electron-transport layer in this order, for example. In addition, an electron-blocking layer may be provided between the hole-transport layer and the light-emitting layer. In addition, a hole-blocking layer may be provided between the electron-transport layer and the light-emitting layer. Furthermore, an electron-injection layer may be provided over the electron-transport layer.

The EL layer 113 may include an electron-injection layer, an electron-transport layer, a light-emitting layer, and a hole-transport layer in this order, for example. In addition, a hole-blocking layer may be provided between the electron-transport layer and the light-emitting layer. In addition, an electron-blocking layer may be provided between the hole-transport layer and the light-emitting layer. Furthermore, a hole-injection layer may be provided over the hole-transport layer.

As described above, the EL layer 113 preferably includes a light-emitting layer and a carrier-transport layer (an electron-transport layer or a hole-transport layer) over the light-emitting layer. Alternatively, the EL layer 113 preferably includes a light-emitting layer and a carrier-blocking layer (a hole-blocking layer or an electron-blocking layer) over the light-emitting layer. Alternatively, the EL layer 113 preferably includes a light-emitting layer, a carrier-blocking layer over the light-emitting layer, and a carrier-transport layer over the carrier-blocking layer. Since the surface of the EL layer 113 is exposed in the manufacturing process of the display device, providing one or both of the carrier-transport layer and the carrier-blocking layer over the light-emitting layer inhibits the light-emitting layer from being exposed on the outermost surface, so that damage to the light-emitting layer can be reduced. As a result, the reliability of the light-emitting element can be improved.

The upper temperature limits of the compounds contained in the EL layer 113 are each preferably higher than or equal to 100° C. and lower than or equal to 180° C. or higher than or equal to 120° C. and lower than or equal to 180° C., further preferably higher than or equal to 140° C. and lower than or equal to 180° C. For example, the glass transition point (Tg) of these compounds is preferably higher than or equal to 100° C. and lower than or equal to 180° C. or higher than or equal to 120° C. and lower than or equal to 180° C., further preferably higher than or equal to 140° C. and lower than or equal to 180° C.

In particular, the upper temperature limits of the functional layers provided over the light-emitting layer are preferably high. It is further preferable that the upper temperature limit of the functional layer provided over and in contact with the light-emitting layer be high. When such a functional layer has high heat resistance, the light-emitting layer can be effectively protected, resulting in less damage to the light-emitting layer.

In addition, the upper temperature limit of the light-emitting layer is preferably high. In this case, the light-emitting layer can be inhibited from being damaged by heating and being decreased in emission efficiency and lifetime.

The light-emitting layer contains a light-emitting substance (also referred to as a light-emitting organic compound, a guest material, or the like) and an organic compound (also referred to as a host material or the like). Since the light-emitting layer contains more organic compound than light-emitting substance, Tg of the organic compound can be used as an indicator of the upper temperature limit of the light-emitting layer.

The EL layer 113 includes a first light-emitting unit, a charge-generation layer, and a second light-emitting unit, for example.

The second light-emitting unit preferably includes a light-emitting layer and a carrier-transport layer (an electron-transport layer or a hole-transport layer) over the light-emitting layer. Alternatively, the second light-emitting unit preferably includes a light-emitting layer and a carrier-blocking layer (a hole-blocking layer or an electron-blocking layer) over the light-emitting layer. Alternatively, the second light-emitting unit preferably includes a light-emitting layer, a carrier-blocking layer over the light-emitting layer, and a carrier-transport layer over the carrier-blocking layer. A surface of the second light-emitting unit is exposed in the manufacturing process of the display device; providing one or both of the carrier-transport layer and the carrier-blocking layer over the light-emitting layer inhibits the light-emitting layer from being exposed on the outermost surface, so that damage to the light-emitting layer can be reduced. As a result, the reliability of the light-emitting element can be improved. Note that in the case where three or more light-emitting units are provided, the uppermost light-emitting unit preferably includes a light-emitting layer and one or both of a carrier-transport layer and a carrier-blocking layer over the light-emitting layer.

The common layer 114 can be provided over the EL layer 113. The common layer 114 is shared by the light-emitting element 130a, the light-emitting element 130b, and the light-emitting element 130c. The common layer 114 includes an electron-injection layer or a hole-injection layer, for example. The common layer 114 includes an electron-transport layer or a hole-transport layer, for example. Alternatively, the common layer 114 may include a stack of an electron-transport layer and an electron-injection layer, or may include a stack of a hole-transport layer and a hole-injection layer, for example.

The common electrode 115 is provided over the common layer 114. The common electrode 115 is shared by the light-emitting element 130a, the light-emitting element 130b, and the light-emitting element 130c. The common electrode 115 can be formed by a sputtering method or a vacuum evaporation method, for example.

As illustrated in FIG. 1B, the common electrode 115 shared by the plurality of light-emitting elements 130 is electrically connected to the conductive layer 123 provided in the connection portion 140. The conductive layer 123 is preferably formed using a conductive layer formed using the same material and in the same step as the pixel electrode 111a, the pixel electrode 111b, and the pixel electrode 111c.

Note that the insulating layer 105 is provided between the conductive layer 123 and the insulating layer 101. The insulating layer 105 can be an insulating layer formed using the same material and in the same step as the insulating layer 103a, the insulating layer 103b, and the insulating layer 103c. Like the insulating layer 103a, the insulating layer 103b, and the insulating layer 103c, the insulating layer 105 can have a projecting portion.

In the connection portion 140, the conductive layer 123 is electrically connected to the common electrode 115. The conductive layer 123 is electrically connected to an FPC (not illustrated), for example. Accordingly, by supplying a power supply potential to the FPC, for example, the power supply potential can be supplied to the common electrode 115 through the conductive layer 123 in the connection portion 140. Consequently, in the case where the common electrode 115 functions as a cathode, the connection portion 140 can be referred to as a cathode contact portion.

Here, in the case where the electric resistance of the common layer 114 in the thickness direction is low enough to be negligible, electrical continuity between the conductive layer 123 and the common electrode 115 can be maintained even when the common layer 114 is provided between the conductive layer 123 and the common electrode 115. When the common layer 114 is provided not only in the display portion but also in the connection portion 140, the common layer 114 can be formed, for example, without using a metal mask such as a mask for specifying a deposition area (also referred to as an area mask or a rough metal mask to be distinguished from a fine metal mask). Thus, the manufacturing process of the display device 100 can be simplified.

Note that in the connection portion 140, the conductive layer 123 and the common electrode 115 may be in direct contact with each other to be electrically connected to each other without providing the common layer 114 over the conductive layer 123. For example, when an area mask for determining a region where the common layer 114 is formed is used, the common layer 114 can be formed only in a desired region.

The common electrode 115 can be formed successively without a process such as etching between formations of the common layer 114 and the common electrode 115. For example, after the common layer 114 is formed in a vacuum, the common electrode 115 can be formed in a vacuum without exposing the substrate 102 to the air. In other words, the common layer 114 and the common electrode 115 can be successively formed in a vacuum. Accordingly, the lower surface of the common electrode 115 can be a clean surface, as compared with the case where the common layer 114 is not provided in the display device 100. Thus, the light-emitting element 130 can have high reliability and favorable characteristics.

As a material used for the pixel electrode 111 and the common electrode 115, a metal, an alloy, an electrically conductive compound, a mixture thereof, and the like can be used as appropriate to for a single layer or a stacked layer. Specific examples of the material include indium tin oxide (In—Sn oxide, also referred to as ITO), In—Si—Sn oxide (also referred to as ITSO), indium zinc oxide (In—Zn oxide), indium gallium zinc oxide (In—Ga—Zn oxide, also referred to as IGZO), and In—W—Zn oxide. Other examples include an alloy of silver and magnesium and an alloy of silver, palladium, and copper (Ag—Pd—Cu, also referred to as APC). Moreover, an alloy containing aluminum (aluminum alloy) such as an alloy of aluminum, nickel, and lanthanum (Al—Ni—La) can be given. In addition, it is possible to use a metal such as aluminum (Al), magnesium (Mg), titanium (Ti), chromium (Cr), manganese (Mn), iron (Fe), cobalt (Co), nickel (Ni), copper (Cu), gallium (Ga), zinc (Zn), indium (In), tin (Sn), molybdenum (Mo), tantalum (Ta), tungsten (W), palladium (Pd), gold (Au), platinum (Pt), silver (Ag), yttrium (Y), or neodymium (Nd) or an alloy containing an appropriate combination of any of these metals. It is also possible to use an element belonging to Group 1 or Group 2 of the periodic table, which is not described above (e.g., lithium (Li), cesium (Cs), calcium (Ca), or strontium (Sr)), a rare earth metal such as europium (Eu) or ytterbium (Yb), an alloy containing an appropriate combination of any of these, graphene, or the like.

The side surface of the EL layer 113 is covered with the insulating layer 141. Furthermore, a structure in which the side surface of the pixel electrode 111, the side surface of the insulating layer 103, the top surface (also referred to as a bottom surface) and the side surface of the depressed portion 108 in the insulating layer 101, the top surface and the side surface of the organic layer 119, and the top surface and the side surface of the conductive layer 123, the side surface of the insulating layer 105 are covered with the insulating layer 141 can be employed. Furthermore, a structure in which part of the top surface of the EL layer 113 is covered with the insulating layer 141 can be employed.

The insulating layer 143 is provided over the insulating layer 141 and is provided between adjacent EL layers 113. The insulating layer 143 can be provided between adjacent pixel electrodes 111. In some cases, the insulating layer 143 is provided between adjacent insulating layers 103. The insulating layer 143 is provided around the conductive layer 123 and the insulating layer 105.

The insulating layer 143 includes a region overlapping with the depressed portion 108. The insulating layer 143 can include a region overlapping with the organic layer 119. Note that the insulating layer 141 and the insulating layer 143 can overlap with part of the top surface of the EL layer 113.

The common layer 114 and the common electrode 115 are provided not only over the light-emitting element 130 but also over the insulating layer 143. When the insulating layer 143 is provided between adjacent EL layers 113 and the common layer 114 and the common electrode 115 are provided over the insulating layer 143, a surface where the common layer 114 and the common electrode 115 are formed can be inhibited from having large unevenness and can be planarized. Thus, the coverage with the common layer 114 and the common electrode 115 can be increased compared with the case where the insulating layer 143 is not provided. Therefore, a connection defect due to disconnection of the common layer 114 and the common electrode 115 and an increase in electric resistance due to local thinning, for example, can be prevented.

When at least one of the insulating layer 141 and the insulating layer 143 is provided between adjacent EL layers 113, the common layer 114 and the common electrode 115 can be prevented from being in contact with the side surface of the EL layer 113 and a short circuit of the light-emitting element 130 can be prevented. Thus, the display device 100 can be a highly reliable display device.

The insulating layer 141 is preferably in contact with the side surface of the EL layer 113. Accordingly, separation of the EL layer 113 can be inhibited. When the insulating layer 141 and the EL layer 113 are in close contact with each other, an effect of fixing adjacent EL layers 113 by or attaching adjacent EL layers 113 to the insulating layer 141 can be attained. Thus, the display device 100 can be a highly reliable display device. Moreover, the display device 100 can be manufactured by a method with a high yield.

In this structure, the insulating layer 141 is preferably formed by a method enabling formation of a film with high coverage, for example an atomic layer deposition (ALD) layer. Accordingly, the insulating layer 141 can favorably cover the bottom surface of the projecting portion of the insulating layer 103 overlapping with the depressed portion 108 and the side surface of the depressed portion 108, for example. Thus, a reduction in the width W of the projecting portion of the insulating layer 103 can be inhibited as compared with the case where the insulating layer 141 is formed by a method for forming a film with low coverage. Although FIG. 2A shows a structure example in which the insulating layer 141 is in contact with the side surface of the depressed portion 108, a structure in which the insulating layer 141 is not in contact with the side surface of the depressed portion 108 may be employed. For example, when the width W of the projecting portion of the insulating layer 103 is large, the insulating layer 141 is not in contact with the side surface of the depressed portion 108 in some cases.

Note that in the display device 100, the insulating layer 143 is provided over the insulating layer 141 to fill the depressed portion formed in the insulating layer 141. The insulating layer 143 is provided between the island-shaped EL layers 113. In other words, the display device 100 employs a process (hereinafter referred to as a process 1) in which the island-shaped EL layer 113 is formed and then the insulating layer 143 is formed to overlap with an end portion of the island-shaped EL layer 113. As a process different from the process 1, there is a process (hereinafter referred to as a process 2) in which the pixel electrode 111 is formed to have an island shape, an insulating layer that covers an end portion of the pixel electrode 111 is formed, and then an island-shaped EL layer is formed over the pixel electrode and the insulating layer.

The above process 1 is preferable to the above process 2 because of having a wider margin. Specifically, the process 1 has a wider margin with respect to alignment accuracy between different patterning steps than the process 2 and can provide a display device with few variations. The method for manufacturing the display device 100 is based on the above process 1 and thus, display devices with few variations and high display quality can be provided.

In the connection portion 140, the insulating layer 141 is provided to cover at least part of the side surface of the conductive layer 123. The insulating layer 141 can be provided to cover the side surface of the insulating layer 105. The insulating layer 143, the common layer 114, and the common electrode 115 are provided over the insulating layer 141.

Next, an example of materials for the insulating layer 141 and the insulating layer 143 is described.

The insulating layer 141 can be an insulating layer including an inorganic material. That is, the insulating layer 141 can be an inorganic insulating layer. As the insulating layer 141, an inorganic insulating film such as an oxide insulating film, a nitride insulating film, an oxynitride insulating film, or a nitride oxide insulating film can be used, for example. The insulating layer 141 may have a single-layer structure or a stacked-layer structure. Examples of the oxide insulating film include a silicon oxide film, an aluminum oxide film, a magnesium oxide film, an indium gallium zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. Aluminum oxide is particularly preferable because it has high selectivity with the EL layer in etching and has a function of protecting the EL layer in forming the insulating layer 143 which is to be described later. An inorganic insulating film such as an aluminum oxide film, a hafnium oxide film, or a silicon oxide film is formed by an ALD method as the insulating layer 141, whereby the insulating layer 141 can have few pinholes and an excellent function of protecting the EL layer 113. The insulating layer 141 may have a stacked-layer structure of a film formed by an ALD method and a film formed by a sputtering method. For example, the insulating layer 141 may have a stacked-layer structure of an aluminum oxide film formed by an ALD method and a silicon nitride film formed by a sputtering method.

The insulating layer 141 preferably has a function of a barrier insulating layer against at least one of water and oxygen. Alternatively, the insulating layer 141 preferably has a function of inhibiting diffusion of at least one of water and oxygen. Alternatively, the insulating layer 141 preferably has a function of capturing or fixing (also referred to as gettering) at least one of water and oxygen.

Note that in this specification and the like, a barrier insulating layer refers to an insulating layer having a barrier property. A barrier property in this specification and the like refers to a function of inhibiting diffusion of a particular substance (also referred to as having low permeability). Alternatively, a barrier property refers to a function of capturing or fixing (also referred to as gettering) a particular substance.

When the insulating layer 141 has a function of a barrier insulating layer, entry of impurities (typically, at least one of water and oxygen) which might diffuse into the light-emitting elements 130 from the outside can be inhibited. With this structure, a highly reliable light-emitting element and a highly reliable display device can be provided.

The insulating layer 141 preferably has a low impurity concentration. In this case, deterioration of the EL layer 113 due to entry of impurities from the insulating layer 141 into the EL layer 113 can be inhibited. In addition, when having a low impurity concentration, the insulating layer 141 can have a high barrier property against at least one of water and oxygen. For example, the insulating layer 141 preferably has one of a sufficiently low hydrogen concentration and a sufficiently low carbon concentration, desirably has both of them.

An insulating layer including an organic material can be suitably used for the insulating layer 143. That is, the insulating layer 143 can be an organic insulating layer. As the organic material, a photosensitive material such as a photosensitive organic resin is preferably used, and for example, a photosensitive resin composition containing an acrylic resin is preferably used. Note that in this specification and the like, an acrylic resin refers to not only a polymethacrylic acid ester or a methacrylic resin, but also all the acrylic polymer in a broad sense in some cases.

For the insulating layer 143, an acrylic resin, a polyimide resin, an epoxy resin, an imide resin, a polyamide resin, a polyimide-amide resin, a silicone resin, a siloxane resin, a benzocyclobutene-based resin, a phenol resin, precursors of these resins, or the like may be used. For the insulating layer 143, an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin may be used. A photoresist may be used for the photosensitive resin. As the photosensitive organic resin, either a positive material or a negative material may be used.

The insulating layer 143 may be formed using a material absorbing visible light. When the insulating layer 143 absorbs light emitted from the light-emitting element 130, leakage of light from the light-emitting element 130 to the adjacent light-emitting element 130 through the insulating layer 143 (stray light) can be inhibited. Thus, the display quality of the display device can be improved. Since no polarizing plate is required to improve the display quality of the display device, the weight and thickness of the display device can be reduced.

Examples of the material absorbing visible light include materials containing pigment of black or the like, materials containing dye, light-absorbing resin materials (e.g., polyimide), and a resin material that can be used for color filters (color filter materials). Using a resin material obtained by stacking or mixing color filter materials of two or three or more colors is particularly preferred to enhance the effect of blocking visible light. In particular, mixing color filter materials of three or more colors enables the formation of a black or nearly black resin layer.

The material used for the insulating layer 143 preferably has a low volume shrinkage rate. In this case, the insulating layer 143 can be easily formed into a desired shape. In addition, the insulating layer 143 preferably has a low volume shrinkage rate after being cured. In this case, the shape of the insulating layer 143 can be easily maintained in a variety of steps after formation of the insulating layer 143. Specifically, the volume shrinkage rate of the insulating layer 143 after thermal curing, after light curing, or after light curing and thermal curing is preferably lower than or equal to 10%, further preferably lower than or equal to 5%, still further preferably lower than or equal to 1%. Here, as the volume shrinkage rate, one of the rate of volume shrinkage by light irradiation and the rate of volume shrinkage by heating, or the sum of these rates can be used.

The protective layer 131 is preferably provided over the light-emitting element 130a, the light-emitting element 130b, and the light-emitting element 130c. Providing the protective layer 131 can increase the reliability of the light-emitting element 130. The protective layer 131 may have a single-layer structure or a stacked-layer structure of two or more layers.

There is no limitation on the conductivity of the protective layer 131. For the protective layer 131, at least one of an insulating material, a semiconductor material, and a conductive material can be used.

The protective layer 131 including an inorganic material can inhibit deterioration of the light-emitting element 130 by preventing oxidation of the common electrode 115 and inhibiting entry of impurities (e.g., moisture and oxygen) into the light-emitting element 130, for example; thus, the reliability of the display device 100 can be improved.

For the protective layer 131, an inorganic film containing an oxide, a nitride, an oxynitride, or a nitride oxide can be used, for example. Specific examples of the materials are as listed in the description of the insulating layer 103. In particular, the protective layer 131 preferably includes a nitride or a nitride oxide.

For the protective layer 131, an inorganic material containing In—Sn oxide (also referred to as ITO), In—Zn oxide, Ga—Zn oxide, Al—Zn oxide, indium gallium zinc oxide (In—Ga—Zn oxide, also referred to as IGZO), or the like can also be used. The inorganic material preferably has high resistance, specifically, higher resistance than the common electrode 115. The inorganic material may further contain nitrogen.

When light emitted from the light-emitting element 130 is extracted through the protective layer 131, the protective layer 131 preferably has a high visible-light-transmitting property. For example, ITO, IGZO, and aluminum oxide are preferable because they are each an inorganic material having a high visible-light-transmitting property.

The protective layer 131 can employ, for example, a stacked-layer structure of an aluminum oxide film and a silicon nitride film over the aluminum oxide film, or a stacked-layer structure of an aluminum oxide film and an IGZO film over the aluminum oxide film. The use of such a stacked-layer structure can inhibit diffusion of impurities (such as water and oxygen) to the EL layer 113 side.

The protective layer 135 has a function of a planarization layer. For example, an organic material can be used for the protective layer 135. As an organic material which can be used for the protective layer 135, an acrylic resin, a polyimide resin, an epoxy resin, an imide resin, a polyamide resin, a polyimide-amide resin, a silicone resin, a siloxane resin, a benzocyclobutene-based resin, a phenol resin, precursors of these resins, or the like may be used, for example.

When the protective layer 135 is provided over the protective layer 131, the coloring layer 132 can be provided on a flat surface. This makes it easy to form the coloring layer 132.

A light-blocking layer may be provided on the surface of the substrate 120 on the adhesive layer 122 side. A variety of optical members can be provided on the outer surface of the substrate 120. Examples of the optical members include a polarizing plate, a retardation plate, a light diffusion layer (a diffusion film or the like), an anti-reflective layer, and a light-condensing film. Furthermore, an antistatic film inhibiting the attachment of dust, a water repellent film inhibiting the attachment of stain, a hard coat film inhibiting generation of a scratch caused by the use, an impact-absorbing layer, or the like may be provided as a surface protective layer on the outer surface of the substrate 120. For example, a glass layer or a silica layer (SiOₓ layer) is preferably provided as the surface protective layer, in which case surface contamination and damage can be prevented from being generated. The surface protective layer may be formed using DLC (diamond like carbon), aluminum oxide (AlOₓ), a polyester-based material, a polycarbonate-based material, or the like. For the surface protective layer, a material having a high visible light transmittance is preferably used. For the surface protective layer, a material with high hardness is preferably used.

In the case where a circularly polarizing plate overlaps with the display device 100, a highly optically isotropic substrate is preferably used as the substrate included in the display device 100. A highly optically isotropic substrate can be referred to as a substrate with a low birefringence (in other words, a small amount of birefringence).

The absolute value of a retardation (phase difference) of a highly optically isotropic substrate is preferably less than or equal to 30 nm, further preferably less than or equal to 20 nm, still further preferably less than or equal to 10 nm.

Examples of a highly optically isotropic film include a triacetyl cellulose (TAC, also referred to as cellulose triacetate) film, a cycloolefin polymer (COP) film, a cycloolefin copolymer (COC) film, and an acrylic film.

When a film is used for the substrate and the film absorbs water, the shape of the display device 100 might be changed, e.g., creases are generated. Thus, for the substrate, a film with a low water absorption rate is preferably used. For example, a film with a water absorption rate lower than or equal to 1% is preferably used, a film with a water absorption rate lower than or equal to 0.1% is further preferably used, and a film with a water absorption rate lower than or equal to 0.01% is still further preferably used.

For the adhesive layer 122, a variety of curable adhesives, e.g., a photocurable adhesive such as an ultraviolet curable adhesive, a reactive curable adhesive, a thermosetting adhesive, and an anaerobic adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferable. Alternatively, a two-liquid-mixture-type resin may be used. An adhesive sheet may be used, for example.

FIG. 1B illustrates an example in which the coloring layer 132a, the coloring layer 132b, and the coloring layer 132c are directly provided over the light-emitting element 130a, the light-emitting element 130b, and the light-emitting element 130c with the protective layer 131 and the protective layer 135 therebetween. With such a structure, the alignment accuracy of the light-emitting element 130 and the coloring layer 132 can be improved. The distance between the light-emitting element 130 and the coloring layer 132 is reduced, so that color mixture can be inhibited and the viewing angle characteristics can be improved, which is preferable.

Although each of the pixel electrode 111a and the pixel electrode 111b in FIG. 2A has a single-layer structure, one embodiment of the present invention is not limited to this structure. FIG. 2B illustrates an example in which each of the pixel electrode 111a and the pixel electrode 111b has a stacked structure with three layers. Note that each of the pixel electrode 111c and the conductive layer 123 can have a structure similar to those of the pixel electrode 111a and the pixel electrode 111b.

In the example illustrated in FIG. 2B, the pixel electrode 111a includes a pixel electrode 111a1, a pixel electrode 111a2 over the pixel electrode 111a1, and a pixel electrode 111a3 over the pixel electrode 111a1 and the pixel electrode 111a2. The pixel electrode 111a3 can cover the top surface and the side surface of the pixel electrode 111a2. In the above manner, the pixel electrode 111a2 can have a structure covered with the pixel electrode 111a1 and the pixel electrode 111a3. Similarly, the pixel electrode 111b includes a pixel electrode 111b1, a pixel electrode 111b2 over the pixel electrode 111b1, and a pixel electrode 111b3 over the pixel electrode 111b1 and the pixel electrode 111b2, and the pixel electrode 111b2 can have a structure covered with the pixel electrode 111b1 and the pixel electrode 111b3.

Examples of materials used for the pixel electrode 111a1, the pixel electrode 111a2, and the pixel electrode 111a3 included in the pixel electrode 111a are described below. Note that the pixel electrode 111b1 can be formed using a material similar to that of the pixel electrode 111a1, the pixel electrode 111b2 can be formed using a material similar to that of the pixel electrode 111a2, and the pixel electrode 111b3 can be formed using a material similar to that of the pixel electrode 111a3. The pixel electrode 111c and the conductive layer 123 can also be formed using a material similar to that described below.

The pixel electrode 111a2 is a layer with a visible light reflectance (e.g., reflectance with respect to light with a predetermined wavelength in a range greater than or equal to 380 nm and less than or equal to 780 nm) higher than those of the pixel electrode 111a1 and the pixel electrode 111a3. The visible light reflectance of the pixel electrode 111a2 can be, for example, higher than or equal to 40% and lower than or equal to 100%, and is preferably higher than or equal to 60% and lower than or equal to 100%, further preferably higher than or equal to 80% and lower than or equal to 100%. A metal or an alloy can be used for the pixel electrode 111a2, for example. Specifically, for the pixel electrode 111a2, silver or an alloy containing silver can be used, for example. As the alloy containing silver, an alloy containing silver, palladium, and copper (APC), for example, can be used. For the pixel electrode 111a2, aluminum or an alloy containing aluminum can be used, for example. As the alloy containing aluminum, an alloy of aluminum, nickel, and lanthanum can be used, for example. Consequently, the display device 100 can be a display device with high light extraction efficiency.

When the insulating layer 103a is in contact with the pixel electrode 111a2 including the above material, film peeling of the pixel electrode 111a2 might be generated. Thus, the pixel electrode 111a1 whose adhesion to the insulating layer 103a is higher than that of the pixel electrode 111a2 is provided between the insulating layer 103a and the pixel electrode 111a2. This can inhibit peeling of the pixel electrode 111a. Accordingly, the display device 100 can be a highly reliable display device. The structure can be employed in which the pixel electrode 111a1 is in contact with the insulating layer 103a and the pixel electrode 111a2 is not in contact with the insulating layer 103a, as illustrated in FIG. 2B.

For the pixel electrode 111a1, an oxide containing one or more selected from indium, tin, zinc, gallium, titanium, aluminum, and silicon can be used. For example, it is preferable to use a conductive oxide containing one or more of indium oxide, indium tin oxide, indium zinc oxide, zinc oxide, zinc oxide containing gallium, titanium oxide, indium titanium oxide, zinc titanate, aluminum zinc oxide, indium zinc oxide containing gallium, indium zinc oxide containing aluminum, indium tin oxide containing silicon, indium zinc oxide containing silicon, and the like.

The pixel electrode 111a3 is a layer having a high work function when the pixel electrode 111a functions as an anode, i.e., the pixel electrode 111a3 is in contact with the hole-injection layer or the hole-transport layer provided in the EL layer 113. The pixel electrode 111a3 is, for example, a layer having a higher work function than the pixel electrode 111a2. This facilitates injection of holes into the hole-injection layer or a hole-transport layer, for example, so that the driving voltage of the light-emitting element 130 can be lowered. For the pixel electrode 111a3, a material similar to the material that can be used for the pixel electrode 111a1 can be used, for example. For example, one kind of material can be used for the pixel electrode 111a1 and the pixel electrode 111a3. For example, in the case where indium tin oxide is used for the pixel electrode 111a1, indium tin oxide can also be used for the pixel electrode 111a3.

Note that the pixel electrode 111a3 is a layer having a low work function when the pixel electrode 111a function as a cathode, i.e., the pixel electrode 111a3 is in contact with the electron-injection layer or the electron-transport layer provided in the EL layer 113, for example. The pixel electrode 111a3 is, for example, a layer having a lower work function than the pixel electrode 111a2. This facilitates injection of electrons into the electron-injection layer or the electron-transport layer, for example, so that the driving voltage of the light-emitting element 130 can be lowered.

The pixel electrode 111a3 is preferably a layer having a high visible light transmittance (e.g., transmittance with respect to light with a predetermined wavelength in a range greater than or equal to 380 nm and less than or equal to 780 nm). For example, the visible light transmittance of the pixel electrode 111a3 is preferably higher than that of the pixel electrode 111a2. The visible light transmittance of the pixel electrode 111a3 can be, for example, greater than or equal to 60% and less than or equal to 100%, and is preferably higher than or equal to 70% and lower than or equal to 100%, further preferably higher than or equal to 80% and lower than or equal to 100%. Accordingly, the amount of light absorbed by the pixel electrode 111a3 among light emitted from the EL layer 113 can be reduced. As described above, the pixel electrode 111a2 under the pixel electrode 111a3 can be a layer having a high visible light reflectance. Thus, the display device 100 can have high light extraction efficiency.

Note that the pixel electrode 111a2 is a layer having a high reflectance with respect to light emitted from the EL layer 113, and the pixel electrode 111a3 is a layer having a high transmittance with respect to light emitted from the EL layer 113. For example, in the case where the EL layer 113 emits infrared light, the pixel electrode 111a2 is a layer having a high reflectance with respect to infrared light, and the pixel electrode 111a3 is a layer having a high transmittance with respect to infrared light. For example, in the case where the EL layer 113 emits infrared light, “visible light” in the above description of the pixel electrode 111a2 and the pixel electrode 111a3 can be replaced with “infrared light.”

Thus, the display device 100 can have high reliability and high light extraction efficiency. In addition, the display device 100 can include a light-emitting element with low driving voltage.

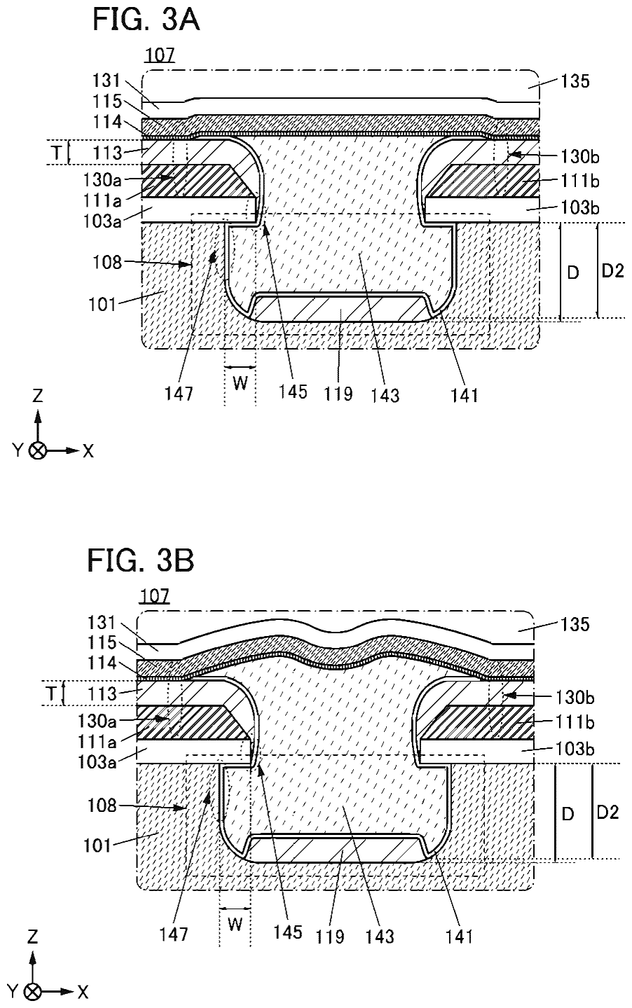

For example, in FIG. 2A, the top surface of the insulating layer 143 has a convex shape when seen from the XZ plane; however, one embodiment of the present invention is not limited thereto. FIG. 3A illustrates an example in which the top surface of the insulating layer 143 is flat when seen from the XZ plane.

When the top surface of the insulating layer 143 is flat, coverage of the insulating layer 143 with the common layer 114 and the common electrode 115 can be improved. Thus, for example, a connection defect due to disconnection of the common layer 114 and the common electrode 115 and an increase in electric resistance due to local thinning can be suitably prevented.

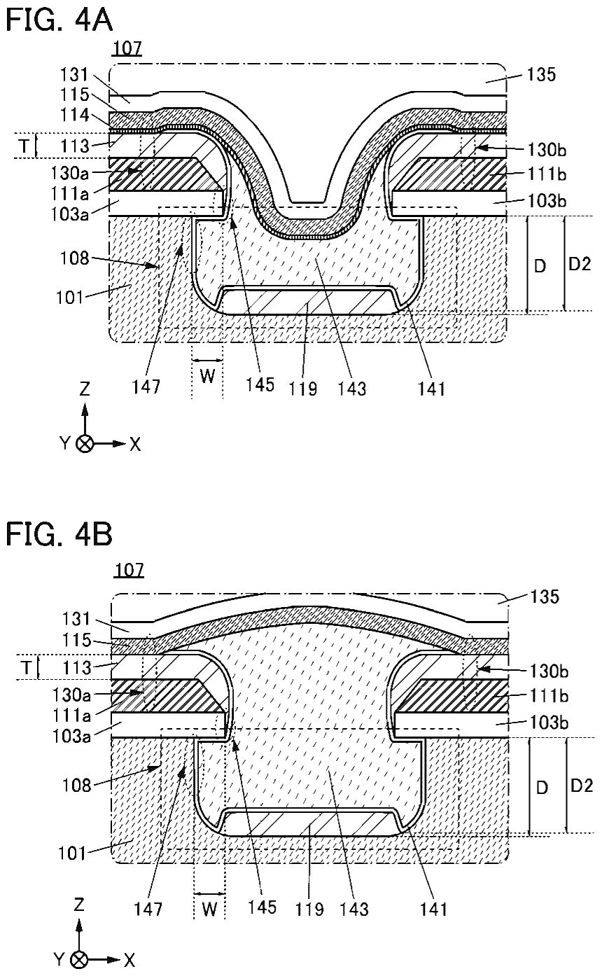

FIG. 3B illustrates an example in which the insulating layer 143 has two convex surfaces when seen from the XZ plane, and a concave surface is provided between the two convex surfaces. FIG. 4A illustrates an example in which the top surface of the insulating layer 143 has a concave shape. The example illustrated in FIG. 4A shows that the common layer 114 and the common electrode 115 are got into a space between adjacent EL layers 113. Even in such a structure, the coverage with the common layer 114 and the common electrode 115 can be increased compared with the case where the insulating layer 143 is not provided.

FIG. 4B illustrates an example in which the common layer 114 is not provided. The example illustrated in FIG. 4B shows that the common electrode 115 includes a region in contact with the EL layer 113 and the insulating layer 143. When the common layer 114 is not provided, the manufacturing process of the display device can be simplified.

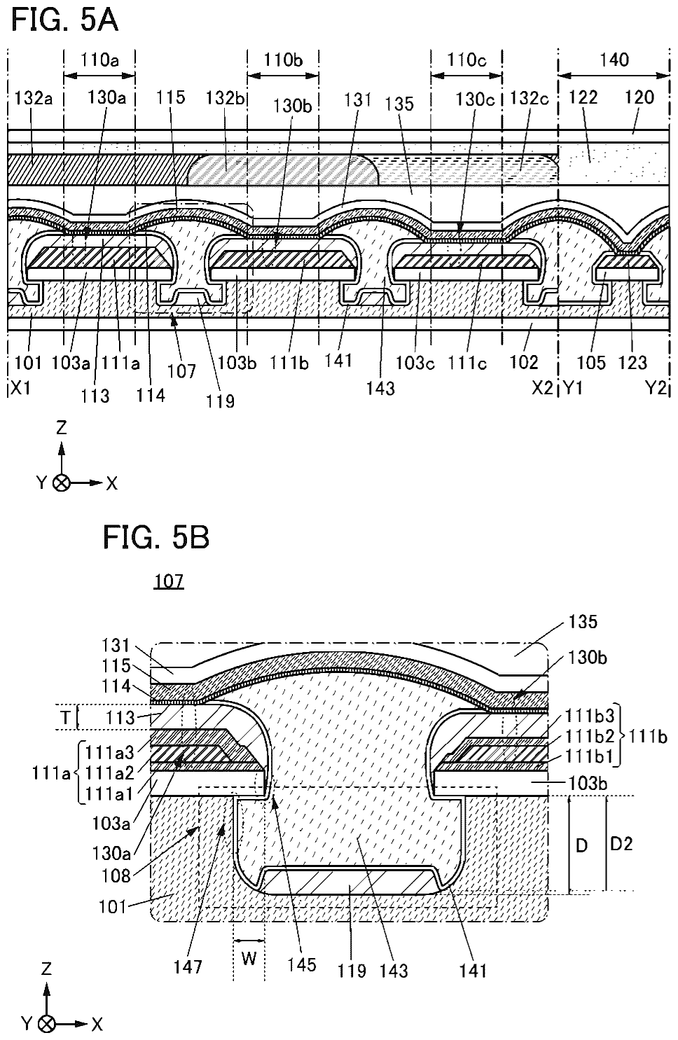

FIG. 5A is a cross-sectional view along dashed-dotted line X1-X2 and dashed-dotted line Y1-Y2 in FIG. 1A, which shows a structure example different from that in FIG. 1B. FIG. 5B is an enlarged view of the region 107 illustrated in FIG. 5A.

The structure illustrated in FIG. 5A and FIG. 5B is different from the structures illustrated in FIG. 1B, FIG. 2A, and FIG. 2B mainly in that the thicknesses of the pixel electrode 111a, the pixel electrode 111b, and the pixel electrode 111c are different from each other. Although the thickness of the conductive layer 123 is equal to or substantially equal to the thickness of the pixel electrode 111c in FIG. 5A, the thickness of the conductive layer 123 may be equal to or substantially equal to the pixel electrode 111a or the pixel electrode 111b. As illustrated in FIG. 5B, the pixel electrode 111 can have a structure similar to that in FIG. 2B.

The display device illustrated in FIG. 5A and FIG. 5B employs a microcavity structure. One of a pair of electrodes of the light-emitting element 130 is, for example, an electrode having properties of transmitting and reflecting visible light (a transflective electrode), and the other is, for example, an electrode having a property of reflecting visible light (a reflective electrode). When the light-emitting element 130 has a microcavity structure, light obtained from the light-emitting layer can be resonated between the electrodes, whereby light emitted from the light-emitting device 130 can be intensified. In addition, emission intensity of light with a specific wavelength can be increased, so that the color purity can be increased. Light (monochromatic light) with different wavelengths can be extracted even if the EL layers 113 with the same structure are included. Furthermore, the emission intensity of light with a specific wavelength in the front direction can be increased, whereby power consumption can be reduced. Note that in the case where the color purity of light emitted from the light-emitting element 130 is sufficiently increased by the microcavity structure, the coloring layer 132 can be omitted in some cases.

In the display device of one embodiment of the present invention, the EL layers 113 included in the light-emitting device 130a, the light-emitting device 130b, and the light-emitting device 130c are formed using the same material in the same step; thus, the thicknesses of the EL layers 113 are equal or substantially equal to each other. Furthermore, a reflective electrode is used for the pixel electrode 111a2, the pixel electrode 111b2, and the like illustrated in FIG. 5B, and a visible-light-transmitting electrode (a transparent electrode) is used for the pixel electrode 111a3, the pixel electrode 111b3, and the like. Accordingly, when the thickness of the pixel electrode 111a3 is different from the thickness of the pixel electrode 111b3, for example, the optical path length of light emitted from the EL layer 113 included in the light-emitting element 130a and the optical path length of light emitted from the EL layer 113 included in the light-emitting element 130b can be different from each other. Specifically, the thickness of the pixel electrode 111a3 is preferably adjusted so that the distance between the top surface of the pixel electrode 111a2 and the bottom surface of the common electrode 115 is mλₐ/2 (m is an integer greater than or equal to 1) or close thereto, for example, in order to extract light with a wavelength λₐ from the subpixel 110a. The thickness of the pixel electrode 111b3 is preferably adjusted so that the distance between the top surface of the pixel electrode 111b2 and the bottom surface of the common electrode 115 is mλ_{b}/J2 or close thereto, for example, in order to extract light with a wavelength λ_{b} from the subpixel 110b. As a result, the color purity of light extracted from the subpixel 110a and the subpixel 110b can be increased. Note that when the pixel electrode 111c also has a structure in which a transparent electrode is provided over a reflective electrode and the thickness of the transparent electrode is adjusted, the color purity of light extracted from the subpixel 110c can be increased.

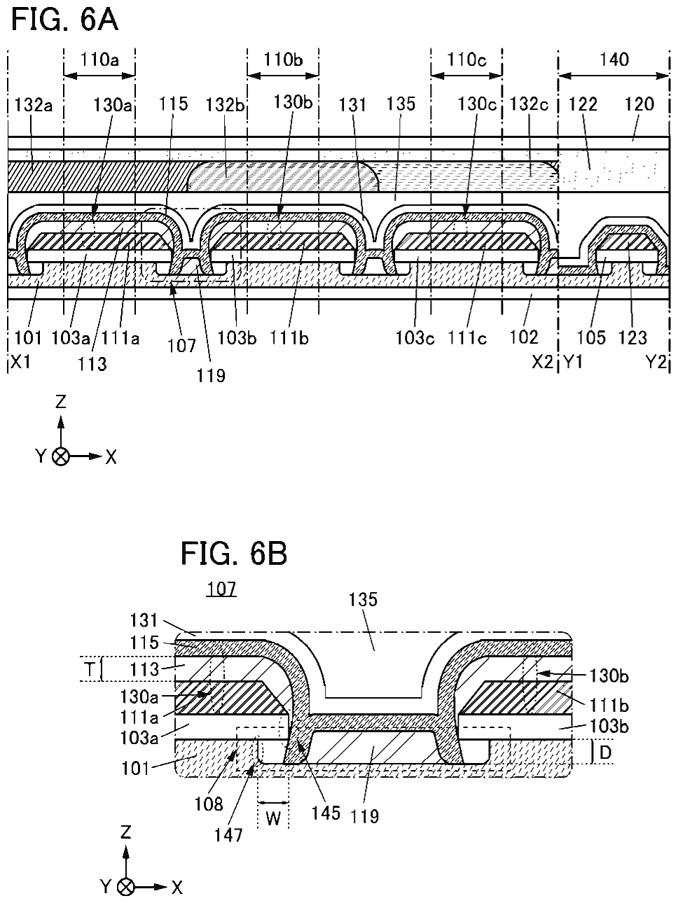

FIG. 6A is a cross-sectional view along dashed-dotted line X1-X2 and dashed-dotted line Y1-Y2 in FIG. 1A, which shows a structure example different from that in FIG. 1B. FIG. 6B is an enlarged view of the region 107 illustrated in FIG. 6A.

The structure illustrated in FIG. 6A and FIG. 6B is different from the structure illustrated in FIG. 1B and FIG. 2A mainly in that the insulating layer 141, the insulating layer 143, and the common layer 114 are omitted. The common layer 114 may not be provided. The insulating layer 141 may be provided.

When the display device 100 has the structure illustrated in FIG. 6A, the manufacturing process of the display device 100 can be simplified. In addition, the aperture ratio of the display device 100 can be increased.

Meanwhile, in the structure illustrated in FIG. 6A and FIG. 6B, the common electrode 115 is in contact with the side surface of the EL layer 113 in some cases. Here, assuming that the EL layer 113 has a tandem structure including a plurality of light-emitting units and a charge-generation layer between the light-emitting units, some light-emitting units are hindered from emitting light by a short circuit in some cases when the common electrode 115 is in contact with the charge-generation layer. For example, in the case where the EL layer 113 includes a first light-emitting unit, a charge-generation layer over the first light-emitting unit, and a second light-emitting unit over the charge-generation layer, a short circuit may be caused between the charge-generation layer and the common electrode 115 when the common electrode 115 is in contact with the charge-generation layer. Accordingly, the second light-emitting unit is not fed with current and does not emit light in some cases.

From the above, the light-emitting element 130 preferably has a single structure when the structure illustrated in FIG. 6A and FIG. 6B is used for the light-emitting device 100. Thus, the display device 100 can be a highly reliable display device.

In the case where the projecting portion of the insulating layer 103 has a too large width W in the display device 100 employing the structure illustrated in FIG. 6A and FIG. 6B, disconnection may be generated in the common electrode 115. In the case where the depth D of the depressed portion 108 is too deep, disconnection may be generated in the common electrode 115. When disconnection is generated in the common electrode 115, voltage is not applied to the EL layer 113 and the light-emitting element 130 does not emit light in some cases. Thus, the width W of the projection portion of the insulating layer 103 and the depth D of the depressed portion 108 are adjusted so that disconnection is not generated in the common electrode 115 while disconnection is made in the EL layer 113.

The common electrode 115 can be formed, for example, by a method, such as a sputtering method or a vacuum evaporation method, which is for forming a film with lower coverage than that of a film formed by an ALD method. In such a case, the common electrode 115 is not in contact with the side surface of the depressed portion 108 as illustrated in FIG. 6A and FIG. 6B; a gap is formed between the side surface of the depressed portion 108 and the common electrode 115 in some cases. Furthermore, the common electrode 115 is not provided in a region of the depressed portion 108 that overlaps with the insulating layer 103 in some cases. Moreover, the common electrode 115 is not in contact with the side surface of the organic layer 119 in some cases. Note that the common electrode 115 may include a region in contact with the side surface of the depressed portion 108.

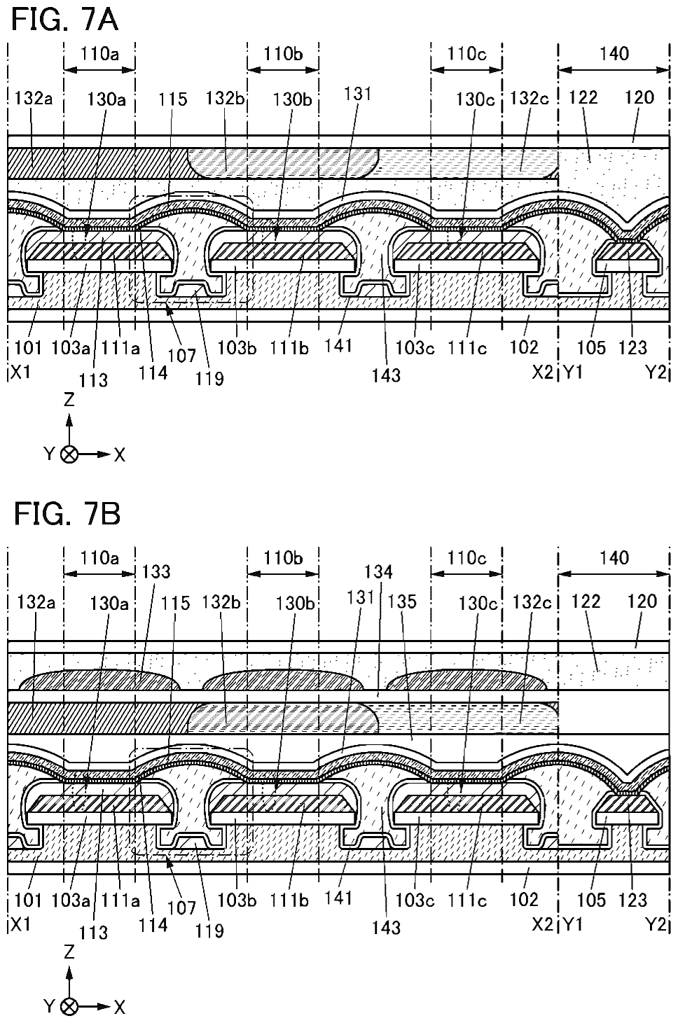

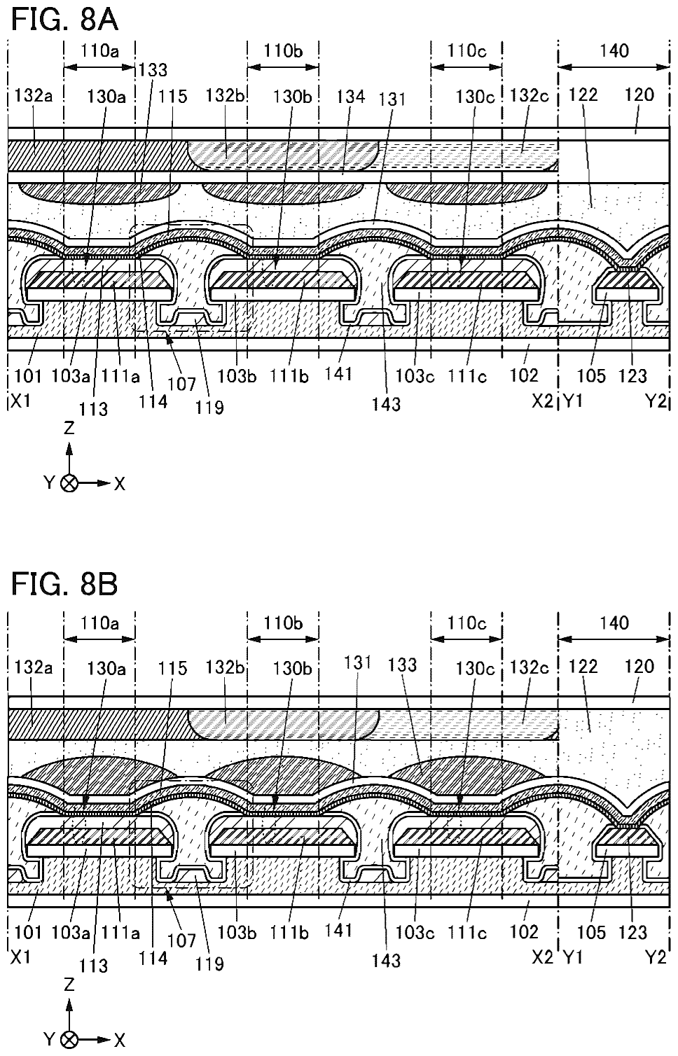

FIG. 7A, FIG. 7B, FIG. 8A, and FIG. 8B are cross-sectional views along dashed-dotted line X1-X2 and dashed-dotted line Y1-Y2 in FIG. 1A, which show structure examples different from that in FIG. 1B.

As illustrated in FIG. 7A, the substrate 120 provided with the coloring layer 132 may be attached to the protective layer 131 with the adhesive layer 122. By providing the coloring layer 132 for the substrate 120, the heat treatment temperature in the formation step of the coloring layer 132 can be increased.

As illustrated in FIG. 7B and FIG. 8A, lens arrays 133 may be provided in the display device 100. The lens array 133 can be provided in regions overlapping with the light-emitting elements 130.

FIG. 7B illustrates an example in which the coloring layer 132a, the coloring layer 132b, and the coloring layer 132c are provided over the light-emitting element 130a, the light-emitting element 130b, and the light-emitting element 130c with the protective layer 131 and the protective layer 135 therebetween, an insulating layer 134 is provided over the coloring layer 132a, the coloring layer 132b, and the coloring layer 132c, and the lens array 133 is provided over the insulating layer 134. The coloring layer 132a, the coloring layer 132b, the coloring layer 132c, and the lens array 133 are directly formed over the substrate 102 provided with the light-emitting elements 130, whereby the accuracy of positional alignment of the light-emitting elements 130 with the coloring layers 132 and the lens arrays 133 can be enhanced.

In FIG. 7B, light emitted by the light-emitting element 130 passes through the coloring layer 132 and then passes through the lens array 133, resulting in being extracted to the outside of the display device 100. The distance between the light-emitting element 130 and the coloring layer 132 is reduced, so that color mixture can be inhibited and the viewing angle characteristics can be improved, which is preferable. Note that the lens array 133 may be provided over the light-emitting element 130 and the coloring layer 132 may be provided over the lens array 133.

FIG. 8A illustrates an example in which the substrate 120 provided with the coloring layer 132a, the coloring layer 132b, the coloring layer 132c, and the lens array 133 is attached onto the protective layer 131 with the adhesive layer 122. The substrate 120 is provided with the coloring layer 132a, the coloring layer 132b, the coloring layer 132c, and the lens array 133, whereby the heat treatment temperature in the forming step of them can be increased.

In the example illustrated in FIG. 8A, the coloring layer 132a, the coloring layer 132b, and the coloring layer 132c are provided in contact with the substrate 120, the insulating layer 134 is provided in contact with the coloring layer 132a, the coloring layer 132b, and the coloring layer 132c, and the lens array 133 is provided in contact with the insulating layer 134.

In FIG. 8A, light emitted by the light-emitting element 130 passes through the lens array 133 and then passes through the coloring layer 132, resulting in being extracted to the outside of the display device 100. Note that such a structure that the lens array 133 is provided in contact with the substrate 120, the insulating layer 134 is provided in contact with the lens array 133, and the coloring layer 132 is provided in contact with the insulating layer 134 may be employed. In this case, light emitted by the light-emitting element 130 passes through the coloring layer 132 and then passes through the lens array 133, resulting in being extracted to the outside of the display device 100. It is preferable to provide a region where coloring layers 132 for different colors overlap with each other between adjacent lens arrays 133 as illustrated in FIG. 7B and FIG. 8A in order to inhibit because color mixture of light emitted by the light-emitting elements 130.

FIG. 8B illustrates an example in which the lens array 133 is provided over the light-emitting element 130a, the light-emitting element 130b, and the light-emitting element 130c with the protective layer 131 therebetween, and the substrate 120 provided with the coloring layer 132a, the coloring layer 132b, and the coloring layer 132c is bonded onto the lens array 133 and the protective layer 131 with the adhesive layer 122.

Unlike in FIG. 8B, the lens array 133 may be provided over the substrate 120 and the coloring layer 132 may be formed directly over the protective layer 131. In this manner, one of the lens array 133 and the coloring layer 132 may be provided over the protective layer 131 and the other may be provided over the substrate 120.

The examples in FIG. 7A, FIG. 8A, and FIG. 8B show that the protective layer 135 is not provided over the protective layer 131. Meanwhile, the example in FIG. 7B shows that the protective layer 135 is provided over the protective layer 131. Since the coloring layer 132 is provided below the adhesive layer 122 in FIG. 7B, the protective layer 135 functioning as a planarization layer is provided over the protective layer 131 and the coloring layer 132 is provided over the protective layer 135, whereby the coloring layer 132 can be provided over the flat surface. This makes it easy to form the coloring layer 132. In FIG. 7A, FIG. 8A, and FIG. 8B, the coloring layer 132 is provided above the adhesive layer 122; thus, the protective layer 135 functioning as a planarization layer does not need to be provided.

The lens array 133 may have a convex surface facing the substrate 120 side or a convex surface facing the light-emitting element 130.

The lens array 133 can be formed using at least one of an inorganic material and an organic material. For example, a material containing a resin can be used for the lens. Moreover, a material containing at least one of an oxide and a sulfide can be used for the lens. As the lens array 133, a microlens array can be used, for example. The lens array 133 may be directly formed over the substrate or the light-emitting element; alternatively, a lens array separately formed may be bonded thereto.

In the display device of one embodiment of the present invention, the island-shaped EL layer 113 is provided in each light-emitting element 130, whereby generation of lateral leakage current between the subpixels can be inhibited. Thus, it is possible to prevent crosstalk due to unintended light emission, so that a display device with extremely high contrast can be achieved. Furthermore, the island-shaped EL layer 113 can be formed without using a fine metal mask, so that the display device with high resolution and a high aperture ratio can be achieved. Moreover, the productivity of the display device can be increased.

### <Manufacturing Method Example>

An example of a method for manufacturing a display device of one embodiment of the present invention will be described below.

Thin films included in the display device (insulating films, semiconductor films, conductive films, and the like) can be formed by a sputtering method, a chemical vapor deposition (CVD) method, a vacuum evaporation method, a pulsed laser deposition (PLD) method, an ALD method, or the like. Examples of the CVD method include a plasma enhanced chemical vapor deposition (PECVD: Plasma Enhanced CVD) method and a thermal CVD method. As an example of the thermal CVD method, a metal organic chemical vapor deposition (MOCVD: Metal Organic CVD) method can be given.

The thin films included in the display device (insulating films, semiconductor films, conductive films, and the like) can be formed by a wet film formation method such as spin coating, dipping, spray coating, inkjetting, dispensing, screen printing, offset printing, a doctor knife method, slit coating, roll coating, curtain coating, and knife coating.

For fabrication of the light-emitting elements, a vacuum process such as an evaporation method or a solution process such as a spin coating method or an inkjet method can be especially used. Examples of the evaporation method include a physical vapor deposition (PVD) method and a CVD method. Examples of the PVD method include a sputtering method, an ion plating method, an ion beam evaporation method, a molecular beam evaporation method, and a vacuum evaporation method. Specifically, the functional layers (e.g., the hole-injection layer, the hole-transport layer, the hole-blocking layer, the electron-blocking layer, the electron-transport layer, the electron-injection layer, and the charge-generation layer) included in the EL layer can be formed by an evaporation method (e.g., a vacuum evaporation method), a coating method (e.g., a dip coating method, a die coating method, a bar coating method, a spin coating method, and a spray coating method), a printing method (e.g., an ink-jet method, a screen printing (stencil) method, an offset printing (planography) method, a flexography (relief printing) method, a gravure printing method, or a micro-contact printing method), or the like.

The thin films included in the display device can be processed by, for example, etching of the thin films in accordance with a pattern that has been formed by a photolithography method. Alternatively, the thin films may be processed by a nanoimprinting method, a sandblasting method, a lift-off method, or the like. An island-shaped thin film may be directly formed by a film formation method using a shielding mask such as a metal mask. A photosensitive thin film can be processed by light exposure and development. That is, the photosensitive thin film can be processed by a photolithography method.

As light used for light exposure in a photolithography method, for example, an i-line (with a wavelength of 365 nm), a g-line (with a wavelength of 436 nm), an h-line (with a wavelength of 405 nm), or light in which these lines are mixed can be used. Besides, ultraviolet rays, KrF laser light, ArF laser light, or the like can be used. In addition, light exposure may be performed by liquid immersion exposure technique. As the light used for light exposure, extreme ultraviolet (EUV) rays or X-rays may be used. Furthermore, instead of the light used for the light exposure, an electron beam can also be used. It is preferable to use extreme ultraviolet rays, X-rays, or an electron beam because extremely minute processing is possible. Note that when light exposure is performed by scanning of a beam such as an electron beam, a photomask is not needed.

For etching of the thin films, a dry etching method, a wet etching method, a sandblasting method, or the like can be used.

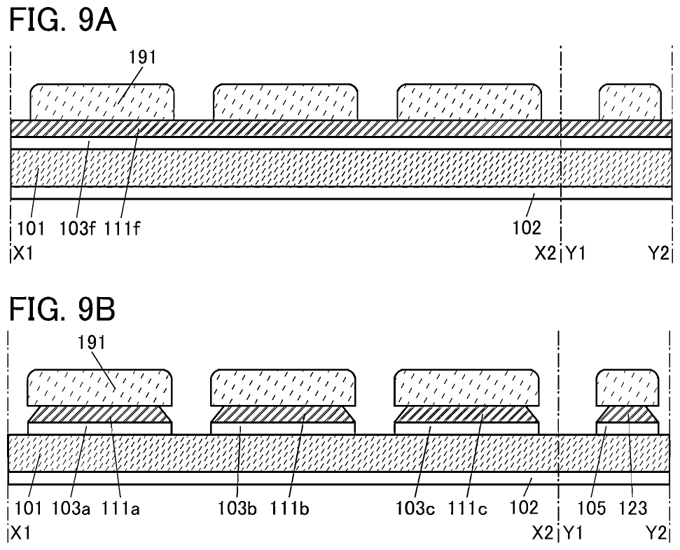

An example of a method for manufacturing the display device 100 having the structure illustrated in FIG. 1B will be described with reference to drawings. As illustrated in FIG. 9A, the insulating layer 101 is formed over the substrate 102, first. Next, an insulating film 103f to be the insulating layer 103a, the insulating layer 103b, the insulating layer 103c, and the insulating layer 105 is formed over the insulating layer 101.

As the substrate 102, a substrate having at least heat resistance high enough to withstand the following heat treatment can be used as described above. In the case where an insulating substrate is used as the substrate 102, a glass substrate, a quartz substrate, a sapphire substrate, a ceramic substrate, an organic resin substrate, or the like can be given. Alternatively, it is possible to use a semiconductor substrate such as a single crystal semiconductor substrate or a polycrystalline semiconductor substrate of silicon, silicon carbide, or the like, a compound semiconductor substrate of silicon germanium or the like, or an SOI substrate.

The insulating layer 101 can be an organic insulating layer as described above. The insulating layer 101 can be deposited by a wet process such as spin coating, dipping, spray coating, ink-jetting, dispensing, screen printing, offset printing, a doctor knife method, slit coating, roll coating, curtain coating, and knife coating.

The insulating film 103f can be an inorganic insulating film. The insulating film 103f can be formed by a vacuum evaporation method, a sputtering method, a CVD method, an ALD method, or the like.

Next, as illustrated in FIG. 9A, a conductive film 111f to be the pixel electrode 111a, the pixel electrode 111b, the pixel electrode 111c, and the conductive layer 123 is formed over the insulating film 103f. The conductive film 111f can be formed by a sputtering method or a vacuum evaporation method.

Next, as illustrated in FIG. 9A, a resist mask 191 is formed over the conductive film 11 if. The resist mask 191 can be formed by application of a photosensitive material (photoresist), light exposure, and development.

Subsequently, as illustrated in FIG. 9A and FIG. 9B, the conductive film 111f in a region not overlapping with the resist mask 191, for example, is removed by an etching method such as a wet etching method. Thus, the pixel electrode 111a, the pixel electrode 111b, the pixel electrode 111c, and the conductive layer 123 are formed.

In the case where the conductive film 111f is processed by a wet etching method, the conductive film 111f is sometimes etched not only in the vertical direction but also in the horizontal direction. Thus, the side surfaces of the pixel electrode 111a, the pixel electrode 111b, the pixel electrode 111c, and the conductive layer 123 are made to have a tapered shape in some cases. Specifically, the side surfaces of the pixel electrode 111a, the pixel electrode 111b, the pixel electrode 111c, and the conductive layer 123 may have a tapered shape with a taper angle less than 90° when seen from the XZ plane or the YZ plane, for example.

In the case where the pixel electrode 111 is formed to have the structure illustrated in FIG. 2B, a first conductive film to be the pixel electrode 111a1, the pixel electrode 111b1, and the like and a second conductive film to be the pixel electrode 111a2, the pixel electrode 111b2, and the like are sequentially formed over the insulating film 103f. Next, a pattern is formed by a photolithography method, for example, and then the second conductive film is processed by an etching method to form the pixel electrode 111a2, the pixel electrode 111b2, and the like. Next, a third conductive film to be the pixel electrode 111a3, the pixel electrode 111b3, and the like is formed over the first conductive film, the pixel electrode 111a2, the pixel electrode 111b2, and the like. Next, the resist mask 191 is formed over the third conductive film, and the third conductive film and the first conductive film in a region not overlapping with the resist mask 191 are removed by an etching method, for example. Through the above steps, the pixel electrode 111 having the structure illustrated in FIG. 2B can be formed. The conductive layer 123 having a structure similar to that of the pixel electrode 111 illustrated in FIG. 2B can be formed.

Next, as illustrated in FIG. 9A and FIG. 9B, the insulating film 103f in a region not overlapping with the pixel electrode 111a, the pixel electrode 111b, the pixel electrode 111c, and the conductive layer 123 is removed by an etching method, for example. Thus, the insulating layer 103a, the insulating layer 103b, the insulating layer 103c, and the insulating layer 105 are formed. The insulating film 103f can be processed by a dry etching method, for example.

Here, the side surfaces of the insulating layer 103a, the insulating layer 103b, the insulating layer 103c, and the insulating layer 105 are made to have a tapered shape with a taper angle less than 90° when seen from the XZ plane or the YZ plane in some cases. In some cases, the upper end portion of the side surface of the insulating layer 103 and the lower end portion of the side surface of the pixel electrode 111 are aligned in some cases or not aligned in other cases. Similarly, the upper end portion of the side surface of the insulating layer 105 and the lower end portion of the side surface of the conductive layer 123 are aligned in some cases or not aligned in other cases. For example, the lower end portion of the side surface of the pixel electrode 111 is located inward from the upper end portion of the side surface of the insulating layer 103, and the lower end portion of the side surface of the conductive layer 123 is located inward from the upper end portion of the side surface of the insulating layer 105 in some cases.

In the case where the side surfaces of the insulating layer 103a, the insulating layer 103b, the insulating layer 103c, and the insulating layer 105 are made to have a tapered shape, the taper angles of the side surfaces of the insulating layer 103a, the insulating layer 103b, the insulating layer 103c, and the insulating layer 105 are equal to the taper angles of the side surfaces of the pixel electrode 111a, the pixel electrode 111b, the pixel electrode 111c, and the conductive layer 123 in some cases and are not equal thereto in other cases. For example, the taper angles of the side surfaces of the insulating layer 103a, the insulating layer 103b, the insulating layer 103c, and the insulating layer 105 are larger than the taper angles of the side surfaces of the pixel electrode 111a, the pixel electrode 111b, the pixel electrode 111c, and the conductive layer 123 in some cases.

Note that the resist mask 191 may be removed after the formation of the pixel electrode 111 and the conductive layer 123 and before the formation of the insulating layer 103 and the insulating layer 105, and then a resist mask may be formed again. Thus, the insulating layer 103 and the insulating layer 105 can be formed with a pattern different from that used for formation of the pixel electrode 111 and the conductive layer 123. For example, the insulating layer 103 and the insulating layer 105 can be formed such that the lower end portion of the side surface of the pixel electrode 111 is located inward from the upper end portion of the side surface of the insulating layer 103 and the lower end portion of the side surface of the conductive layer 123 is located inward from the upper end portion of the side surface of the insulating layer 105.

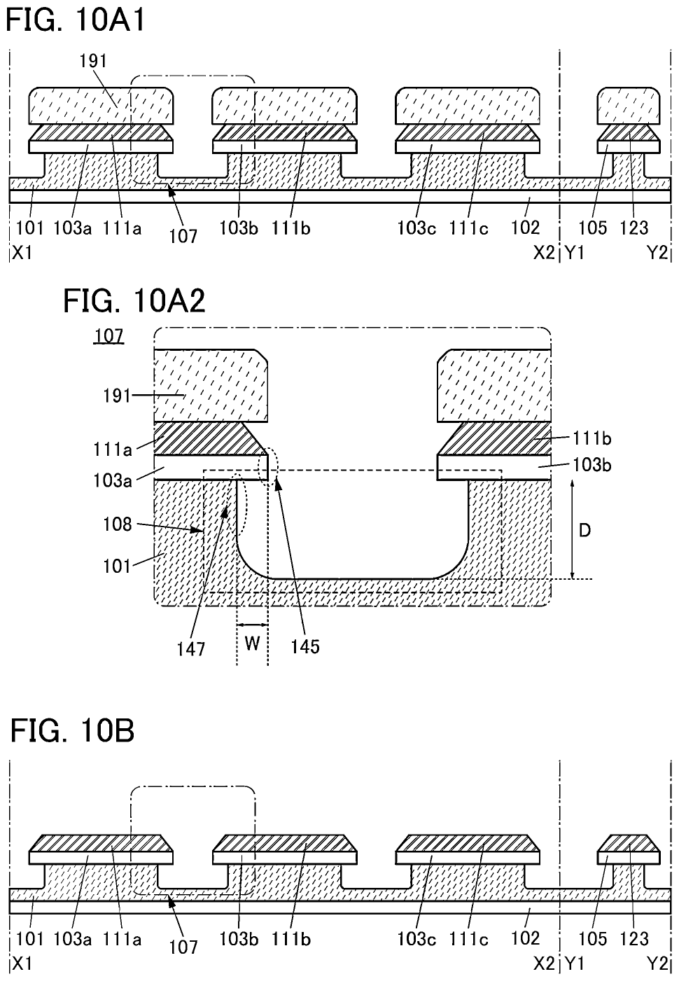

Next, as illustrated in FIG. 10A1, the insulating layer 101 is processed to form the depressed portion 108. FIG. 10A2 is an enlarged view of the region 107 in the cross-sectional view illustrated in FIG. 10A1.

The depressed portion 108 of the insulating layer 101 is formed in a region between the insulating layers 103 adjacent to each other in a plan view, and the end portion 145 of the insulating layer 103 overlaps with the depressed portion 108. That is, formation of the depressed portion 108 results in formation of a projecting portion in the insulating layer 103 that overlaps with the depressed portion 108.

When the insulating layer 101 is processed by a method enabling isotropic processing more easily than a processing method of the insulating film 103f, the depressed portion 108 can be formed so that the insulating layer 103 has a projecting portion. For example, in the case where the insulating layer 101 is an organic insulating layer and the insulating layer 103 is an inorganic insulating layer, the insulating layer 101 can be processed by ashing using oxygen plasma, for example. Alternatively, the insulating layer 101 can be processed using an oxygen gas and CF₄, C₄F₈, SF₆, CHF₃, Cl₂, H₂O, BCl₃, or a Group 18 element. He can be used as the Group 18 element, for example. Alternatively, the insulating layer 101 may be processed by etching or wet etching, for example. Note that the resist mask 191 is recessed (reduced) by processing the insulating layer 101 in some cases. The resist mask 191 is removed by processing the insulating layer 101 in some cases.

Note that the insulating layer 101 can be an inorganic insulating layer, for example, as long as the insulating layer 101 has high selectivity with respect to the insulating layer 103 and can be processed under a condition at least enabling higher isotropy than a condition of processing the insulating film 103f. In the case where the insulating layer 101 is an inorganic insulating layer, the insulating layer 101 can be processed by etching, for example, dry etching.

Here, the side surface of the insulating layer 101 in the depressed portion 108 is sometimes made to have a tapered shape with a taper angle less than 90° when seen from the XZ plane or the YZ plane, for example. In such a case, the taper angle of the side surface of the insulating layer 101 in the depressed portion 108 is equal to the taper angle of the side surface of the pixel electrode 111 or the taper angle of the side surface of the insulating layer 103 in some cases and is not equal thereto in other cases. For example, the taper angle of the side surface of the insulating layer 101 in the depressed portion 108 may be larger than the taper angle of the side surface of the pixel electrode 111.

Next, as illustrated in FIG. 10A1 and FIG. 10B, the resist mask 191 is removed. The resist mask 191 can be removed by wet etching, for example. Note that in the case where the resist mask 191 is removed in the step of forming the depressed portion 108 in the insulating layer 101, the above wet etching is not necessarily performed, for example.

Then, hydrophobic treatment is preferably performed on the pixel electrode 111. The hydrophobic treatment can change the property of the surface of a processing target from hydrophilic to hydrophobic, or can improve the hydrophobic property of the surface of the processing target. The hydrophobic treatment for the pixel electrode 111 can increase the adhesion between the pixel electrode 111 and the EL layer 113 formed in a later step and suppress separation of the EL layer 113. Note that the hydrophobic treatment is not necessarily performed.

The hydrophobic treatment can be performed by fluorination of the pixel electrode 111, for example. The fluorine modification can be performed by, for example, treatment or heat treatment using a fluorine-containing gas, plasma treatment in an atmosphere of a fluorine-containing gas, or the like. As the fluorine-containing gas, a fluorine gas such as a fluorocarbon gas can be used, for example. As a fluorocarbon gas, a low carbon fluoride gas such as a carbon tetrafluoride (CF₄) gas, a C₄F₆ gas, a C₂F₆ gas, a C₄F₈ gas, or a C₅F₈ gas can be used, for example. Moreover, as the fluorine-containing gas, a SF₆ gas, a NF₃ gas, a CHF₃ gas, or the like can be used, for example. Alternatively, a helium gas, an argon gas, a hydrogen gas, or the like can be added to any of the above gases as appropriate.

In addition, treatment using a silylation agent is performed on the surface of the pixel electrode 111 after plasma treatment is performed in a gas atmosphere containing a Group 18 element such as argon, so that the surface of the pixel electrode 111 can have a hydrophobic property. As the silylation agent, hexamethyldisilazane (HMIDS), trimethylsilylimidazole (TMSI), or the like can be used. Alternatively, treatment using a silane coupling agent is performed on the surface of the pixel electrode 111 after plasma treatment is performed in a gas atmosphere containing a Group 18 element such as argon, so that the surface of the pixel electrode 111 can be hydrophobic.

Plasma treatment in a gas atmosphere containing a Group 18 element such as argon is performed on the surface of the pixel electrode 111, whereby the surface of the pixel electrode 111 can be damaged. Accordingly, a methyl group contained in the silylation agent such as HMDS is likely to bond to the surface of the pixel electrode 111. Moreover, silane coupling due to the silane coupling agent is likely to occur. As described above, treatment using a silylation agent or a silane coupling agent performed on the surface of the pixel electrode 111 after plasma treatment in a gas atmosphere containing a Group 18 element such as argon enables the surface of the pixel electrode 111 to be hydrophobic.

The treatment using the silylation agent, the silane coupling agent, or the like can be performed by application of the silylation agent, the silane coupling agent, or the like by a spin coating method or a dipping method, for example. The treatment using the silylation agent, the silane coupling agent, or the like can also be performed by forming a film containing the silylation agent, a film containing the silane coupling agent, or the like over the pixel electrode 111 and the like by a gas phase method, for example. In a gas phase method, first, a material containing the silylation agent, a material containing the silane coupling agent, or the like is volatilized so that the silylation agent, the silane coupling agent, or the like is included in the atmosphere. Next, the substrate 102 where the pixel electrode 111 and the like are formed is put in the atmosphere. In this manner, a film containing a silylation agent, a silane coupling agent, or the like can be formed over the pixel electrode 111, whereby the surface of the pixel electrode 111 can be hydrophobic.

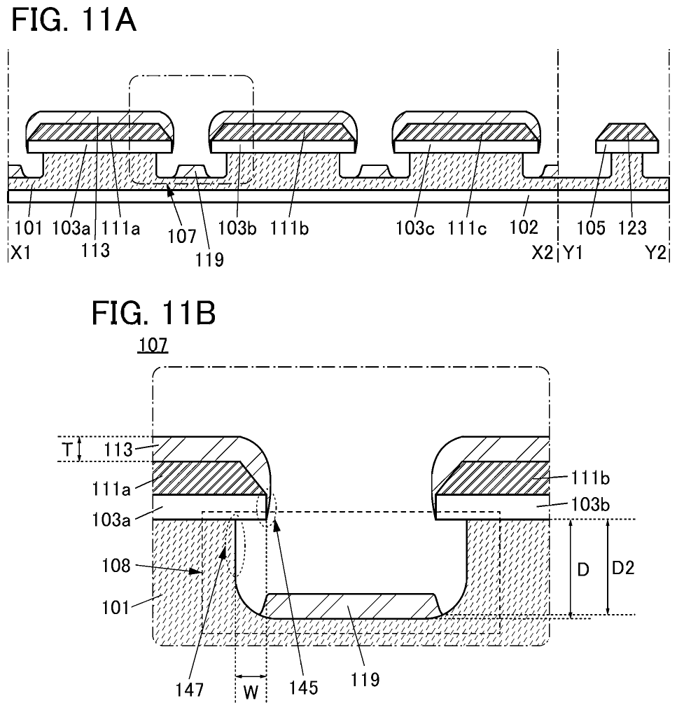

Next, as illustrated in FIG. 11A, the EL layer 113 is formed over the pixel electrode 111a, the pixel electrode 111b, and the pixel electrode 111c. FIG. 11B is an enlarged view of the region 107 in the cross-sectional view illustrated in FIG. 11A.

As illustrated in FIG. 11A, the EL layer 113 is not formed over the conductive layer 123. The EL layer 113 can be formed only in an intended region by using an area mask, for example.

The EL layer 113 is preferably formed by a method for forming a film with low coverage. The EL layer 113 can be formed by an evaporation method, specifically a vacuum evaporation method, for example. The EL layer 113 may be formed by a transfer method, a printing method, an inkjet method, a coating method, or the like.

In the formation of the EL layer 113, the EL layer 113 is divided due to the projecting portion provided for the insulating layer 103 to overlap with the depressed portion 108. Thus, the island-shaped EL layer 113 is formed. Note that in the formation of the EL layer 113, the material of the EL layer 113 reaches the inside of the depressed portion 108, and the EL layer 113 is divided, so that the organic layer 119 is formed in the depressed portion 108 in some cases.

In the above manner, a plurality of island-shaped EL layers 113 can be formed using the same material in the same step, without using a fine metal mask. Since the EL layers 113 are inhibited from being in contact with each other in adjacent subpixels, generation of leakage current between the subpixels can be inhibited. Accordingly, degradation of the display quality of the display device can be inhibited. In addition, the display device can have both high resolution and high display quality.

The island-shaped EL layer 113 can be formed to cover the top surface of the pixel electrode 111 and at least part of the side surface. With such a structure, the entire top surface of the pixel electrode 111 can be used as a light-emitting region as described above. Thus, the aperture ratio of the display device can be increased as compared with the structure in which the island-shaped EL layer 113 does not cover the side surface of the pixel electrode 111. When the EL layer 113 covers the side surface of the pixel electrode 111 and the side surface of the pixel electrode 111 has a tapered shape, coverage of the pixel electrode 111 with the EL layer 113 can be improved compared with the case where the side surface of the pixel electrode 111 is perpendicular. Note that as illustrated in FIG. 11A and FIG. 11B, the EL layer 113 covers not only the side surface of the pixel electrode 111 but also the side surface of the insulating layer 103 in some cases.

As described above, the ratio of the width W of the projecting portion of the insulating layer 103 to the thickness T of the EL layer 113 (W/T) is preferably greater than or equal to 0.3, further preferably greater than or equal to 0.5, still further preferably greater than or equal to 0.7, still further preferably greater than or equal to 0.9, yet still further preferably greater than or equal to 1.0. In addition, W/T is preferably less than or equal to 10.0, further preferably less than or equal to 5.0. As described above, the ratio of the depth D of the depressed portion 108 to the thickness T of the EL layer 113 (D/T) is preferably greater than or equal to 1.0, further preferably greater than or equal to 2.0, still further preferably greater than or equal to 3.0, still further preferably greater than or equal to 3.5, yet still further preferably greater than or equal to 4.0. In addition, D/T is preferably less than or equal to 50.0, further preferably less than or equal to 30.0, still further preferably less than or equal to 20.0.

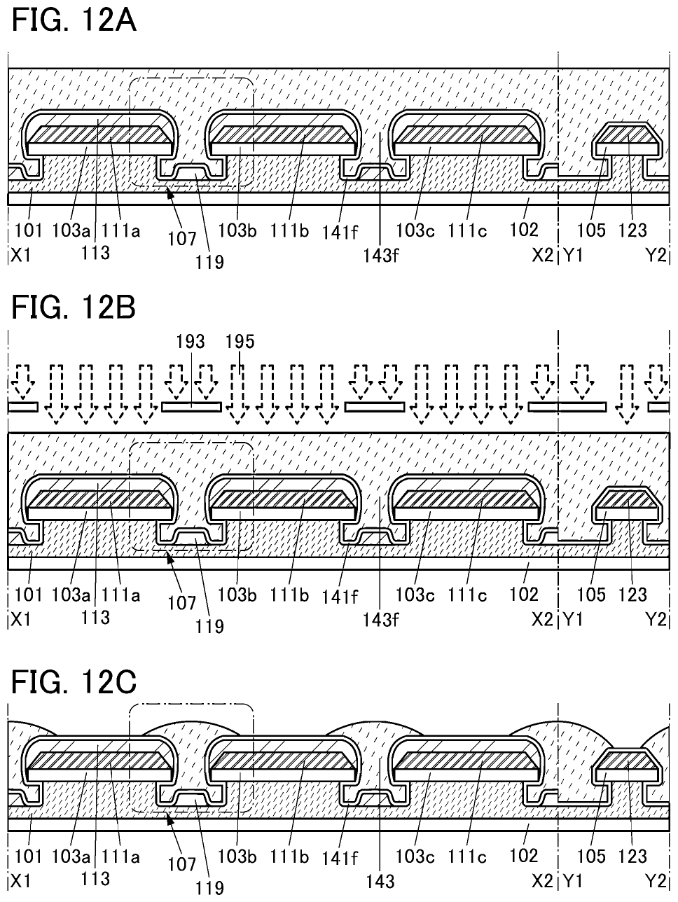

Next, as illustrated in FIG. 12A, an insulating film 141f to be the insulating layer 141 and an insulating film 143f to be the insulating layer 143 are sequentially formed to cover the EL layer 113, the organic layer 119, and the conductive layer 123.

Therefore, the top surface of the insulating film 141f preferably has high affinity for a material used for the insulating film 143f (e.g., a photosensitive resin composition containing an acrylic resin). To improve the affinity, surface treatment is preferably performed so that the top surface of the insulating film 141f is made hydrophobic or its hydrophobic properties are improved. For example, it is preferable to perform the treatment using a silylation agent such as HMDS. By making the top surface of the insulating film 141f hydrophobic in this manner, the insulating film 143f can be formed with high adhesion to the insulating film 141f. Note that the above-described hydrophobic treatment may be performed as the surface treatment.

The insulating film 141f and the insulating film 143f are preferably formed by a formation method that causes less damage to the EL layer 113. In particular, the insulating film 141f, which is formed in contact with the side surface of the EL layer 113, is preferably formed by a formation method that causes less damage to the EL layer 113 than the formation method of the insulating film 143f.

In addition, the insulating film 141f and the insulating film 143f are each formed at a temperature lower than the upper temperature limit of the EL layer 113. When the temperature of the substrate 102 at the time when the insulating film 141f is formed is increased, the formed insulating film 141f, even with a small thickness, can have a low impurity concentration and a high barrier property against at least one of water and oxygen.

The temperature of the substrate 102 at the time of forming the insulating film 141f and the insulating film 143f is preferably higher than or equal to 60° C., higher than or equal to 80° C., higher than or equal to 100° C., or higher than or equal to 120° C. and lower than or equal to 200° C., lower than or equal to 180° C., lower than or equal to 160° C., lower than or equal to 150° C., or lower than or equal to 140° C.

As the insulating film 141f, an insulating film is preferably formed within the above temperature range of the substrate 102 to have a thickness greater than or equal to 3 nm, greater than or equal to 5 nm, or greater than or equal to 10 nm and less than or equal to 200 nm, less than or equal to 150 nm, less than or equal to 100 nm, or less than or equal to 50 nm.

The insulating film 141f is preferably formed by an ALD method, for example. The use of an ALD method is preferable, in which case damage by the deposition is reduced and a film with favorable coverage can be deposited. Thus, for example, the insulating film 141f can favorably cover the bottom surface of the projecting portion of the insulating layer 103 overlapping with the depressed portion 108 and the side surface of the depressed portion 108. Accordingly, the width W of the projecting portion of the insulating layer 103 can be inhibited from being reduced, as compared with the case where the insulating layer 141 is formed by a method for forming a film with low coverage. As the insulating film 141f, an aluminum oxide film can be formed by an ALD method, for example.

Alternatively, the insulating film 141f may be formed by a sputtering method, a CVD method, or a PECVD method, each of which has a higher deposition rate than an ALD method. In that case, a highly reliable display device can be manufactured with high productivity.

The insulating film 143f is preferably formed by the aforementioned wet film formation method. The insulating film 143f is preferably formed by spin coating using a photosensitive material, for example, and preferably formed using specifically a photosensitive resin composition containing an acrylic resin.

The insulating film 143f is preferably formed using a resin composition containing a polymer, an acid-generating agent, and a solvent, for example. The polymer is formed using one or more kinds of monomers and has a structure where one or more kinds of structural units (also referred to as building blocks) are repeated regularly or irregularly. As the acid-generating agent, one or both of a compound that generates an acid by light irradiation and a compound that generates an acid by heating can be used. The resin composition may also include one or more of a photosensitizing agent, a sensitizer, a catalyst, an adhesive aid, a surface-active agent, and an antioxidant.

Heat treatment (also referred to as prebaking) is preferably performed after the insulating film 143f is formed. The heat treatment is performed at a temperature lower than the upper temperature limit of the EL layer 113. The temperature of the substrate 102 in the heat treatment is preferably higher than or equal to 50° C. and lower than or equal to 200° C., further preferably higher than or equal to 60° C. and lower than or equal to 150° C., still further preferably higher than or equal to 70° C. and lower than or equal to 120° C. Accordingly, a solvent contained in the insulating film 143f can be removed.

Next, as illustrated in FIG. 12B, part of the insulating film 143f is irradiated with light 195 that is visible light or ultraviolet rays to be subjected to light exposure. In the case where a positive photosensitive material is used for the insulating film 143f, a region where the insulating layer 143 is not formed in a later step is irradiated with the light 195 with use of a mask 193. Specifically, the mask 193 is placed to overlap on a region where the insulating layer 143 is formed in a later step, and the insulating film 143f and the mask 193 are irradiated with the light 195. The insulating layer 143 is formed between adjacent EL layers 113 and around the conductive layer 123. Thus, as illustrated in FIG. 12B, the light 195 is incident on portions in the insulating film 143f that overlap with the EL layer 113 and the conductive layer 123.

The light 195 preferably includes the i-line (wavelength: 365 nm). Furthermore, the light 195 may include at least one of the g-line (wavelength: 436 nm) and the h-line (wavelength: 405 nm).

Note that a negative photosensitive material may be used for the insulating film 143f. In this case, the light 195 is incident on a region of the insulating film 143f where the insulating layer 143 is formed. Specifically, the mask 193 is placed to overlap on a region where the insulating layer 143 is not formed in a later step, and the insulating film 143f and the mask 193 are irradiated with the light 195.

Next, the region of the insulating film 143f exposed to light is removed by development as illustrated in FIG. 12C, so that the insulating layer 143 is formed. The insulating layer 143 is formed between adjacent EL layers 113 as described above. The insulating layer 143 can be formed between adjacent pixel electrodes 111. In some cases, the insulating layer 143 is formed between adjacent insulating layers 103. The insulating layer 143 is formed around the conductive layer 123 and the insulating layer 105.

As described above, the insulating layer 143 is formed to have a region overlapping with the depressed portion 108. The insulating layer 143 can be formed to have a region overlapping with the organic layer 119. Note that the insulating layer 143 can be formed to overlap with part of the top surface of the EL layer 113. Here, when an acrylic resin is used for the insulating film 143f, a developer is preferably an alkaline solution and can be TMAH, for example.

As described above, the photosensitive insulating film 143f is processed through the exposure and development, so that the insulating layer 143 can be formed. In other words, the insulating layer 143 can be formed by a photolithography method.

Then, a residue (scum) due to the development may be removed. For example, the residue can be removed by ashing using oxygen plasma.

Etching may be performed to adjust the surface levels of the insulating layers 143. The insulating layer 143 may be processed by ashing using oxygen plasma, for example. In the case where a non-photosensitive material is used for the insulating film 143f, the surface level of the insulating film 143f can be adjusted by the ashing, for example.

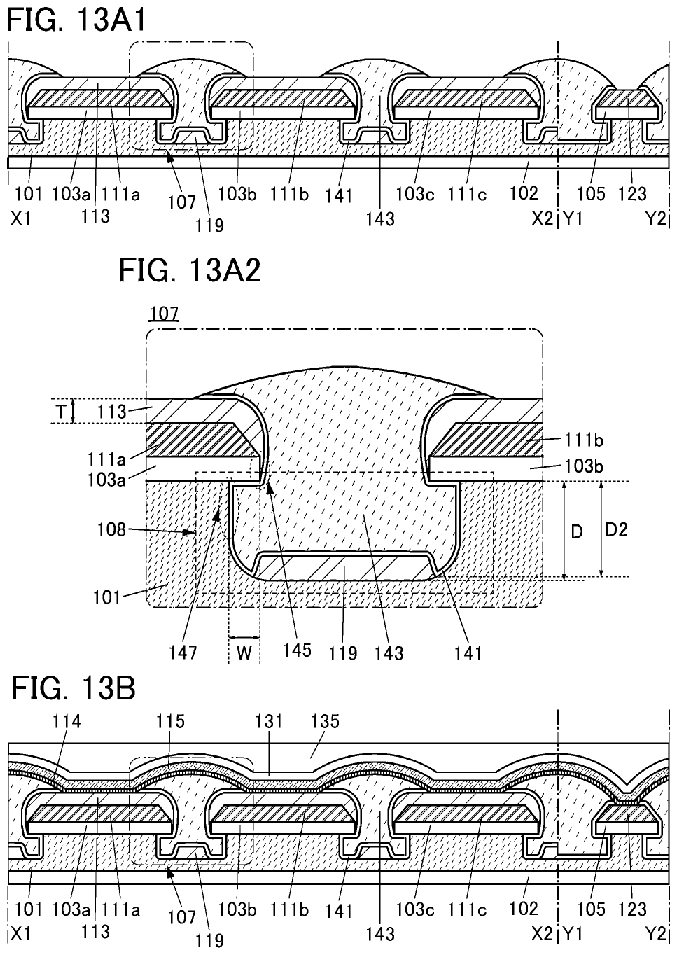

Next, as illustrated in FIG. 12C and FIG. 13A1, etching treatment is performed using the insulating layer 143 as a mask to remove part of the insulating film 141f. Thus, the insulating layer 141 is formed under the insulating layer 143. Furthermore, the top surface of the EL layer 113 and the top surface of the conductive layer 123 are exposed. FIG. 13A2 is an enlarged view of the region 107 in FIG. 13A1. The insulating film 141f is preferably processed by a wet etching method, in which case damage to the EL layer 113 can be reduced as compared with the case where the insulating film 141f is processed by a dry etching method, for example. Note that as long as damage to the EL layer 113 is a negligible level, the insulating film 141f may be processed by a dry etching method. In such a case, the subpixel 110a, the subpixel 110b, and the subpixel 110c can be miniaturized as compared with the case where the insulating film 141f is processed by a wet etching method, for example.

Next, as illustrated in FIG. 13B, the common layer 114 is formed over the EL layer 113, the conductive layer 123, and the insulating layer 143. The common layer 114 can be formed by a method such as an evaporation method (including a vacuum evaporation method), a transfer method, a printing method, an inkjet method, or a coating method. As described above, the common layer 114 can include an electron-injection layer or a hole-injection layer, for example. The common layer 114 further includes an electron-transport layer or a hole-transport layer, for example. Alternatively, the common layer 114 may include a stack of an electron-transport layer and an electron-injection layer, or may include a stack of a hole-transport layer and a hole-injection layer.

Then, as illustrated in FIG. 13B, the common electrode 115 is formed over the common layer 114. Thus, the light-emitting element 130a, the light-emitting element 130b, and the light-emitting element 130c are completed. The common electrode 115 can be formed by a method such as a sputtering method or a vacuum evaporation method. Alternatively, the common electrode 115 may be formed in such a manner that a film formed by an evaporation method and a film formed by a sputtering method are stacked.

Next, the protective layer 131 is formed over the common electrode 115 as illustrated in FIG. 13B. The protective layer 131 can be formed by a vacuum evaporation method, a sputtering method, a CVD method, an ALD method, or the like.

Next, the protective layer 135 is formed over the protective layer 131 as illustrated in FIG. 13B. The protective layer 135 can be deposited by a wet process such as spin coating, dipping, spray coating, ink-jetting, dispensing, screen printing, offset printing, a doctor knife method, slit coating, roll coating, curtain coating, or knife coating.

Subsequently, the coloring layer 132a, the coloring layer 132b, and the coloring layer 132c are formed over the protective layer 135. The coloring layer 132a is formed to have a region overlapping with the pixel electrode 111a and the EL layer 113 included in the light-emitting element 130a. The coloring layer 132b is formed to have a region overlapping with the pixel electrode 111b and the EL layer 113 included in the light-emitting element 130b. The coloring layer 132c is formed to have a region overlapping with the pixel electrode 111c and the EL layer 113 included in the light-emitting element 130c.

Subsequently, the substrate 120 is attached onto the coloring layer 132a, the coloring layer 132b, the coloring layer 132c, and the protective layer 135 with the adhesive layer 122, whereby the display device 100 having the structure illustrated in FIG. 1B can be manufactured.

Next, an example of a method for manufacturing the display device 100 having the structure illustrated in FIG. 6A will be described with reference to drawings. Note that description of a method similar to the method described with reference to FIG. 9A to FIG. 13B is omitted as appropriate.

First, steps with a method similar to that illustrated in FIG. 9A to FIG. 11B are performed. Thus, the insulating layer 101, the insulating layer 103, the insulating layer 105, the pixel electrode 111, the conductive layer 123, the EL layer 113, and the like are formed over the substrate 102. In addition, the depressed portion 108 is formed in the insulating layer 101.

As described above, a too large width W of the projecting portion of the insulating layer 103 might cause disconnection in the common electrode 115 formed in a later step. When the depth D of the depressed portion 108 is too deep, disconnection might be generated in the common electrode 115 formed in a later step. When disconnection is generated in the common electrode 115, voltage is not applied to the EL layer 113 and the light-emitting element 130 does not emit light in some cases. Thus, the depressed portion 108 is formed so as to provide the width W of the projecting portion of the insulating layer 103 and the depth D of the depressed portion 108 making disconnection in the EL layer 113 and preventing disconnection in the common electrode 115.

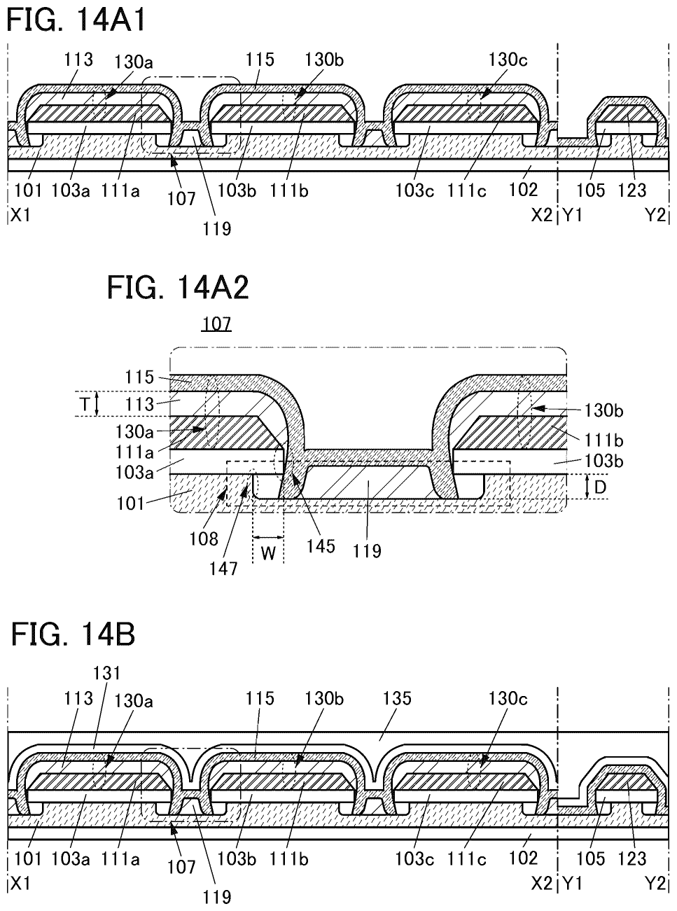

Then, the common electrode 115 is formed over the EL layer 113 and the conductive layer 123 as illustrated in FIG. 14A1. FIG. 14A2 is an enlarged view of the region 107 illustrated in FIG. 14A1.

As described above, the common electrode 115 can be formed by a method, such as a sputtering method or a vacuum evaporation method, which is for forming a film with lower coverage than that of a film formed by an ALD method. In such a case, as illustrated in FIG. 14A1 and FIG. 14A2, the common electrode 115 is not in contact with the side surface of the depressed portion 108 and a gap is sometimes formed between the side surface of the depressed portion 108 and the common electrode 115. The common electrode 115 is not formed in a region of the depressed portion 108 that overlaps with the insulating layer 103 in some cases. Furthermore, in some cases, the common electrode 115 is formed so as not to be in contact with the side surface of the organic layer 119. Note that the common electrode 115 may be formed to have a region in contact with the side surface of the depressed portion 108.

Next, the protective layer 131 is formed over the common electrode 115, and the protective layer 135 is formed over the protective layer 131 as illustrated in FIG. 14B. Subsequently, the coloring layer 132a, the coloring layer 132b, and the coloring layer 132c are formed over the protective layer 135. Then, the substrate 120 is attached onto the coloring layer 132a, the coloring layer 132b, the coloring layer 132c, and the protective layer 135 with the adhesive layer 122. Through the above process, the display device 100 having the structure illustrated in FIG. 6A can be manufactured.

In the method illustrated in FIG. 14A1, FIG. 14A2, and FIG. 14B, the insulating layer 141, the insulating layer 143, and the common layer 114 are not formed. Thus, the manufacturing method of the display device 100 can be simplified. Note that the common layer 114 may be provided. The insulating layer 141 may be provided.

In the method for manufacturing a display device of one embodiment of the present invention, the island-shaped EL layer 113 is provided in each light-emitting element 130, whereby generation of leakage current between the subpixels can be inhibited. Thus, it is possible to prevent crosstalk due to unintended light emission, so that a display device with extremely high contrast can be manufactured. Furthermore, the island-shaped EL layer 113 can be formed without using a fine metal mask, so that the display device with high resolution and a high aperture ratio can be manufactured. Furthermore, the display device can be manufactured with high mass productivity.

This embodiment can be combined with the other embodiments or an example as appropriate.

### Embodiment 2

In this embodiment, a display device of one embodiment of the present invention will be described with reference to drawings.

### [Pixel Layout]

In this embodiment, a pixel layout different from that in FIG. 1A will be described. There is no particular limitation on the arrangement of subpixels, and any of a variety of methods can be employed. Examples of the arrangement of subpixels include stripe arrangement, S-stripe arrangement, matrix arrangement, delta arrangement, Bayer arrangement, and PenTile arrangement.

The top surface shape of the subpixel shown in a diagram in this embodiment corresponds to the top surface shape of a light-emitting region.

Examples of the top surface shape of the subpixel include polygons such as a triangle, a tetragon (including a rectangle and a square), and a pentagon; polygons with rounded corners; an ellipse; and a circle.

The range of the circuit layout for forming the subpixels is not limited to the range of the subpixels illustrated in a diagram and circuits may be placed outside the subpixels.

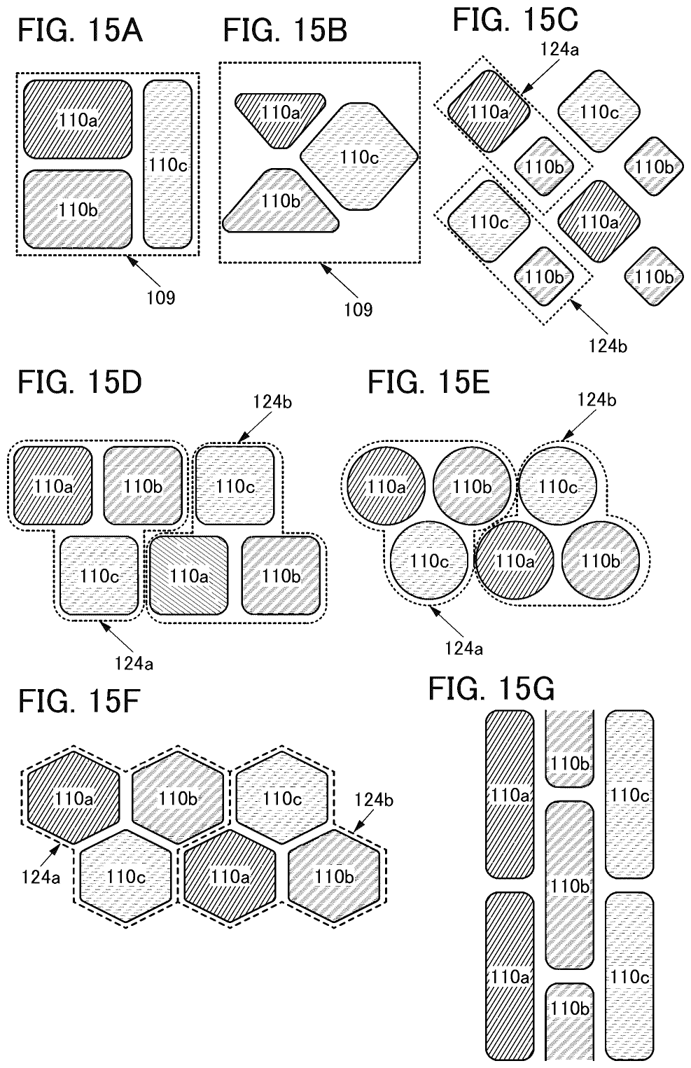

The pixel 109 illustrated in FIG. 15A employs S-stripe arrangement. The pixel 109 illustrated in FIG. 15A is composed of three subpixels: the subpixel 110a, the subpixel 110b, and the subpixel 110c.

The pixel 109 illustrated in FIG. 15B includes the subpixel 110a whose top surface has a rough triangle shape with rounded corners, the subpixel 110b whose top surface has a rough trapezoidal shape with rounded corners, and the subpixel 110c whose top surface has a rough tetragonal or rough hexagonal shape with rounded corners. The subpixel 110b has a larger light-emitting area than the subpixel 110a. In this manner, the shapes and sizes of the subpixels can be determined independently. For example, the size of a subpixel including a light-emitting element with higher reliability can be smaller.

A pixel 124a and a pixel 124b illustrated in FIG. 15C employ PenTile arrangement. FIG. 15C illustrates an example where the pixel 124a including the subpixel 110a and the subpixel 110b and the pixel 124b including the subpixel 110b and the subpixel 110c are alternately arranged.

The pixel 124a and the pixel 124b illustrated in FIG. 15D, FIG. 15E, and FIG. 15F employ a delta arrangement. The pixel 124a includes two subpixels (the subpixel 110a and the subpixel 110b) in the upper row (first row) and one subpixel (the subpixel 110c) in the lower row (second row). The pixel 124b includes one subpixel (the subpixel 110c) in the upper row (first row) and two subpixels (the subpixel 110a and the subpixel 110b) in the lower row (second row).

FIG. 15D illustrates an example where a top surface shape of each subpixel is a rough tetragon with rounded corners, FIG. 15E illustrates an example where a top surface shape of each subpixel is a circle, and FIG. 15F illustrates an example where a top surface shape of each subpixel is a rough hexagon with rounded corners.

FIG. 15G illustrates an example where subpixels of different colors are arranged in a zigzag manner. Specifically, the positions of the top sides of two subpixels arranged in the column direction (e.g., the subpixel 110a and the subpixel 110b or the subpixel 110b and the subpixel 110c) are not aligned in a plan view.

For example, in each pixel illustrated in FIG. 15A to FIG. 15G, it is preferable that the subpixel 110a be a subpixel R exhibiting red light, the subpixel 110b be a subpixel G exhibiting green light, and the subpixel 110c be a subpixel B exhibiting blue light. Note that the structure of the subpixels is not limited to this, and the colors and arrangement order of the subpixels can be determined as appropriate. For example, the subpixel 110b may be the subpixel R that emits red light and the subpixel 110a may be the subpixel G that emits green light.

In a photolithography method, as a pattern to be processed becomes finer, the influence of light diffraction becomes more difficult to ignore; therefore, the fidelity in transferring a photomask pattern by light exposure is degraded, and it becomes difficult to process a resist mask into a desired shape. Thus, a pattern with rounded corners is likely to be formed even with a rectangular photomask pattern. Consequently, the top surface of a pixel electrode may have a polygonal shape with rounded corners, an elliptical shape, a circular shape, or the like. In the display device of one embodiment of the present invention, the top surface shape of the EL layer and the top surface shape of the light-emitting element may each be a polygon with rounded corners, an ellipse, a circle, or the like due to the influence of the top surface shape of the pixel electrode.

Note that to obtain a desired top surface shape of the pixel electrode, a technique of correcting a mask pattern in advance so that a transferred pattern agrees with a design pattern, an OPC (Optical Proximity Correction) technique, may be used. Specifically, with the OPC technique, a pattern for correction is added to a corner portion or the like of a figure on a mask pattern.

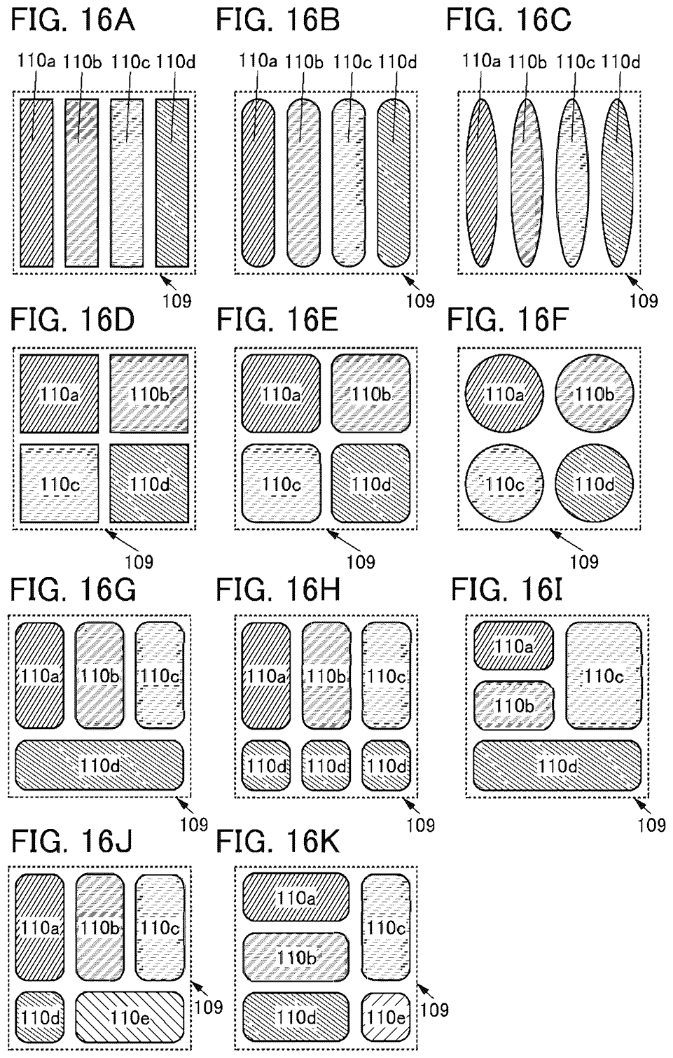

As illustrated in FIG. 16A to FIG. 16I, the pixel can include four types of subpixels.

The pixels 109 illustrated in FIG. 16A to FIG. 16C employ stripe arrangement.

FIG. 16A illustrates an example where each subpixel has a rectangular top surface shape, FIG. 16B illustrates an example where each subpixel has a top surface shape formed by combining two half circles and a rectangle, and FIG. 16C illustrates an example where each subpixel has an elliptical top surface shape.

The pixels 109 illustrated in FIG. 16D to FIG. 16F employ matrix arrangement.

FIG. 16D illustrates an example where each subpixel has a square top surface shape, FIG. 16E illustrates an example where each subpixel has a rough square top surface shape with rounded corners, and FIG. 16F illustrates an example where each subpixel has a circular top surface shape.

FIG. 16G and FIG. 16H each illustrate an example where one pixel 109 is composed of two rows and three columns.

The pixel 109 illustrated in FIG. 16G includes three subpixels (the subpixel 110a, the subpixel 110b, and the subpixel 110c) in the upper row (first row) and one subpixel (the subpixel 110d) in the lower row (second row). In other words, the pixel 109 includes the subpixel 110a in the left column (first column), the subpixel 110b in the center column (second column), the subpixel 110c in the right column (third column), and the subpixel 110d across these three columns.

The pixel 109 illustrated in FIG. 16H includes three subpixels (the subpixel 110a, the subpixel 110b, and the subpixel 110c) in the upper row (first row) and three of the subpixels 110d in the lower row (second row). In other words, the pixel 109 includes the subpixel 110a and the subpixel 110d in the left column (first column), the subpixel 110b and another subpixel 110d in the center column (second column), and the subpixel 110c and another subpixel 110d in the right column (third column). Matching the positions of the subpixels in the upper row and the lower row as illustrated in FIG. 16H enables dust that would be produced in the manufacturing process, for example, to be removed efficiently. Thus, a display device with high display quality can be provided.

FIG. 16I illustrates an example where one pixel 109 is composed of three rows and two columns.

The pixel 109 illustrated in FIG. 16I includes the subpixel 110a in the upper row (first row), the subpixel 110b in the center row (second row), the subpixel 110c across the first and second rows, and one subpixel (the subpixel 110d) in the lower row (third row). In other words, the pixel 109 includes the subpixel 110a and the subpixel 110b in the left column (first column), the subpixel 110c in the right column (second column), and the subpixel 110d across these two columns.

The pixels 109 illustrated in FIG. 16A to FIG. 16I are each composed of four subpixels: the subpixel 110a, the subpixel 110b, the subpixel 110c, and the subpixel 110d.

The subpixel 110a, the subpixel 110b, the subpixel 110c, and the subpixel 110d can include light-emitting elements that emit light of different colors. The subpixel 110a, the subpixel 110b, the subpixel 110c, and the subpixel 110d can be subpixels of four colors of R, G, B, and W, subpixels of four colors of R, G, B, and Y, or subpixels of four colors of R, G, B, and infrared light (IR), for example.

In the pixels 109 illustrated in FIG. 16A to FIG. 16I, it is preferable that the subpixel 110a be a subpixel exhibiting red light, the subpixel 110b be a subpixel exhibiting green light, the subpixel 110c be a subpixel exhibiting blue light, and the subpixel 110d be any of a subpixel emitting white light, a subpixel emitting yellow light, and a subpixel exhibiting near-infrared light, for example. In the case of such a structure, stripe arrangement is employed as the layout of R, G, and B in the pixels 109 illustrated in FIG. 16G and FIG. 16H, leading to higher display quality. In addition, what is called S-stripe arrangement is employed as the layout of R, G, and B in the pixel 109 illustrated in FIG. 16I, leading to higher display quality.

As illustrated in FIG. 16J and FIG. 16K, the pixel can include five types of subpixels. Examples of subpixels of five colors include subpixels of five colors of R, G, B, Y, and W.

FIG. 16J illustrates an example where one pixel 109 is composed of two rows and three columns.

The pixel 109 illustrated in FIG. 16J includes three subpixels (the subpixel 110a, the subpixel 110b, and the subpixel 110c) in the upper row (first row) and two subpixels (the subpixel 110d and the subpixel 110e) in the lower row (second row). In other words, the pixel 109 includes the subpixel 110a and the subpixel 110d in the left column (first column), the subpixel 110b in the center column (second column), the subpixel 110c in the right column (third column), and the subpixel 110e across the second and third columns.

FIG. 16K illustrates an example where one pixel 109 is composed of three rows and two columns.

The pixel 109 illustrated in FIG. 16K includes the subpixel 110a in the upper row (first row), the subpixel 110b in the center row (second row), the subpixel 110c across the first and second rows, and two subpixels (the subpixels 110d and 110e) in the lower row (third row). In other words, the pixel 109 includes the subpixel 110a, the subpixel 110b, and the subpixel 110d in the left column (first column), and the subpixel 110c and the subpixel 110e in the right column (second column).

As described above, the pixel composed of the subpixels each including the light-emitting element can employ any of a variety of layouts in the display device of one embodiment of the present invention.

This embodiment can be combined with the other embodiments or an example as appropriate.

### Embodiment 3

In this embodiment, a display device of one embodiment of the present invention will be described with reference to drawings.

The display device of this embodiment can be a high-definition display device or a large-sized display device. Accordingly, the display device of this embodiment can be used for display portions of electronic devices such as a digital camera, a digital video camera, a digital photo frame, a mobile phone, a portable game console, a portable information terminal, and an audio reproducing device, in addition to display portions of electronic devices with a relatively large screen, such as a television device, a desktop or laptop personal computer, a monitor of a computer and the like, digital signage, and a large game machine such as a pachinko machine.

### [Display Device 100A]

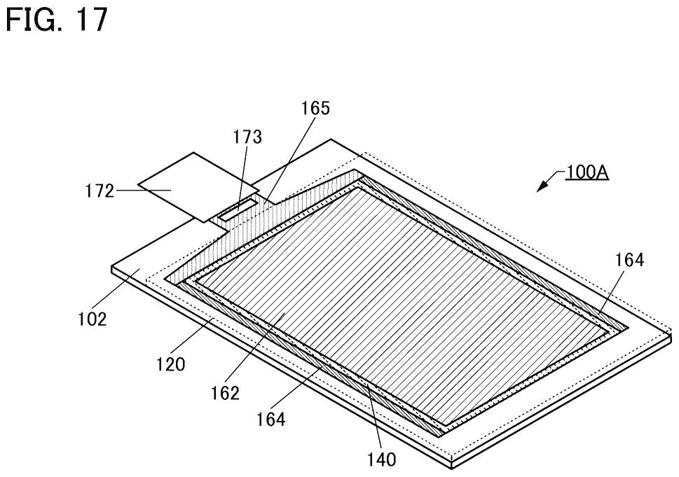

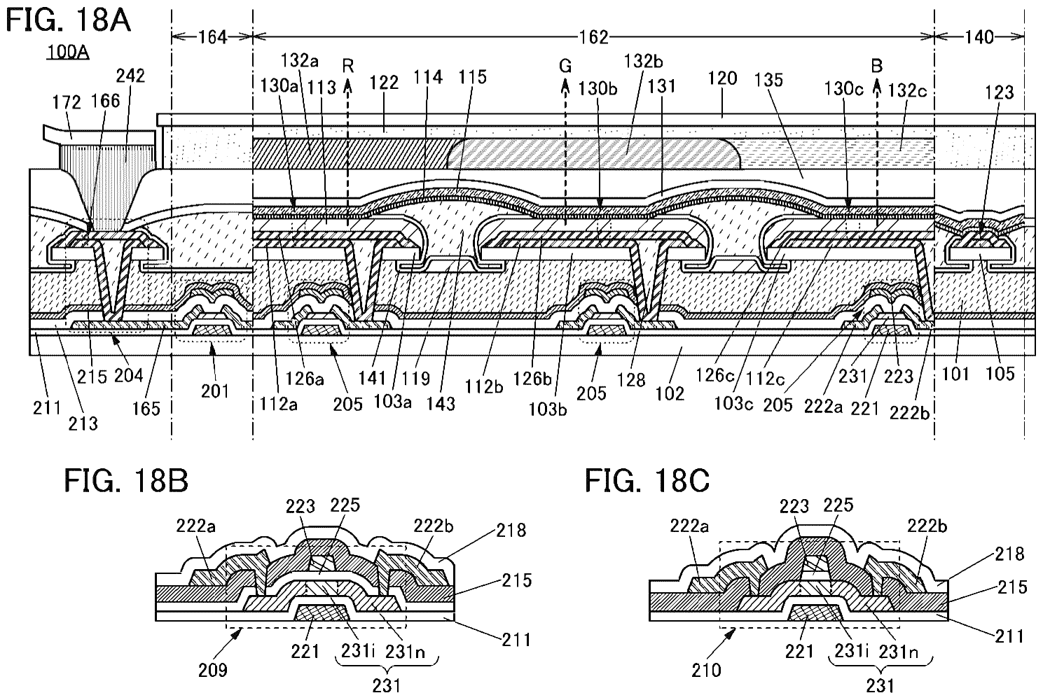

FIG. 17 is a perspective view of a display device 100A, and FIG. 18A is a cross-sectional view of the display device 100A.

The display device 100A has a structure in which the substrate 120 and the substrate 102 are bonded to each other. In FIG. 17, the substrate 120 is denoted by the dashed line.

The display device 100A includes a display portion 162, the connection portion 140, a circuit 164, a wiring 165, and the like. FIG. 17 illustrates an example in which an IC 173 and an FPC 172 are mounted on the display device 100A. Thus, the structure illustrated in FIG. 17 can be regarded as a display module including the display device 100A, the IC (integrated circuit), and the FPC.

In this specification and the like a display device in which a substrate is equipped with a connector such as an FPC or mounted with an IC is referred to as a display module.

The connection portion 140 is provided outside the display portion 162. The connection portion 140 can be provided along one or more sides of the display portion 162. The number of connection portions 140 can be one or more. FIG. 17 illustrates an example where the connection portion 140 is provided to surround the four sides of the display portion.

As the circuit 164, a scan line driver circuit can be used, for example.

The wiring 165 has a function of supplying a signal and power to the display portion 162 and the circuit 164. The signal and power are input to the wiring 165 from the outside through the FPC 172 or from the IC 173.

FIG. 17 illustrates an example where the IC 173 is provided over the substrate 102 by a COG (Chip On Glass) method, a COF (Chip On Film) method, or the like. An IC including a scan line driver circuit, a signal line driver circuit, or the like can be used as the IC 173, for example. Note that the display device 100A and the display module are not necessarily provided with an IC. The IC may be mounted on the FPC by a COF method, for example.

FIG. 18A illustrates an example of cross sections of part of a region including the FPC 172, part of the circuit 164, part of the display portion 162, part of the connection portion 140, and part of a region including an end portion of the display device 100A.

The display device 100A illustrated in FIG. 18A includes a transistor 201, a transistor 205, the light-emitting device 130a, the light-emitting device 130b, the light-emitting device 130c, the coloring layer 132a, the coloring layer 132b, the coloring layer 132c, and the like between the substrate 102 and the substrate 120. The light-emitting element 130a, the light-emitting element 130b, and the light-emitting element 130c can emit white light, for example. The coloring layer 132a has higher transmittance of red light than those of light of other colors, for example. The coloring layer 132b has higher transmittance of green light than those of light of other colors, for example. The coloring layer 132c has higher transmittance of blue light with than those of light of other colors, for example. The organic layer 119, the insulating layer 141, and the insulating layer 143 are provided between adjacent light-emitting elements 130.

Except for the structure of the pixel electrode, the structure described in Embodiment 1 can be employed for the light-emitting element 130a, the light-emitting element 130b, and the light-emitting element 130c.

The light-emitting device 130a includes a conductive layer 112a and a conductive layer 126a over the conductive layer 112a. The conductive layer 112a and the conductive layer 126a correspond to the pixel electrode 11a described in Embodiment 1.

The light-emitting device 130b includes a conductive layer 112b and a conductive layer 126b over the conductive layer 112b. The conductive layer 112b and the conductive layer 126b correspond to the pixel electrode 111b described in Embodiment 1.

The light-emitting device 130c includes a conductive layer 112c and a conductive layer 126c over the conductive layer 112c. The conductive layer 112c and the conductive layer 126c correspond to the pixel electrode 111c described in Embodiment 1.

The conductive layer 112a is connected to a conductive layer 222b included in the transistor 205 through an opening provided in the insulating layer 101 and the insulating layer 103a. An end portion of the conductive layer 126a is located outward from an end portion of the conductive layer 112a.

The conductive layer 112b and the conductive layer 126b in the light-emitting element 130b and the conductive layer 112c and the conductive layer 126c in the light-emitting element 130c are similar to those of the conductive layer 112a and the conductive layer 126a in the light-emitting element 130a; thus, the detailed description is omitted.

A depressed portion is formed in the conductive layer 112a to cover the opening provided in the insulating layer 101 and the insulating layer 103a. A depressed portion is formed in the conductive layer 112b to cover the opening provided in the insulating layer 101 and the insulating layer 103b. A depressed portion is formed in the conductive layer 112c to cover the opening provided in the insulating layer 101 and the insulating layer 103c. A layer 128 is embedded in each of the depressed portions of the conductive layer 112a, the conductive layer 112b, and the conductive layer 112c.

The layer 128 has a planarization function for the depressed portions of the conductive layer 112a, the conductive layer 112b, and the conductive layer 112c. The conductive layer 126a electrically connected to the conductive layer 112a is provided over the conductive layer 112a and the layer 128. The conductive layer 126b electrically connected to the conductive layer 112b is provided over the conductive layer 112b and the layer 128. The conductive layer 126c electrically connected to the conductive layer 112c is provided over the conductive layer 112c and the layer 128. Thus, regions overlapping with the depressed portions of the conductive layer 112a, the conductive layer 112b, and the conductive layer 112c can also be used as the light-emitting regions, increasing the aperture ratio of the pixels.

The layer 128 may be an insulating layer or a conductive layer. Any of a variety of inorganic insulating materials, organic insulating materials, and conductive materials can be used for the layer 128 as appropriate. Specifically, the layer 128 is preferably formed using an insulating material and is particularly preferably formed using an organic insulating material. For the layer 128, an organic insulating material that can be used for the protective layer 135 can be used, for example.

The protective layer 131 is provided over the light-emitting element 130a, the light-emitting element 130b, and the light-emitting element 130c, and the protective layer 135 is provided over the protective layer 131. The coloring layer 132a, the coloring layer 132b, and the coloring layer 132c are provided over the protective layer 135. The coloring layer 132a, the coloring layer 132b, the coloring layer 132c, and the protective layer 135 are bonded to the substrate 120 with the adhesive layer 122 therebetween.

A solid sealing structure, a hollow sealing structure, or the like can be employed to seal the light-emitting element 130. In FIG. 18A, a solid sealing structure is employed in which a space between the substrate 120 and the protective layer 135 is filled with the adhesive layer 122. Alternatively, a hollow sealing structure in which the space is filled with an inert gas (e.g., nitrogen or argon) may be employed. Here, the adhesive layer 122 may be provided not to overlap with the light-emitting element 130. Alternatively, the space may be filled with a frame-shaped resin different from the adhesive layer 122.

In the connection portion 140, the insulating layer 105 is provided over the insulating layer 101, and the conductive layer 123 is provided over the insulating layer 105. The conductive layer 123 can have a stacked-layer structure of a conductive layer obtained by processing the same conductive film as the conductive layer 112a, the conductive layer 112b, and the conductive layer 112c, and a conductive layer obtained by processing the same conductive film as the conductive layer 126a, the conductive layer 126b, and the conductive layer 126c. An end portion of the conductive layer 123 is covered with the insulating layer 141 and the insulating layer 143. The common layer 114 is provided over the conductive layer 123, and the common electrode 115 is provided over the common layer 114. The conductive layer 123 and the common electrode 115 are electrically connected to each other through the common layer 114. Note that the common layer 114 is not necessarily formed in the connection portion 140. In this case, the conductive layer 123 and the common electrode 115 are directly in contact with each other to be electrically connected to each other.

The display device 100A is of a top emission type. Light emitted by the light-emitting element is emitted toward the substrate 120 side. For the substrate 120, a material having a high visible-light-transmitting property is preferably used. In contrast, there is no limitation on the light-transmitting property of a material used for the substrate 102. The pixel electrode (the conductive layer 112 and the conductive layer 126) contains a material that reflects visible light, and a counter electrode (the common electrode 115) contains a material that transmits visible light.

The transistor 201 and the transistor 205 are formed over the substrate 102. These transistors can be fabricated using the same material in the same step.

An insulating layer 211, an insulating layer 213, the insulating layer 215, and the insulating layer 101 are provided in this order over the substrate 102. Part of the insulating layer 211 functions as a gate insulating layer of each transistor. Part of the insulating layer 213 functions as a gate insulating layer of each transistor. The insulating layer 215 is provided to cover the transistors. The insulating layer 101 is provided to cover the transistors and has a function of a planarization layer. Note that the number of gate insulating layers and the number of insulating layers covering the transistors are not limited and may each be one or two or more.

A material in which impurities such as water and hydrogen do not easily diffuse is preferably used for at least one of the insulating layers covering the transistors. This allows the insulating layer to function as a barrier layer. Such a structure can effectively inhibit diffusion of impurities into the transistors from the outside and increase the reliability of a display device.

An inorganic insulating film is preferably used as each of the insulating layer 211, the insulating layer 213, and the insulating layer 215. As the inorganic insulating film, a silicon nitride film, a silicon oxynitride film, a silicon oxide film, a silicon nitride oxide film, an aluminum oxide film, or an aluminum nitride film can be used, for example. A hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may be used. A stack including two or more of the above insulating films may also be used.

Each of the transistor 201 and the transistor 205 includes a conductive layer 221 functioning as a gate, the insulating layer 211 functioning as a gate insulating layer, a conductive layer 222a and the conductive layer 222b functioning as a source and a drain, a semiconductor layer 231, the insulating layer 213 functioning as a gate insulating layer, and a conductive layer 223 functioning as a gate. Here, a plurality of layers obtained by processing the same conductive film are shown with the same hatching pattern. The insulating layer 211 is positioned between the conductive layer 221 and the semiconductor layer 231. The insulating layer 213 is positioned between the conductive layer 223 and the semiconductor layer 231.

There is no particular limitation on the structure of the transistors included in the display device of this embodiment. For example, a planar transistor, a staggered transistor, an inverted staggered transistor, or the like can be used. A top-gate transistor structure or a bottom-gate transistor structure may be employed. Alternatively, gates may be provided above and below a semiconductor layer where a channel is formed.

The structure where the semiconductor layer where a channel is formed is provided between two gates is used for the transistor 201 and the transistor 205. The two gates may be connected to each other and supplied with the same signal to drive the transistor. Alternatively, a potential for controlling the threshold voltage may be supplied to one of the two gates and a potential for driving may be supplied to the other to control the threshold voltage of the transistor.

There is no particular limitation on the crystallinity of a semiconductor material used for the transistors, and an amorphous semiconductor or a semiconductor having crystallinity (a microcrystalline semiconductor, a polycrystalline semiconductor, a single crystal semiconductor, or a semiconductor partly including crystal regions) may be used. A semiconductor having crystallinity is preferably used, in which case degradation of the transistor characteristics can be inhibited.

The semiconductor layer of the transistor preferably includes a metal oxide (also referred to as an oxide semiconductor). That is, a transistor including a metal oxide in its channel formation region (hereinafter, also referred to as an OS transistor) is preferably used for the display device of this embodiment.

As the oxide semiconductor having crystallinity, a CAAC (c-axis aligned crystalline)-OS, an nc (nanocrystalline)-OS, and the like can be given.

Alternatively, a transistor including silicon in its channel formation region (a Si transistor) may be used. As silicon, single crystal silicon, polycrystalline silicon, amorphous silicon, and the like can be given. In particular, a transistor including low-temperature polysilicon (LTPS) in a semiconductor layer (such a transistor is referred to as an LTPS transistor below) can be used. The LTPS transistor has high field-effect mobility and excellent frequency characteristics.

With use of Si transistors such as LTPS transistors as the transistor 201, the transistor 205, and the like, a circuit required to be driven at a high frequency (e.g., a source driver circuit) can be formed on the same substrate as the display portion. Thus, external circuits mounted on the display device can be simplified, and parts costs and mounting costs can be reduced.

An OS transistor has extremely higher field-effect mobility than a transistor including amorphous silicon. In addition, the OS transistor has extremely low leakage current between a source and a drain in an off state (hereinafter, also referred to as off-state current), and charge accumulated in a capacitor that is connected in series to the transistor can be retained for a long period. Furthermore, power consumption of the display device can be reduced with use of an OS transistor.

To increase the emission luminance of the light-emitting element included in the pixel circuit, the amount of current fed through the light-emitting element needs to be increased. For this, it is necessary to increase the source-drain voltage of a driving transistor included in the pixel circuit. Since an OS transistor has a higher breakdown voltage between the source and the drain than a Si transistor, a high voltage can be applied between the source and the drain of the OS transistor. Accordingly, when an OS transistor is used as the driving transistor included in the pixel circuit, the amount of current flowing through the light-emitting element can be increased, so that the emission luminance of the light-emitting element can be increased.

When transistors operate in a saturation region, a change in source-drain current with respect to a change in gate-source voltage can be smaller in an OS transistor than in a Si transistor. Accordingly, when an OS transistor is used as the driving transistor in the pixel circuit, the amount of current flowing between the source and the drain can be set minutely by a change in gate-source voltage; hence, the amount of current flowing through the light-emitting element can be precisely controlled. Accordingly, the number of gray levels controlled by the pixel circuit can be increased.

Regarding saturation characteristics of current flowing when a transistor operates in a saturation region, even in the case where the source-drain voltage of an OS transistor increases gradually, more stable current (saturation current) can be made flow through an OS transistor than through a Si transistor. Thus, by using an OS transistor as the driving transistor, a stable current can be fed through a light-emitting element even when the current-voltage characteristics of an EL element vary, for example. In other words, when the OS transistor operates in the saturation region, the source-drain current hardly changes with an increase in the source-drain voltage; hence, the emission luminance of the light-emitting element can be stable.

As described above, with use of an OS transistor as a driving transistor included in the pixel circuit, it is possible to achieve “inhibition of black-level degradation,” “increase in emission luminance,” “increase in gray level,” “inhibition of variation in light-emitting elements,” and the like.

The semiconductor layer preferably includes indium, M (M is one or more selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. Specifically, M is preferably one or more selected from aluminum, gallium, yttrium, and tin.

It is particularly preferable that an oxide containing indium (In), gallium (Ga), and zinc (Zn) (also referred to as IGZO) be used for the semiconductor layer. Alternatively, it is preferable to use an oxide containing indium, tin, and zinc. Further alternatively, it is preferable to use an oxide containing indium, gallium, tin, and zinc. Alternatively, an oxide containing indium (In), aluminum (Al), and zinc (Zn) (also referred to as IAZO) is preferably used for the semiconductor layer. Alternatively, an oxide containing indium (In), aluminum (Al), gallium (Ga), and zinc (Zn) (also referred to as IAGZO) is preferably used for the semiconductor layer.

When the semiconductor layer is an In-M-Zn oxide, the atomic ratio of In is preferably higher than or equal to the atomic ratio of M in the In-M-Zn oxide. Examples of the atomic ratio of the metal elements in such an In-M-Zn oxide are the follows: In:M:Zn=1:1:1 or a composition in the neighborhood thereof; In:M:Zn=1:1:1.2 or a composition in the neighborhood thereof; In:M:Zn=1:3:2 or a composition in the neighborhood thereof; In:M:Zn=1:3:4 or a composition in the neighborhood thereof; In:M:Zn=2:1:3 or a composition in the neighborhood thereof; In:M:Zn=3:1:2 or a composition in the neighborhood thereof; In:M:Zn=4:2:3 or a composition in the neighborhood thereof; In:M:Zn=4:2:4.1 or a composition in the neighborhood thereof; In:M:Zn=5:1:3 or a composition in the neighborhood thereof; In:M:Zn=5:1:6 or a composition in the neighborhood thereof; In:M:Zn=5:1:7 or a composition in the neighborhood thereof; In:M:Zn=5:1:8 or a composition in the neighborhood thereof; In:M:Zn=6:1:6 or a composition in the neighborhood thereof; and In:M:Zn=5:2:5 or a composition in the neighborhood thereof. Note that a composition in the neighborhood includes the range of ±30% of an intended atomic ratio.

For example, when the atomic ratio is described as In:Ga:Zn=4:2:3 or a composition in the neighborhood thereof, the case is included where the atomic proportion of Ga is greater than or equal to 1 and less than or equal to 3 and the atomic proportion of Zn is greater than or equal to 2 and less than or equal to 4 with the atomic proportion of In being 4. When the atomic ratio is described as In:Ga:Zn=5:1:6 or a composition in the neighborhood thereof, the case is included where the atomic proportion of Ga is greater than 0.1 and less than or equal to 2 and the atomic proportion of Zn is greater than or equal to 5 and less than or equal to 7 with the atomic proportion of In being 5. When the atomic ratio is described as In:Ga:Zn=1:1:1 or a composition in the neighborhood thereof, the case is included where the atomic proportion of Ga is greater than 0.1 and less than or equal to 2 and the atomic proportion of Zn is greater than 0.1 and less than or equal to 2 with the atomic proportion of In being 1.

The transistor included in the circuit 164 and the transistor included in the display portion 162 may have the same structure or different structures. One structure or two or more types of structures may be employed for a plurality of transistors included in the circuit 164. Similarly, one structure or two or more types of structures may be employed for a plurality of transistors included in the display portion 162.

All of the transistors included in the display portion 162 may be OS transistors or all of the transistors included in the display portion 162 may be Si transistors; alternatively, some of the transistors included in the display portion 162 may be OS transistors and the others may be Si transistors.

For example, when both an LTPS transistor and an OS transistor are used in the display portion 162, the display device can have low power consumption and high drive capability. A structure in which an LTPS transistor and an OS transistor are used in combination is referred to as LTPO in some cases. Note that as a further preferable example, a structure is given in which an OS transistor is used as a transistor functioning as a switch for controlling conduction and non-conduction between wirings and an LTPS transistor is used as a transistor for controlling current.

For example, one transistor included in the display portion 162 may function as a transistor for controlling current flowing through the light-emitting element 130 and be also referred to as a driving transistor. One of a source and a drain of the driving transistor is electrically connected to the pixel electrode of the light-emitting element 130. An LTPS transistor is preferably used as the driving transistor. In that case, the amount of current flowing through the light-emitting element 130 can be increased in the pixel circuit.

Another transistor included in the display portion 162 functions as a switch for controlling selection and non-selection of the pixel and can be referred to as a selection transistor. A gate of the selection transistor is electrically connected to a gate line, and one of a source and a drain thereof is electrically connected to a signal line. An OS transistor is preferably used as the selection transistor. In that case, the gray level of the pixel can be maintained even with an extremely low frame frequency (e.g., lower than or equal to 1 fps); thus, power consumption can be reduced by stopping the driver in displaying a still image.

As described above, the display device of one embodiment of the present invention can have all of a high aperture ratio, high resolution, high display quality, and low power consumption.

Note that the display device of one embodiment of the present invention has a structure including the OS transistor and the light-emitting element having an MML (metal maskless) structure. With this structure, the leakage current that might flow through the transistor and the leakage current that might flow between adjacent light-emitting elements (also referred to as lateral leakage current, side leakage current, or the like) can be extremely low. With the structure, a viewer can notice any one or more of the image crispness, the image sharpness, a high chroma, and a high contrast ratio in an image displayed on the display device. When the leakage current that would flow through the transistor and the lateral leakage current between the light-emitting elements are extremely low, light leakage that might occur in black display (what is called black-level degradation) or the like can be minimized.

FIG. 18B and FIG. 18C illustrate other structure examples of transistors.

A transistor 209 and a transistor 210 each include the conductive layer 221 functioning as a gate, the insulating layer 211 functioning as a gate insulating layer, the semiconductor layer 231 including a channel formation region 231i and a pair of low-resistance regions 231n, the conductive layer 222a connected to one of the pair of low-resistance regions 231n, the conductive layer 222b connected to the other of the pair of the low-resistance regions 231n, an insulating layer 225 functioning as a gate insulating layer, the conductive layer 223 functioning as a gate, and the insulating layer 215 covering the conductive layer 223. The insulating layer 211 is located between the conductive layer 221 and the channel formation region 231i. The insulating layer 225 is located at least between the conductive layer 223 and the channel formation region 231i. Furthermore, an insulating layer 218 covering the transistor may be provided.

FIG. 18B illustrates an example of the transistor 209 in which the insulating layer 225 covers the top and side surfaces of the semiconductor layer 231. The conductive layer 222a and the conductive layer 222b are connected to the low-resistance regions 231n through openings provided in the insulating layer 225 and the insulating layer 215. One of the conductive layer 222a and the conductive layer 222b functions as a source, and the other functions as a drain.

Meanwhile, in the transistor 210 illustrated in FIG. 18C, the insulating layer 225 overlaps with the channel formation region 231i of the semiconductor layer 231 and does not overlap with the low-resistance regions 231n. The structure illustrated in FIG. 18C is obtained by processing the insulating layer 225 with the conductive layer 223 as a mask, for example. In the transistor 210 illustrated in FIG. 18C, the insulating layer 215 is provided to cover the insulating layer 225 and the conductive layer 223, and the conductive layer 222a and the conductive layer 222b are connected to the low-resistance regions 231n through the openings in the insulating layer 215.

A connection portion 204 is provided in a region of the substrate 102 not overlapping with the substrate 120. In the connection portion 204, the wiring 165 is electrically connected to the FPC 172 through a conductive layer 166 and a connection layer 242. The conductive layer 166 can have a stacked-layer structure of a conductive layer obtained by processing the same conductive film as the conductive layer 112a, the conductive layer 112b, and the conductive layer 112c and a conductive layer obtained by processing the same conductive film as the conductive layer 126a, the conductive layer 126b, and the conductive layer 126c. A variety of optical members can be provided on the outer surface of the substrate 120.

As the connection layer 242, an anisotropic conductive film (ACF), an anisotropic conductive paste (ACP), or the like can be used.

### [Display Device 100B]

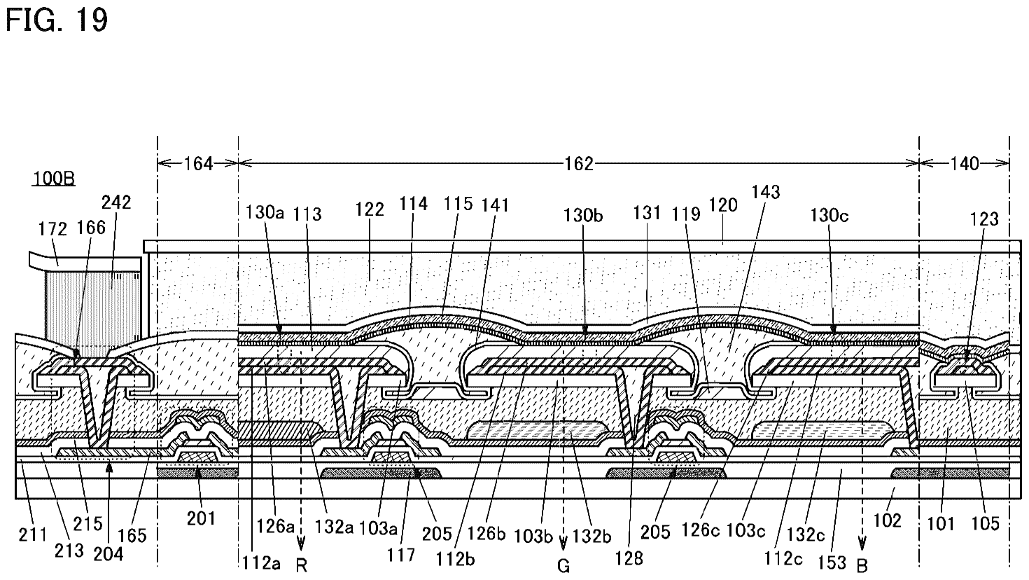

A display device 100B illustrated in FIG. 19 differs from the display device 100A mainly in having a bottom-emission structure.

Light emitted by the light-emitting element is emitted toward the substrate 102 side. For the substrate 102, a material having a high visible-light-transmitting property is preferably used. In contrast, there is no limitation on the light-transmitting property of a material used for the substrate 120.

The light-blocking layer 117 is preferably formed between the substrate 102 and the transistor 201 and between the substrate 102 and the transistor 205. FIG. 19 illustrates an example in which the light-blocking layer 117 is provided over the substrate 102, an insulating layer 153 is provided over the substrate 102 and the light-blocking layer 117, and the transistor 201, the transistor 205, and the like are provided over the insulating layer 153.

A material having a high visible-light-transmitting property is used for each of the conductive layer 112a, the conductive layer 112b, the conductive layer 126a, and the conductive layer 126b. A material reflecting visible light is preferably used for the common electrode 115.

Note that although FIG. 18A and FIG. 19 each illustrate an example where the top surface of the layer 128 includes a planar portion, the shape of the layer 128 is not particularly limited. The top surface of the layer 128 can have a shape in which its center and the vicinity thereof are depressed, i.e., a shape including a concave surface, seen from the XZ plane or the YZ plane, for example. Alternatively, the top surface of the layer 128 can have a shape in which its center and the vicinity thereof bulge, i.e., having a shape including a convex surface, seen from the XZ plane or the YZ plane, for example. The top surface of the layer 128 may include both a convex surface and a concave surface. The number of convex surfaces and the number of concave surfaces included in the top surface of the layer 128 are not limited and can each be one or more.

The level of the top surface of the layer 128 and the level of the top surface of the conductive layer 112 may be equal to or substantially equal to each other, or may be different from each other. For example, the level of the top surface of the layer 128 may be either lower or higher than the level of the top surface of the conductive layer 112.

This embodiment can be combined with the other embodiments or an example as appropriate.

### Embodiment 4

In this embodiment, light-emitting elements that can be used for the display device of one embodiment of the present invention will be described with reference to drawings.

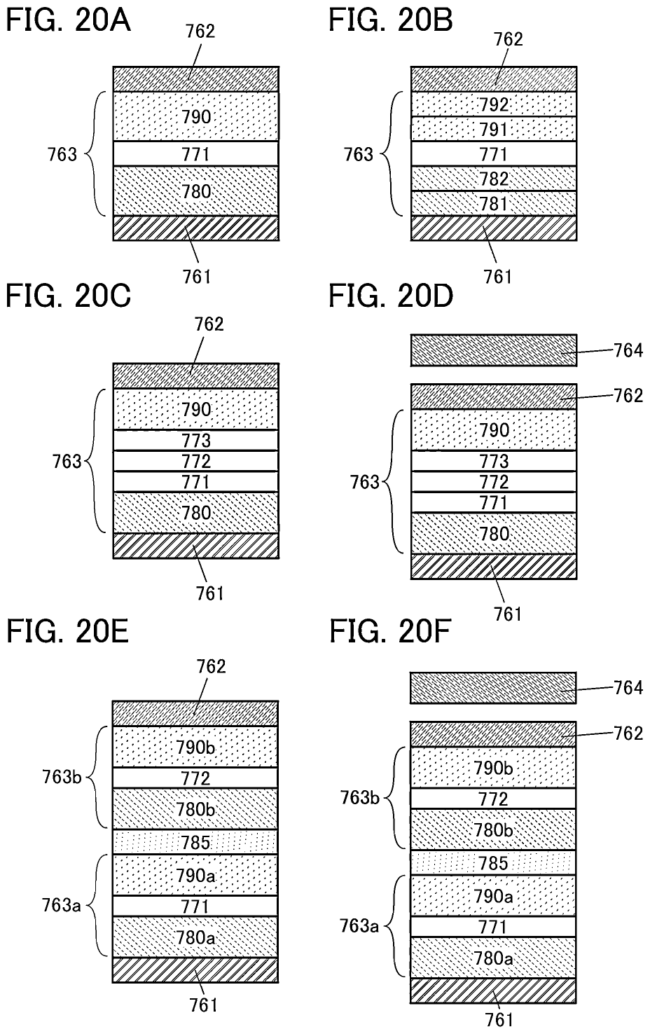

As illustrated in FIG. 20A, the light-emitting element includes an EL layer 763 between a pair of electrodes (a lower electrode 761 and an upper electrode 762). The EL layer 763 can be formed of a plurality of layers such as a layer 780, a light-emitting layer 771, and a layer 790.

The light-emitting layer 771 includes at least a light-emitting substance.

In the case where the lower electrode 761 is an anode and the upper electrode 762 is a cathode, the layer 780 includes one or more of a layer including a substance with a high hole-injection property (a hole-injection layer), a layer including a substance with a high hole-transport property (a hole-transport layer), and a layer including a substance with a high electron-blocking property (an electron-blocking layer). Furthermore, the layer 790 includes one or more of a layer including a substance with a high electron-injection property (an electron-injection layer), a layer including a substance with a high electron-transport property (an electron-transport layer), and a layer including a substance with a high hole-blocking property (a hole-blocking layer). In the case where the lower electrode 761 is a cathode and the upper electrode 762 is an anode, the above structures of the layer 780 and the layer 790 are replaced with each other.

The structure including the layer 780, the light-emitting layer 771, and the layer 790, which is provided between a pair of electrodes, can function as a single light-emitting unit, and the structure in FIG. 20A is referred to as a single structure in this specification and the like.

FIG. 20B is a variation example of the EL layer 763 included in the light-emitting element illustrated in FIG. 20A. Specifically, the light-emitting element illustrated in FIG. 20B includes a layer 781 over the lower electrode 761, a layer 782 over the layer 781, the light-emitting layer 771 over the layer 782, a layer 791 over the light-emitting layer 771, a layer 792 over the layer 791, and the upper electrode 762 over the layer 792.

In the case where the lower electrode 761 is an anode and the upper electrode 762 is a cathode, the layer 781 can be a hole-injection layer, the layer 782 can be a hole-transport layer, the layer 791 can be an electron-transport layer, and the layer 792 can be an electron-injection layer, for example. In the case where the lower electrode 761 is a cathode and the upper electrode 762 is an anode, the layer 781 can be an electron-injection layer, the layer 782 can be an electron-transport layer, the layer 791 can be a hole-transport layer, and the layer 792 can be a hole-injection layer. With such a layer structure, carriers can be efficiently injected to the light-emitting layer 771, and the efficiency of the recombination of carriers in the light-emitting layer 771 can be increased.

Note that structures in which a plurality of light-emitting layers (the light-emitting layer 771, a light-emitting layer 772, and a light-emitting layer 773) are provided between the layer 780 and the layer 790 as illustrated in FIG. 20C and FIG. 20D are variations of the single structure. Although FIG. 20C and FIG. 20D illustrate the examples where three light-emitting layers are included, the light-emitting element having a single structure may include two or four or more light-emitting layers. In addition, the light-emitting element having a single structure may include a buffer layer between two light-emitting layers.

A structure in which a plurality of light-emitting units (a light-emitting unit 763a and a light-emitting unit 763b) are connected in series with a charge-generation layer 785 (also referred to as an intermediate layer) therebetween as illustrated in FIG. 20E and FIG. 20F is referred to as a tandem structure in this specification and the like. Note that the tandem structure may be referred to as a stack structure. The tandem structure enables a light-emitting element capable of high-luminance light emission. Furthermore, the tandem structure reduces the amount of current needed for obtaining the same luminance as compared with a single structure, and thus can improve the reliability.

Note that FIG. 20D and FIG. 20F illustrate examples where the display device includes a layer 764 overlapping with the light-emitting element. FIG. 20D illustrates an example in which the layer 764 overlaps with the light-emitting element illustrated in FIG. 20C, and FIG. 20F illustrates an example in which the layer 764 overlaps with the light-emitting element illustrated in FIG. 20E. In FIG. 20D and FIG. 20F, a conductive film transmitting visible light is used for the upper electrode 762 to extract light to the upper electrode 762 side.

One or both of a color conversion layer and a color filter (coloring layer) can be used as the layer 764.

In FIG. 20C and FIG. 20D, light-emitting substances that emit light of the same color, or moreover, the same light-emitting substance may be used for the light-emitting layer 771, the light-emitting layer 772, and the light-emitting layer 773. For example, a light-emitting substance that emits blue light may be used for the light-emitting layer 771, the light-emitting layer 772, and the light-emitting layer 773. In a subpixel that emits blue light, blue light emitted from the light-emitting element can be extracted. In a subpixel that emits red light and a subpixel that emits green light, by providing a color conversion layer as the layer 764 illustrated in FIG. 20D, blue light emitted from the light-emitting element can be converted into light with a longer wavelength, and red light or green light can be extracted. As the layer 764, both a color conversion layer and a coloring layer are preferably used. In some cases, part of light emitted from the light-emitting element is transmitted through the color conversion layer without being converted. When light transmitted through the color conversion layer is extracted through the coloring layer, light other than light of the intended color can be absorbed by the coloring layer, and color purity of light exhibited by a subpixel can be improved.

Alternatively, in FIG. 20C and FIG. 20D, light-emitting substances emitting light of different colors may be used for the light-emitting layer 771, the light-emitting layer 772, and the light-emitting layer 773. White light emission can be obtained when the light-emitting layer 771, the light-emitting layer 772, and the light-emitting layer 773 emit light of complementary colors. The light-emitting element having a single structure preferably includes a light-emitting layer including a light-emitting substance emitting blue light and a light-emitting layer including a light-emitting substance emitting visible light with a longer wavelength than blue light, for example.

A color filter may be provided as the layer 764 illustrated in FIG. 20D. When white light passes through the color filter, light of a desired color can be obtained.

In the case where the light-emitting element having a single structure includes three light-emitting layers, for example, a light-emitting layer including a light-emitting substance emitting red (R) light, a light-emitting layer including a light-emitting substance emitting green (G) light, and a light-emitting layer including a light-emitting substance emitting blue (B) light are preferably included. The stacking order of the light-emitting layers can be RGB or RBG from an anode side, for example. In that case, a buffer layer may be provided between R and G or between R and B.

For example, in the case where the light-emitting element having a single structure includes two light-emitting layers, the light-emitting element preferably includes a light-emitting layer including a light-emitting substance that emits blue (B) light and a light-emitting layer including a light-emitting substance that emits yellow (Y) light. Such a structure may be referred to as a BY single structure.

The light-emitting element emitting white light preferably includes two or more light-emitting layers. For example, when white light emission is obtained using two light-emitting layers, two or more light-emitting layers are selected such that their emission colors are complementary. For example, when an emission color of a first light-emitting layer and an emission color of a second light-emitting layer are complementary colors, the light-emitting element can be configured to emit white light as a whole. To obtain white light emission by using three or more light-emitting layers, the light-emitting element is configured to emit white light as a whole by combining emission colors of the three or more light-emitting layers.

Also in FIG. 20C and FIG. 20D, the layer 780 and the layer 790 may each independently have a stacked-layer structure of two or more layers as illustrated in FIG. 20B.

In FIG. 20E and FIG. 20F, light-emitting substances that emit light of the same color, or moreover, the same light-emitting substance may be used for the light-emitting layer 771 and the light-emitting layer 772. For example, in light-emitting elements included in subpixels emitting light of different colors, a light-emitting substance that emits blue light can be used for each of the light-emitting layer 771 and the light-emitting layer 772. In a subpixel that emits blue light, blue light emitted from the light-emitting element can be extracted. In the subpixel that emits red light and the subpixel that emits green light, by providing a color conversion layer as the layer 764 illustrated in FIG. 20F, blue light emitted from the light-emitting element can be converted into light with a longer wavelength, and red light or green light can be extracted. As the layer 764, both a color conversion layer and a coloring layer are preferably used.

In the case where the light-emitting element having the structure illustrated in FIG. 20E or FIG. 20F is used for the subpixels emitting different colors, the subpixels may use different light-emitting substances. Specifically, in the light-emitting element included in the subpixel emitting red light, a light-emitting substance that emits red light can be used for each of the light-emitting layer 771 and the light-emitting layer 772. Similarly, in the light-emitting element included in the subpixel emitting green light, a light-emitting substance that emits green light can be used for each of the light-emitting layer 771 and the light-emitting layer 772. In the light-emitting element included in the subpixel emitting blue light, a light-emitting substance that emits blue light can be used for each of the light-emitting layer 771 and the light-emitting layer 772. A display device having such a structure can be regarded as employing a light-emitting element with the tandem structure and the SBS structure. Thus, advantages of both the tandem structure and the SBS structure can be achieved. Accordingly, a light-emitting element being capable of high-luminance light emission and having high reliability can be obtained.

In FIG. 20E and FIG. 20F, light-emitting substances that emit light of different colors may be used for the light-emitting layer 771 and the light-emitting layer 772. White light emission can be obtained when the light-emitting layer 771 and the light-emitting layer 772 emit light of complementary colors. A color filter may be provided as the layer 764 illustrated in FIG. 20F. When white light passes through the color filter, light of a desired color can be obtained.

Although FIG. 20E and FIG. 20F illustrate examples where the light-emitting unit 763a includes one light-emitting layer 771 and the light-emitting unit 763b includes one light-emitting layer 772, one embodiment of the present invention is not limited thereto. Each of the light-emitting unit 763 a and the light-emitting unit 763b may include two or more light-emitting layers.

In addition, although FIG. 20E and FIG. 20F illustrate the light-emitting element including two light-emitting units, one embodiment of the present invention is not limited thereto. The light-emitting element may include three or more light-emitting units. Note that a structure including two light-emitting units and a structure including three light-emitting units may be referred to as a two-unit tandem structure and a three-unit tandem structure, respectively.

In FIG. 20E and FIG. 20F, the light-emitting unit 763a includes a layer 780a, the light-emitting layer 771, and a layer 790a, and the light-emitting unit 763b includes a layer 780b, the light-emitting layer 772, and a layer 790b.

In the case where the lower electrode 761 is an anode and the upper electrode 762 is a cathode, the layer 780a and the layer 780b each include one or more of a hole-injection layer, a hole-transport layer, and an electron-blocking layer. The layer 790a and the layer 790b each include one or more of an electron-injection layer, an electron-transport layer, and a hole-blocking layer. In the case where the lower electrode 761 is a cathode and the upper electrode 762 is an anode, the structures of the layer 780a and the layer 790a are replaced with each other, and the structures of the layer 780b and the layer 790b are also replaced with each other.

In the case where the lower electrode 761 is an anode and the upper electrode 762 is a cathode, for example, the layer 780a includes a hole-injection layer and a hole-transport layer over the hole-injection layer, and may further include an electron-blocking layer over the hole-transport layer. The layer 790a includes an electron-transport layer, and may further include a hole-blocking layer between the light-emitting layer 771 and the electron-transport layer. The layer 780b includes a hole-transport layer, and may further include an electron-blocking layer over the hole-transport layer. The layer 790b includes an electron-transport layer and an electron-injection layer over the electron-transport layer, and may further include a hole-blocking layer between the light-emitting layer 772 and the electron-transport layer. In the case where the lower electrode 761 is a cathode and the upper electrode 762 is an anode, for example, the layer 780a includes an electron-injection layer and an electron-transport layer over the electron-injection layer, and may further include a hole-blocking layer over the electron-transport layer. The layer 790a includes a hole-transport layer, and may further include an electron-blocking layer between the light-emitting layer 771 and the hole-transport layer. The layer 780b includes an electron-transport layer, and may further include a hole-blocking layer over the electron-transport layer. The layer 790b includes a hole-transport layer and a hole-injection layer over the hole-transport layer, and may further include an electron-blocking layer between the light-emitting layer 772 and the hole-transport layer.

In the case of fabricating a light-emitting element with the tandem structure, two light-emitting units are stacked with the charge-generation layer 785 therebetween. The charge-generation layer 785 includes at least a charge-generation region. The charge-generation layer 785 has a function of injecting electrons into one of the two light-emitting units and injecting holes into the other when voltage is applied between the pair of electrodes.

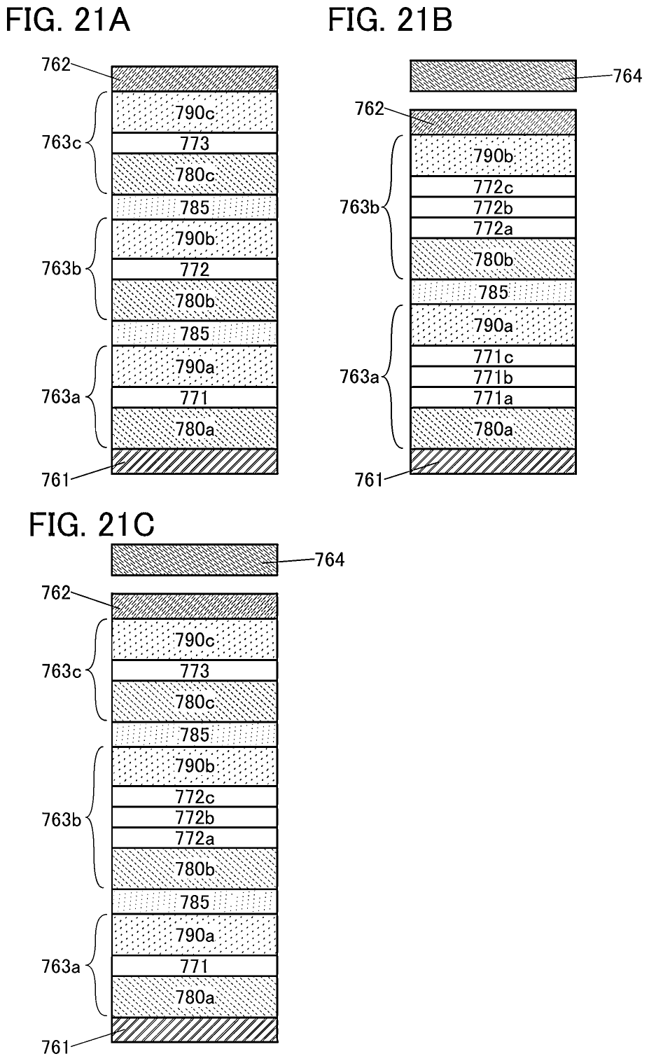

The structures illustrated in FIG. 21A to FIG. 21C can be given as examples of the light-emitting element having a tandem structure.

FIG. 21A illustrates a structure including three light-emitting units. As shown in FIG. 21A, a plurality of light-emitting units (the light-emitting unit 763a, the light-emitting unit 763b, and a light-emitting unit 763c) are connected in series through charge-generation layers 785. The light-emitting unit 763a includes the layer 780a, the light-emitting layer 771, and the layer 790a. The light-emitting unit 763b includes the layer 780b, the light-emitting layer 772, and the layer 790b. The light-emitting unit 763c includes a layer 780c, the light-emitting layer 773, and a layer 790c. Note that the layer 780c can have a structure applicable to the layer 780a and the layer 780b, and the layer 790c can have a structure applicable to the layer 790a and the layer 790b.

In FIG. 21A, the light-emitting layer 771, the light-emitting layer 772, and the light-emitting layer 773 preferably include light-emitting substances that emit light of the same color. Specifically, the light-emitting layer 771, the light-emitting layer 772, and the light-emitting layer 773 can each include a light-emitting substance that emits red (R) light (a so-called R\R\R three-unit tandem structure); the light-emitting layer 771, the light-emitting layer 772, and the light-emitting layer 773 can each include a light-emitting substance that emits green (G) light (a so-called a G\G\G three-unit tandem structure); or the light-emitting layer 771, the light-emitting layer 772, and the light-emitting layer 773 can each include a light-emitting substance that emits blue (B) light (a so-called B\BB \three-unit tandem structure). Note that “a\b” means that a light-emitting unit including a light-emitting substance that emits light of b is provided over a light-emitting unit including a light-emitting substance that emits light of a with a charge-generation layer therebetween, where a and b represent colors.

In FIG. 21A, light-emitting substances that emit light of different colors may be used for some or all of the light-emitting layer 771, the light-emitting layer 772, and the light-emitting layer 773. Examples of a combination of emission colors for the light-emitting layer 771, the light-emitting layer 772, and the light-emitting layer 773 include blue (B) for two of them and yellow (Y) for the other; and red (R) for one of them, green (G) for another, and blue (B) for the other.

Note that the structure of the light-emitting unit is not limited to that in FIG. 21A. For example, a light-emitting element with a tandem structure may be employed in which light-emitting units each including a plurality of light-emitting layers are stacked as illustrated in FIG. 21B. FIG. 21B illustrates a structure in which two light-emitting units (the light-emitting unit 763a and the light-emitting unit 763b) are connected in series with the charge-generation layer 785 therebetween. The light-emitting unit 763a includes the layer 780a, a light-emitting layer 771a, a light-emitting layer 771b, a light-emitting layer 771c, and the layer 790a. The light-emitting unit 763b includes the layer 780b, a light-emitting layer 772a, a light-emitting layer 772b, a light-emitting layer 772c, and the layer 790b.

In FIG. 21B, the light-emitting unit 763a is configured to emit white (W) light by selecting light-emitting substances for the light-emitting layer 771a, the light-emitting layer 771b, and the light-emitting layer 771c so that their emission colors are complementary colors. Furthermore, the light-emitting unit 763b is configured to emit white (W) light by selecting light-emitting substances for the light-emitting layer 772a, the light-emitting layer 772b, and the light-emitting layer 772c so that their emission colors are complementary colors. That is, the structure illustrated in FIG. 21B is a two-unit tandem structure of W\W. Note that there is no particular limitation on the stacking order of the light-emitting substances having complementary emission colors. The practitioner can select the optimal stacking order as appropriate. Although not illustrated, a three-unit tandem structure of W\W\W or a tandem structure with four or more units may be employed.

For a light-emitting element with a tandem structure, the following structure can be given: a B\Y or Y\B two-unit tandem structure including a light-emitting unit that emits yellow (Y) light and a light-emitting unit that emits blue (B) light; an R·G\B or B\R·G two-unit tandem structure including a light-emitting unit that emits red (R) light and green (G) light and a light-emitting unit that emits blue (B) light; a B\Y\B three-unit tandem structure including a light-emitting unit that emits blue (B) light, a light-emitting unit that emits yellow (Y) light, and a light-emitting unit that emits blue (B) light in this order; a B\YG\B three-unit tandem structure including a light-emitting unit that emits blue (B) light, a light-emitting unit that emits yellow green (YG) light, and a light-emitting unit that emits blue (B) light in this order; and a B\G\B three-unit tandem structure including a light-emitting unit that emits blue (B) light, a light-emitting unit that emits green (G) light, and a light-emitting unit that emits blue (B) light in this order. Note that “a-b” means that one light-emitting unit includes a light-emitting substance that emits light of a and a light-emitting substance that emits light of b.

As illustrated in FIG. 21C, a light-emitting unit including one light-emitting layer and a light-emitting unit including a plurality of light-emitting layers may be used in combination.

Specifically, in the structure illustrated in FIG. 21C, a plurality of light-emitting units (the light-emitting unit 763a, the light-emitting unit 763b, and the light-emitting unit 763c) are connected in series through the charge-generation layers 785. The light-emitting unit 763a includes the layer 780a, the light-emitting layer 771, and the layer 790a. The light-emitting unit 763b includes the layer 780b, the light-emitting layer 772a, the light-emitting layer 772b, the light-emitting layer 772c, and the layer 790b. The light-emitting unit 763c includes the layer 780c, the light-emitting layer 773, and the layer 790c.

As the structure illustrated in FIG. 21C, for example, a three-unit tandem structure of B\R·G·YG\B in which the light-emitting unit 763a is a light-emitting unit that emits blue (B) light, the light-emitting unit 763b is a light-emitting unit that emits red (R), green (G), and yellow green (YG) light, and the light-emitting unit 763c is a light-emitting unit that emits blue (B) light can be employed.

Examples of the number of stacked light-emitting units and the order of colors from the anode side include a two-unit structure of B and Y; a two-unit structure of B and the light-emitting unit X; a three-unit structure of B, Y, and B; and a three-unit structure of B, X, and B. Examples of the number of light-emitting layers stacked in the light-emitting unit X and the order of colors from the anode side include a two-layer structure of R and Y; a two-layer structure of R and G; a two-layer structure of G and R; a three-layer structure of G, R, and G; and a three-layer structure of R, G, and R. Another layer may be provided between two light-emitting layers.

Next, materials that can be used for the light-emitting element will be described.

A conductive film transmitting visible light is used as the electrode through which light is extracted, which is either the lower electrode 761 or the upper electrode 762. A conductive film reflecting visible light is preferably used as the electrode through which light is not extracted. In the case where a display device includes a light-emitting element emitting infrared light, it is preferable that a conductive film transmitting visible light and infrared light be used as the electrode through which light is extracted and a conductive film reflecting visible light and infrared light be used as the electrode through which light is not extracted.

A conductive film transmitting visible light may be used as the electrode through which light is not extracted. In that case, the electrode is preferably placed between a reflective layer and the EL layer 763. In other words, light emitted from the EL layer 763 may be reflected by the reflective layer to be extracted from the display device.

As a material that forms the pair of electrodes of the light-emitting element, a metal, an alloy, an electrically conductive compound, a mixture thereof, or the like can be used as appropriate. Specific examples of the material include metals such as aluminum, magnesium, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing any of these metals in appropriate combination. Other examples of the material include indium tin oxide, indium tin oxide containing silicon, indium zinc oxide, and indium zinc oxide containing tungsten. Examples of the material include an aluminum-containing alloy such as an alloy of aluminum, nickel, and lanthanum (Al—Ni—La), an alloy of silver and magnesium, and an alloy containing silver such as an alloy of silver, palladium, and copper (APC). Other examples of the material include elements belonging to Group 1 or Group 2 of the periodic table, which are not exemplified above (e.g., lithium, cesium, calcium, and strontium), rare earth metals such as europium and ytterbium, an alloy containing any of these metals in appropriate combination, and graphene.

In addition, the light-emitting element preferably also employs a microcavity structure. Therefore, one of the pair of electrodes of the light-emitting element preferably includes an electrode having properties of transmitting and reflecting visible light (a transflective electrode), and the other preferably includes an electrode having a property of reflecting visible light (a reflective electrode). When the light-emitting elements have a microcavity structure, light obtained from the light-emitting layers can be resonated between the electrodes, whereby light emitted from the light-emitting elements can be intensified.

Note that the transflective electrode can have a stacked-layer structure of a conductive layer that can be used as a reflective electrode and a conductive layer that can be used as an electrode having a property of transmitting visible light (also referred to as a transparent electrode).

The transparent electrode has a light transmittance higher than or equal to 40%. For example, an electrode having a visible light (light with wavelengths greater than or equal to 400 nm and less than 750 nm) transmittance higher than or equal to 40% is preferably used as the transparent electrode of the light-emitting element. The transflective electrode has a visible light reflectance higher than or equal to 10% and lower than or equal to 95%, preferably higher than or equal to 30% and lower than or equal to 80%. The reflective electrode has a visible light reflectance higher than or equal to 40% and lower than or equal to 100%, preferably higher than or equal to 70% and lower than or equal to 100%. These electrodes preferably have a resistivity lower than or equal to 1×10⁻² Ωcm.

The light-emitting element includes at least the light-emitting layer. The light-emitting element may further include, as a layer other than the light-emitting layer, a layer including a substance with a high hole-injection property, a substance with a high hole-transport property, a hole-blocking material, a substance with a high electron-transport property, an electron-blocking material, a substance with a high electron-injection property, a substance with a bipolar property (a substance with a high electron-transport property and a high hole-transport property), or the like. For example, the light-emitting element can include one or more of a hole-injection layer, a hole-transport layer, a hole-blocking layer, a charge-generation layer, an electron-blocking layer, an electron-transport layer, and an electron-injection layer in addition to the light-emitting layer.

Either a low molecular compound or a high molecular compound can be used in the light-emitting element, and an inorganic compound may be included. Each layer included in the light-emitting element can be formed by any of the following methods: an evaporation method (including a vacuum evaporation method), a transfer method, a printing method, an ink-jet method, a coating method, and the like.

The light-emitting layer includes one or more kinds of light-emitting substances. As the light-emitting substance, a substance exhibiting an emission color of blue, violet, bluish violet, green, yellowish green, yellow, orange, red, or the like is used as appropriate. Alternatively, as the light-emitting substance, a substance that emits near-infrared light can be used.

Examples of the light-emitting substance include a fluorescent material, a phosphorescent material, a TADF material, and a quantum dot material.

Examples of a fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of a phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton; an organometallic complex (particularly an iridium complex) having a phenylpyridine derivative including an electron-withdrawing group as a ligand; a platinum complex; and a rare earth metal complex.

The light-emitting layer may include one or more kinds of organic compounds (e.g., a host material and an assist material) in addition to the light-emitting substance (a guest material). As one or more kinds of organic compounds, one or both of a substance with a high hole-transport property (a hole-transport material) and a substance with a high electron-transport property (an electron-transport material) can be used. As the hole-transport material, it is possible to use a material having a high hole-transport property which can be used for the hole-transport layer and will be described later. As the electron-transport material, it is possible to use a material having a high electron-transport property which can be used for the electron-transport layer and will be described later. Alternatively, as one or more kinds of organic compounds, a bipolar material or a TADF material may be used.

The light-emitting layer preferably includes a phosphorescent material and a combination of a hole-transport material and an electron-transport material that easily forms an exciplex, for example. Such a structure makes it possible to efficiently obtain light emission using ExTET (Exciplex-Triplet Energy Transfer), which is energy transfer from an exciplex to a light-emitting substance (a phosphorescent material). When a combination is selected to form an exciplex that exhibits light emission whose wavelength overlaps with the wavelength of the lowest-energy-side absorption band of the light-emitting substance, energy can be transferred smoothly and light emission can be obtained efficiently. With this structure, the high efficiency, low-voltage driving, and long lifetime of the light-emitting element can be achieved at the same time.

The hole-injection layer is a layer injecting holes from the anode to the hole-transport layer, and is a layer containing a material with a high hole-injection property. Examples of the material with a high hole-injection property include an aromatic amine compound and a composite material containing a hole-transport material and an acceptor material (electron-accepting material).

As the hole-transport material, it is possible to use a material having a high hole-transport property which can be used for the hole-transport layer and will be described later.

As the acceptor material, an oxide of a metal belonging to Group 4 to Group 8 of the periodic table can be used, for example. Specific examples include molybdenum oxide, vanadium oxide, niobium oxide, tantalum oxide, chromium oxide, tungsten oxide, manganese oxide, and rhenium oxide. Among these, molybdenum oxide is particularly preferable since it is stable in the air, has a low hygroscopic property, and is easy to handle. An organic acceptor material containing fluorine can be used. An organic acceptor material such as a quinodimethane derivative, a chloranil derivative, or a hexaazatriphenylene derivative can be used.

As the material having a high hole-injection property, a material that includes a hole-transport material and the above-described oxide of a metal belonging to any of Group 4 to Group 8 of the periodic table (typically, molybdenum oxide) may be used, for example.

The hole-transport layer is a layer transporting holes injected from the anode by the hole-injection layer, to the light-emitting layer. The hole-transport layer is a layer including a hole-transport material. As the hole-transport material, a substance having a hole mobility higher than or equal to 1×10⁻⁶ cm²/Vs is preferable. Note that other substances can also be used as long as the substances have a hole-transport property higher than an electron-transport property. As the hole-transport material, a material with a high hole-transport property, such as a π-electron rich heteroaromatic compound (e.g., a carbazole derivative, a thiophene derivative, or a furan derivative) or an aromatic amine (a compound having an aromatic amine skeleton), is preferable.

The electron-blocking layer is provided in contact with the light-emitting layer. The electron-blocking layer has a hole-transport property and includes a material capable of blocking electrons. Any of the materials having an electron-blocking property among the above hole-transport materials can be used for the electron-blocking layer.

The electron-blocking layer has a hole-transport property, and thus can also be referred to as a hole-transport layer. A layer having an electron-blocking property among the hole-transport layers can also be referred to as an electron-blocking layer.

The electron-transport layer is a layer transporting electrons injected from the cathode by the electron-injection layer, to the light-emitting layer. The electron-transport layer is a layer including an electron-transport material. As the electron-transport material, a substance having an electron mobility higher than or equal to 1×10⁻⁶ cm²/Vs is preferable. Note that other substances can also be used as long as the substances have an electron-transport property higher than a hole-transport property. As the electron-transport material, any of the following materials with a high electron-transport property can be used, for example: a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, and a π-electron deficient heteroaromatic compound such as a nitrogen-containing heteroaromatic compound.

The hole-blocking layer is provided in contact with the light-emitting layer. The hole-blocking layer has an electron-transport property and includes a material capable of blocking holes. Any of the materials having a hole-blocking property among the above electron-transport materials can be used for the hole-blocking layer.

The hole-blocking layer has an electron-transport property, and thus can also be referred to as an electron-transport layer. A layer having a hole-blocking property among the electron-transport layers can also be referred to as a hole-blocking layer.

The electron-injection layer is a layer injecting electrons from the cathode to the electron-transport layer, and is a layer containing a material with a high electron-injection property. As the material with a high electron-injection property, an alkali metal, an alkaline earth metal, or a compound thereof can be used. As the material with a high electron-injection property, a composite material containing an electron-transport material and a donor material (electron-donating material) can also be used.

The difference between the LUMO level of the substance with a high electron-injection property and the work function value of the material used for the cathode is preferably small (specifically, smaller than or equal to 0.5 eV).

The electron-injection layer can be formed using, for example, an alkali metal, an alkaline earth metal, or a compound thereof, such as lithium, cesium, ytterbium, lithium fluoride (LiF), cesium fluoride (CsF), calcium fluoride (CaFₓ, where X is a given number), 8-(quinolinolato)lithium (abbreviation: Liq), 2-(2-pyridyl)phenolatolithium (abbreviation: LiPP), 2-(2-pyridyl)-3-pyridinolatolithium (abbreviation: LiPPy), 4-phenyl-2-(2-pyridyl)phenolatolithium (abbreviation: LiPPP), lithium oxide (LiOₓ), or cesium carbonate. The electron-injection layer may have a stacked-layer structure of two or more layers. The stacked-layer structure can be, for example, a structure in which lithium fluoride is used for the first layer and ytterbium is used for the second layer.

The electron-injection layer may include an electron-transport material. For example, a compound having an unshared electron pair and an electron deficient heteroaromatic ring can be used as the electron-transport material. Specifically, a compound having at least one of a pyridine ring, a diazine ring (a pyrimidine ring, a pyrazine ring, and a pyridazine ring), and a triazine ring can be used.

Note that the lowest unoccupied molecular orbital (LUMO) level of the organic compound having an unshared electron pair is preferably higher than or equal to −3.6 eV and lower than or equal to −2.3 eV. In general, the highest occupied molecular orbital (HOMO) level and the LUMO level of an organic compound can be estimated by CV (cyclic voltammetry), photoelectron spectroscopy, optical absorption spectroscopy, inverse photoelectron spectroscopy, or the like.

For example, 4,7-diphenyl-1,10-phenanthroline (abbreviation: BPhen), 2,9-di(naphthalen-2-yl)-4,7-diphenyl-1,10-phenanthroline (abbreviation: NBPhen), diquinoxalino[2,3-a:2′,3′-c]phenazine (abbreviation: HATNA), 2,4,6-tris[3′-(pyridin-3-yl)biphenyl-3-yl]-1,3,5-triazine (abbreviation: TmPPPyTz), or the like can be used for the organic compound having an unshared electron pair. Note that NBPhen has a higher glass transition point than BPhen and thus has high heat resistance.

As described above, the charge-generation layer includes at least a charge-generation region. The charge-generation region preferably contains an acceptor material, and for example, preferably contains a hole-transport material and an acceptor material which can be used for the hole-injection layer.

The charge-generation layer preferably includes a layer including a material having a high electron-injection property. The layer can also be referred to as an electron-injection buffer layer. The electron-injection buffer layer is preferably provided between the charge-generation region and the electron-transport layer. By provision of the electron-injection buffer layer, an injection barrier between the charge-generation region and the electron-transport layer can be lowered; thus, electrons generated in the charge-generation region can be easily injected into the electron-transport layer.

The electron-injection buffer layer preferably includes an alkali metal or an alkaline earth metal, and for example, can include an alkali metal compound or an alkaline earth metal compound. Specifically, the electron-injection buffer layer preferably includes an inorganic compound containing an alkali metal and oxygen or an inorganic compound containing an alkaline earth metal and oxygen, further preferably includes an inorganic compound containing lithium and oxygen (e.g., lithium oxide (Li₂O)). Alternatively, a material that can be used for the electron-injection layer can be suitably used for the electron-injection buffer layer.

The charge-generation layer preferably includes a layer including a material having a high electron-transport property. The layer can also be referred to as an electron-relay layer. The electron-relay layer is preferably provided between the charge-generation region and the electron-injection buffer layer. In the case where the charge-generation layer does not include an electron-injection buffer layer, the electron-relay layer is preferably provided between the charge-generation region and the electron-transport layer. The electron-relay layer has a function of preventing interaction between the charge-generation region and the electron-injection buffer layer (or the electron-transport layer) and smoothly transferring electrons.

A phthalocyanine-based material such as copper(II) phthalocyanine (abbreviation: CuPc) or a metal complex having a metal-oxygen bond and an aromatic ligand is preferably used for the electron-relay layer.

Note that the charge-generation region, the electron-injection buffer layer, and the electron-relay layer cannot be clearly distinguished from each other in some cases on the basis of the cross-sectional shapes or the characteristics, for example.

Note that the charge-generation layer may include a donor material instead of an acceptor material. For example, the charge-generation layer may include a layer including an electron-transport material and a donor material, which can be used for the electron-injection layer.

When the light-emitting units are stacked, provision of a charge-generation layer between two light-emitting units can inhibit an increase in driving voltage.

This embodiment can be combined with the other embodiments or an example as appropriate.

### Embodiment 5

In this embodiment, electronic devices of one embodiment of the present invention will be described with reference to drawings.

Electronic devices of this embodiment each include the display device of one embodiment of the present invention in a display portion. The display device of one embodiment of the present invention has high display quality and can be easily increased in resolution and definition. Thus, the display device of one embodiment of the present invention can be used for a display portion of a variety of electronic devices.

Examples of the electronic devices include electronic devices with a relatively large screen, such as a television device, a desktop or notebook personal computer, a monitor of a computer or the like, digital signage, and a large game machine such as a pachinko machine; a digital camera; a digital video camera; a digital photo frame; a mobile phone; a portable game console; a portable information terminal; and an audio reproducing device.

The definition of the display device of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), 8K (number of pixels: 7680×4320), or the like. In particular, a definition of 4K, 8K, or higher is preferable. There is no particular limitation on the screen ratio (aspect ratio) of the display device of one embodiment of the present invention. For example, the display device is compatible with a variety of screen ratios such as 1:1 (a square), 4:3, 16:9, and 16:10.

The electronic device in this embodiment may include a sensor (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device in this embodiment can have a variety of functions. For example, the electronic device of this embodiment can have a function of displaying a variety of data (a still image, a moving image, a text image, and the like) on the display portion, a touch panel function, a function of displaying a calendar, date, time, and the like, a function of executing a variety of software (programs), a wireless communication function, and a function of reading out a program or data stored in a storage medium.

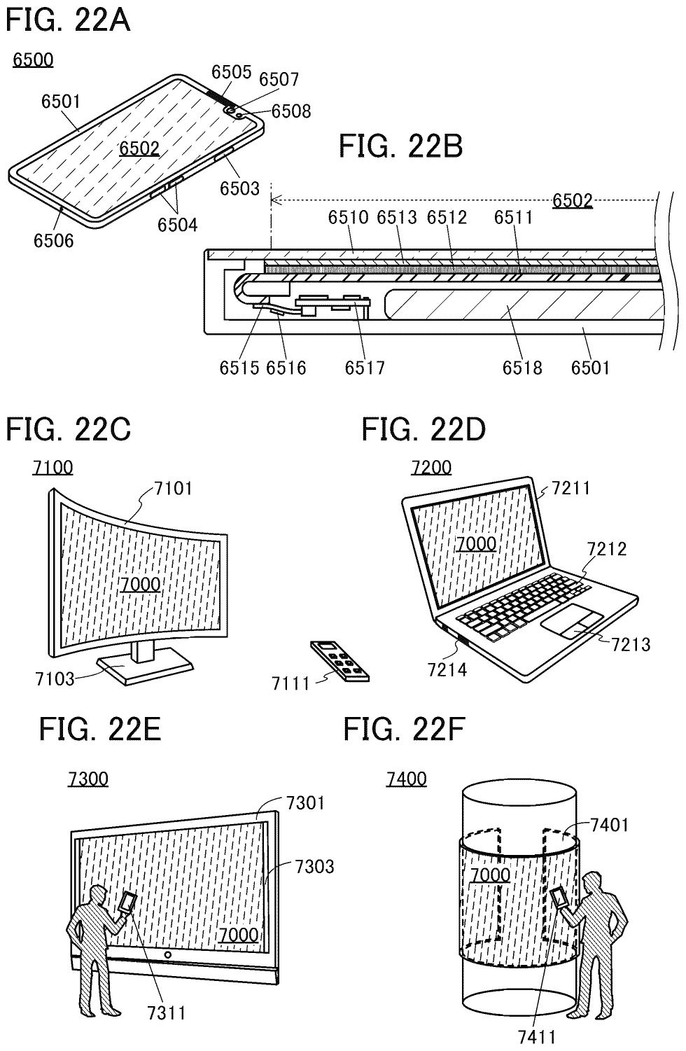

An electronic device 6500 illustrated in FIG. 22A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display device of one embodiment of the present invention can be used in the display portion 6502. Thus, an image with high display quality can be displayed on the display portion 6502.

FIG. 22B is a schematic cross-sectional view including an end portion of the housing 6501 on the microphone 6506 side.

A protection member 6510 having a light-transmitting property is provided on a display surface side of the housing 6501, and a display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be used as the display panel 6511. Thus, an extremely lightweight electronic device can be achieved. In addition, since the display panel 6511 is extremely thin, the battery 6518 with high capacity can be mounted while the thickness of the electronic device is reduced. Moreover, part of the display panel 6511 is folded back so that a connection portion with the FPC 6515 is provided on the back side of a pixel portion, so that an electronic device with a narrow bezel can be achieved.

FIG. 22C illustrates an example of a television device. In a television device 7100, a display portion 7000 is incorporated in a housing 7101. Here, the housing 7101 is supported by a stand 7103.

Operations of the television device 7100 illustrated in FIG. 22C can be performed with an operation switch provided in the housing 7101 and a separate remote controller 7111. Alternatively, the display portion 7000 may be provided with a touch sensor, and the television device 7100 may be operated by touch on the display portion 7000 with, for example, a finger. The remote controller 7111 may be provided with a display portion for displaying information output from the remote controller 7111. With operation keys or a touch panel provided in the remote controller 7111, channels and volume can be controlled and videos displayed on the display portion 7000 can be operated.

Note that the television device 7100 has a structure in which a receiver, a modem, and the like are provided. A general television broadcast can be received with the receiver. When the television device is connected to a communication network by wire or wirelessly via the modem, one-way (from a transmitter to a receiver) or two-way (between a transmitter and a receiver or between receivers, for example) data communication can be performed.

FIG. 22D illustrates an example of a laptop personal computer. A laptop personal computer 7200 includes a housing 7211, a keyboard 7212, a pointing device 7213, an external connection port 7214, and the like. In the housing 7211, the display portion 7000 is incorporated.

FIG. 22E and FIG. 22F illustrate examples of digital signage.

Digital signage 7300 illustrated in FIG. 22E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 22F is digital signage 7400 attached to a cylindrical pillar 7401. The digital signage 7400 includes the display portion 7000 provided along a curved surface of the pillar 7401.

The display device of one embodiment of the present invention can be employed for the display portion 7000 illustrated in each of FIG. 22C to FIG. 22F. Thus, the display portion 7000 can display a high-quality image.

A larger area of the display portion 7000 can increase the amount of information that can be provided at a time. The larger the display portion 7000 attracts more attention, so that the effectiveness of the advertisement can be increased, for example.

The use of a touch panel in the display portion 7000 is preferable because in addition to display of a still image or a moving image on the display portion 7000, intuitive operation by a user is possible. Moreover, for an application for providing information such as route information or traffic information, usability can be enhanced by intuitive operation.

In addition, as illustrated in FIG. 22E and FIG. 22F, it is preferable that the digital signage 7300 or the digital signage 7400 can work with an information terminal 7311 or an information terminal 7411 such as a user's smartphone through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

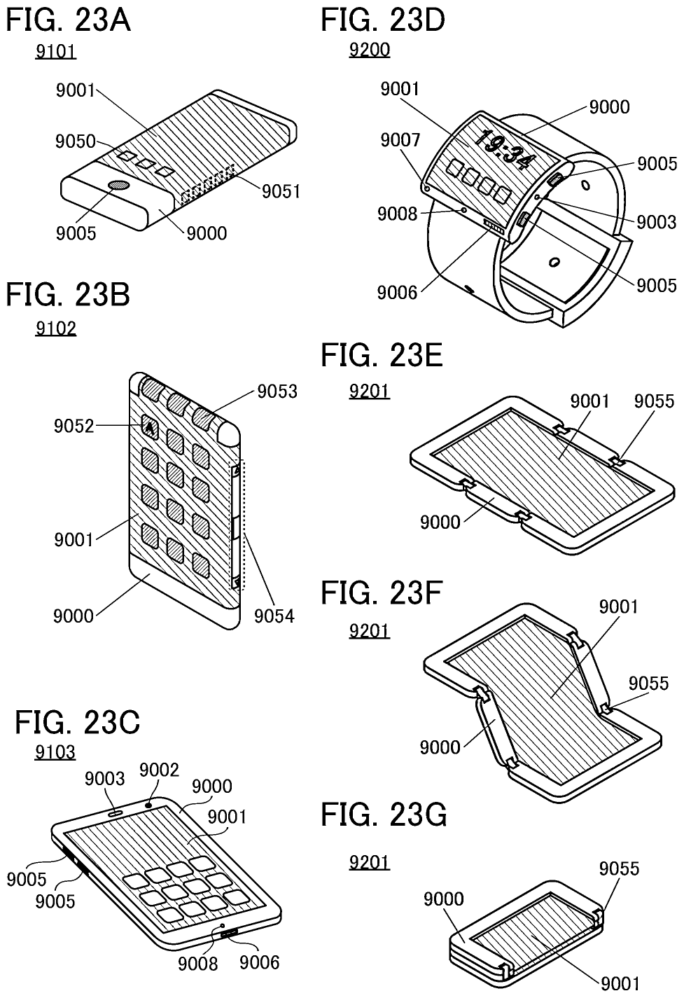

Electronic devices illustrated in FIG. 23A to FIG. 23G include a housing 9000, a display portion 9001, a speaker 9003, an operation key 9005 (including a power switch or an operation switch), a connection terminal 9006, a sensor 9007 (a sensor having a function of measuring force, displacement, a position, speed, acceleration, angular velocity, rotational frequency, distance, light, liquid, magnetism, temperature, a chemical substance, sound, time, hardness, an electric field, current, voltage, power, radiation, flow rate, humidity, a gradient, oscillation, an odor, or infrared rays), a microphone 9008, and the like.

The display device of one embodiment of the present invention can be used for the display portion 9001 in FIG. 23A to FIG. 23G. Thus, a high-quality image can be displayed on the display portion 9001.

The electronic devices illustrated in FIG. 23A to FIG. 23G have a variety of functions. For example, the electronic devices can have a function of displaying a variety of information (a still image, a moving image, a text image, and the like) on the display portion, a touch panel function, a function of displaying a calendar, date, time, and the like, a function of controlling processing with a variety of software (programs), a wireless communication function, and a function of reading out and processing a program or data stored in a storage medium. Note that the functions of the electronic devices are not limited thereto, and the electronic devices can have a variety of functions. The electronic devices may include a plurality of display portions. In addition, the electronic device may be provided with, for example, a camera. In this case, the electronic device may have a function of taking a still image or a moving image and storing the taken image in a storage medium, a function of displaying the taken image on the display portion, or the like. Note that the storage medium may be provided outside the electronic device, for example, or incorporated in the camera.

The electronic devices illustrated in FIG. 23A to FIG. 23G are described in detail below.

FIG. 23A is a perspective view illustrating a portable information terminal 9101. The portable information terminal 9101 can be used as a smartphone, for example. Note that the portable information terminal 9101 may be provided with the speaker 9003, the connection terminal 9006, the sensor 9007, or the like. The portable information terminal 9101 can display characters and image information on its plurality of surfaces. FIG. 23A illustrates an example in which three icons 9050 are displayed. Furthermore, information 9051 indicated by dashed rectangles can be displayed on another surface of the display portion 9001. Examples of the information 9051 include notification of reception of an e-mail, an SNS message, an incoming call, or the like, the title and sender of an e-mail, an SNS message, or the like, the date, the time, remaining battery, and the radio field intensity. Alternatively, for example, the icon 9050 may be displayed at the position where the information 9051 is displayed.

FIG. 23B is a perspective view illustrating a portable information terminal 9102. The portable information terminal 9102 has a function of displaying information on three or more surfaces of the display portion 9001. Here, an example in which information 9052, information 9053, and information 9054 are displayed on different surfaces is illustrated. For example, a user can check the information 9053 displayed in a position that can be observed from above the portable information terminal 9102, with the portable information terminal 9102 put in a breast pocket of his/her clothes. The user can see the display without taking out the portable information terminal 9102 from the pocket and decide whether to answer the call, for example.

FIG. 23C is a perspective view illustrating a tablet terminal 9103. The tablet terminal 9103 is capable of executing a variety of applications such as mobile phone calls, e-mailing, viewing and editing texts, music reproduction, Internet communication, and a computer game, for example. The tablet terminal 9103 includes the display portion 9001, a camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 23D is a perspective view illustrating a wristwatch-type portable information terminal 9200. For example, the portable information terminal 9200 can be used as a Smartwatch (registered trademark). The display surface of the display portion 9001 is curved, and display can be performed on the curved display surface. Furthermore, for example, mutual communication between the portable information terminal 9200 and a headset capable of wireless communication can be performed, and thus hands-free calling is possible. With the connection terminal 9006, the portable information terminal 9200 can perform mutual data transmission with another information terminal and can be charged. Note that the charging operation may be performed by wireless power feeding.

FIG. 23E to FIG. 23G are perspective views illustrating a foldable portable information terminal 9201. FIG. 23E is a perspective view of an opened state of the portable information terminal 9201, FIG. 23G is a perspective view of a folded state thereof, and FIG. 23F is a perspective view of a state in the middle of change from one of FIG. 23E and FIG. 23G to the other. The portable information terminal 9201 is highly portable in the folded state and is highly browsable in the opened state because of a seamless large display region. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

This embodiment can be combined with the other embodiments or an example as appropriate.

### EXAMPLE

In this example, the result of fabricating a sample including the light-emitting element described in Embodiment 1 will be described.

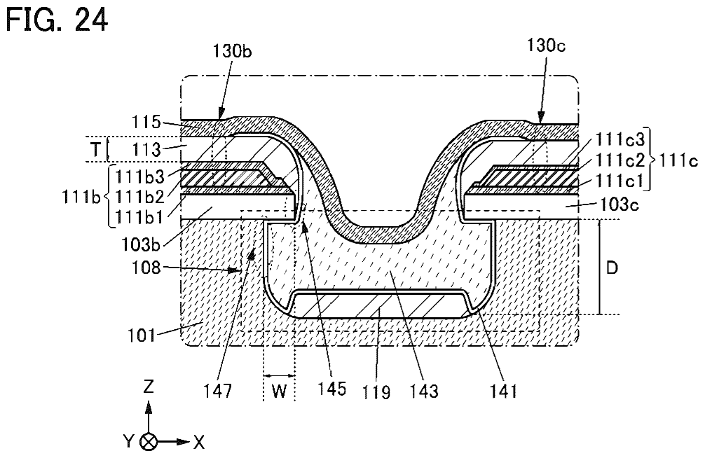

FIG. 24 is a cross-sectional view illustrating a structure of the sample fabricated in this example. FIG. 24 illustrates the light-emitting element 130b, the light-emitting element 130c, and a surrounding region thereof. Although not illustrated in FIG. 24, the light-emitting element 130a was also fabricated.

The structure illustrated in FIG. 24 is a structure in which the common layer 114, the protective layer 131, and the protective layer 135 are removed from the structure in FIG. 4A. The pixel electrode 111 has the structure illustrated in FIG. 5B, and the light-emitting element 130 employs a microcavity structure. Here, the pixel electrode 111c includes a pixel electrode 111c1, a pixel electrode 111c2 over the pixel electrode 111c1, and a pixel electrode 111c3 over the pixel electrode 111c1 and the pixel electrode 111c2. That is, the pixel electrode 111c2 is covered with the pixel electrode 111c1 and the pixel electrode 111c3. The microcavity structure was employed in the light-emitting element 130 to provide a structure where the light-emitting element 130b illustrated in FIG. 24 emits green-enhanced light and the light-emitting element 130c emits blue-enhanced light.

An acrylic resin was used as the insulating layer 101. The insulating layer 103 was formed to have a stacked-layer structure of a layer using silicon nitride and a layer using silicon oxynitride over the layer. ITSO was used as the pixel electrode 111b1, the pixel electrode 111c1, and the like. APC was used as the pixel electrode 111b2, the pixel electrode 111c2, and the like. ITSO was used as the pixel electrode 111b3, the pixel electrode 111c3, and the like.

The EL layer 113 was formed to have a structure including a first light-emitting unit, a charge-generation layer over the first light-emitting unit, and a second light-emitting unit over the charge-generation layer. The first light-emitting unit was formed to have a structure including a hole-injection layer, a hole-transport layer over the hole-injection layer, a light-emitting layer emitting blue light over the hole-transport layer, and an electron-transport layer over the light-emitting layer emitting blue light. The second light-emitting unit was formed to have a structure including a hole-transport layer, a light-emitting layer emitting green light over the hole-transport layer, a light-emitting layer emitting red light over the light-emitting layer emitting green light, an electron-transport layer over the light-emitting layer emitting red light, and an electron-injection layer over the electron-transport layer.

The common electrode 115 was formed to have a stacked-layer structure of a layer formed using an alloy of silver and magnesium and a layer formed using IGZO over the layer. As the insulating layer 141, aluminum oxide was used. As the insulating layer 143, a positive photoresist was used.

For fabrication of the sample, first, the insulating layer 101 using an acrylic resin was formed over a substrate (not illustrated) by a spin coating method. Next, a film to be the insulating layer 103 in which a silicon nitride film and a silicon oxynitride film were stacked was deposited over the insulating layer 101 by a CVD method. Here, the target thickness of the silicon nitride film was 10 nm and the target thickness of the silicon oxynitride film was 200 nm.

Next, a film to be the pixel electrode 111b1, the pixel electrode 111c1, and the like was deposited using ITSO over the film to be the insulating layer 103 by a sputtering method to have a thickness of 40 nm. Then, a film to be the pixel electrode 111b2, the pixel electrode 111c2, and the like was deposited using APC over the film to be the pixel electrode 111b1, the pixel electrode 111c1, and the like by a sputtering method to have a thickness of 100 nm.

Next, a resist mask was formed over the film to be the pixel electrode 111b2, the pixel electrode 111c2, and the like. Next, the film to be the pixel electrode 111b2, the pixel electrode 111c2, and the like was processed by a wet etching method with the resist mask, whereby the pixel electrode 111b2, the pixel electrode 111c2, and the like were formed. Then, the resist mask was removed.

Next, a step including deposition of an ITSO film by a sputtering method, formation of a resist mask, processing by a wet etching method, and a removal of the resist mask was performed three times, so that the pixel electrode 111a1, the pixel electrode 111b1, the pixel electrode 111c1, the pixel electrode 111a3, the pixel electrode 111b3, and the pixel electrode 111c3 were formed. Note that the pixel electrode 111a1 and the pixel electrode 111a3 are not illustrated in FIG. 24. In this step, the target thickness of the ITSO film was set so that the thickness of the pixel electrode 111a3 was 108 nm, the thickness of the pixel electrode 111b3 was 50 nm, and the thickness of the pixel electrode 111c3 was 11 nm. Through the above steps, the pixel electrode 111 was formed.

Next, a resist mask was formed over the pixel electrode 111a, the pixel electrode 111b, the pixel electrode 111c, and a film to be the insulating layer 103b, the insulating layer 103c, and the like. Next, the film to be the insulating layer 103b, the insulating layer 103c, and the like was processed by a dry etching method with the resist mask, whereby the insulating layer 103 was formed. Then, the insulating layer 101 was processed by ashing using oxygen plasma, whereby the depressed portion 108 was formed. Next, the resist mask was removed by a wet etching method.

Next, the EL layer 113 was formed to a thickness of 180.9 nm by a vacuum evaporation method. Specifically, the EL layer 113 was formed so that the thickness of the first light-emitting unit was 75.2 nm, the thickness of the charge-generation layer was 14.7 nm, and the thickness of the second light-emitting unit was 91.0 nm. A fine metal mask was not used to form the EL layer 113.

Next, a film to be the insulating layer 141 was deposited using aluminum oxide over the EL layer 113 and the insulating layer 101 by an ALD method to have a thickness of 30 nm. Next, a film to be the insulating layer 143 was deposited using positive photoresist over the film to be the insulating layer 141 by a spin coating method. Next, exposure and development were performed on the film to be the insulating layer 143, whereby the insulating layer 143 was formed. Then, wet etching was performed using the insulating layer 143 as a mask to form the insulating layer 141. Next, over the EL layer 113, the insulating layer 141, and the insulating layer 143, the common electrode 115 was deposited by a sputtering method to have a stacked-layer structure of a layer formed using an alloy of silver and magnesium and a layer formed using IGZO over the layer. Here, the target thickness of the layer formed using an alloy of silver and magnesium was 15 nm, and the target thickness of the layer formed using IGZO was 70 nm. Through the above steps, the sample including the light-emitting element 130 was fabricated.

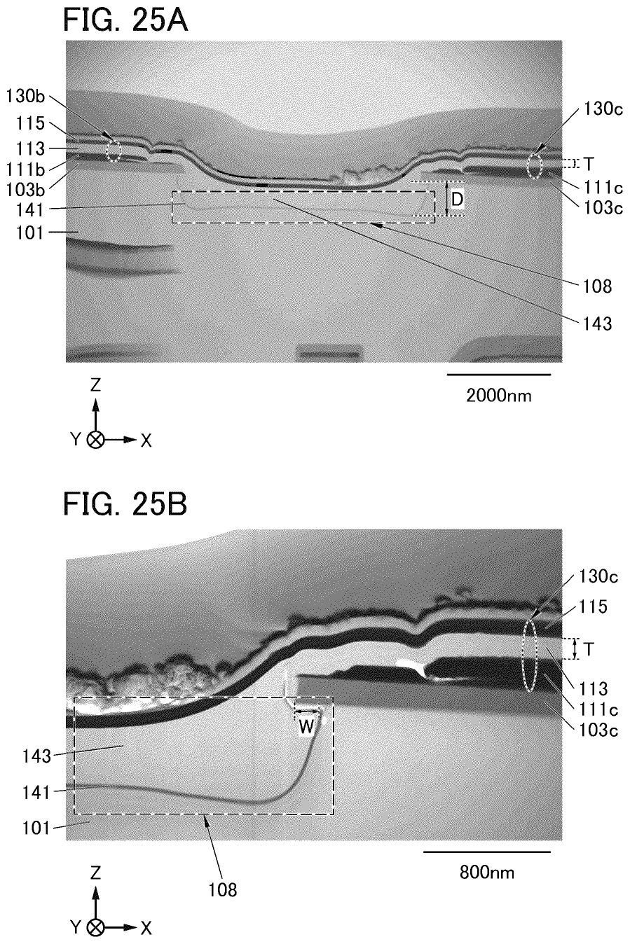

FIG. 25A and FIG. 25B are STEM images of the sample fabricated in this example. FIG. 25B is an enlarged image of the light-emitting element 130c and its surrounding region shown in FIG. 25A.

As shown in FIG. 25A and FIG. 25B, it was confirmed that the depressed portion 108 was formed in the insulating layer 101, and each of the insulating layer 103b and the insulating layer 103c was provided with a projecting portion overlapping with the depressed portion 108. In addition, it was confirmed that the EL layer 113 was divided between the light-emitting element 130b and the light-emitting element 130c as long as at least the ratio of the width W of the projecting portion of the insulating layer 103 to the thickness T of the EL layer 113 (W/T) in the cross section along the XZ plane was greater than or equal to 1.20 and the ratio of the depth D of the depressed portion 108 to the thickness T of the EL layer 113 (D/T) in the cross section along the XZ plane was greater than or equal to 4.10. Moreover, it was confirmed that the EL layer 113 was divided between the light-emitting element 130b and the light-emitting element 130c when the width W of the projecting portion of the insulating layer 103 in the cross section along the XZ plane was greater than or equal to 700 nm and the depth D of the depressed portion 108 in the cross section along the XZ plane was greater than or equal to 200 nm.

This embodiment can be combined with the other embodiments or an example as appropriate.

### REFERENCE NUMERALS

100A: display device, 100B: display device, 100: display device, 101: insulating layer, 102: substrate, 103a: insulating layer, 103b: insulating layer, 103c: insulating layer, 103f: insulating film, 103: insulating layer, 105: insulating layer, 107: region, 108: depressed portion, 109: pixel, 110a: subpixel, 110b: subpixel, 110c: subpixel, 110d: subpixel, 110e: subpixel, 110: subpixel, 111a: pixel electrode, 111b: pixel electrode, 111c: pixel electrode, 111f: conductive film, 111: pixel electrode, 112a: conductive layer, 112b: conductive layer, 112c: conductive layer, 112: conductive layer, 113: EL layer, 114: common layer, 115: common electrode, 117: light-blocking layer, 119: organic layer, 120: substrate, 122: adhesive layer, 123: conductive layer, 124a: pixel, 124b: pixel, 126a: conductive layer, 126b: conductive layer, 126c: conductive layer, 126: conductive layer, 128: layer, 130a: light-emitting element, 130b: light-emitting element, 130c: light-emitting element, 130: light-emitting element, 131: protective layer, 132a: coloring layer, 132b: coloring layer, 132c: coloring layer, 132: coloring layer, 133: lens array, 134: insulating layer, 135: protective layer, 140: connection portion, 141f: insulating film, 141: insulating layer, 143f: insulating film, 143: insulating layer, 145: end portion, 147: end portion, 153: insulating layer, 162: display portion, 164: circuit, 165: wiring, 166: conductive layer, 172: FPC, 173: IC, 191: resist mask, 193: mask, 195: light, 201: transistor, 204: connection portion, 205: transistor, 209: transistor, 210: transistor, 211: insulating layer, 213: insulating layer, 215: insulating layer, 218: insulating layer, 221: conductive layer, 222a: conductive layer, 222b: conductive layer, 223: conductive layer, 225: insulating layer, 231i: channel formation region, 231n: low-resistance region, 231: semiconductor layer, 242: connection layer, 761: lower electrode, 762: upper electrode, 763a: light-emitting unit, 763b: light-emitting unit, 763c: light-emitting unit, 763: EL layer, 764: layer, 771a: light-emitting layer, 771b: light-emitting layer, 771c: light-emitting layer, 771: light-emitting layer, 772a: light-emitting layer, 772b: light-emitting layer, 772c: light-emitting layer, 772: light-emitting layer, 773: light-emitting layer, 780a: layer, 780b: layer, 780c: layer, 780: layer, 781: layer, 782: layer, 785: charge-generation layer, 790a: layer, 790b: layer, 790c: layer, 790: layer, 791: layer, 792: layer, 6500: electronic device, 6501: housing, 6502: display portion, 6503: power button, 6504: button, 6505: speaker, 6506: microphone, 6507: camera, 6508: light source, 6510: protection member, 6511: display panel, 6512: optical member, 6513: touch sensor panel, 6515: FPC, 6516: IC, 6517: printed circuit board, 6518: battery, 7000: display portion, 7100: television device, 7101: housing, 7103: stand, 7111: remote controller, 7200: laptop personal computer, 7211: housing, 7212: keyboard, 7213: pointing device, 7214: external connection port, 7300: digital signage, 7301: housing, 7303: speaker, 7311: information terminal device, 7400: digital signage, 7401: pillar, 7411: information terminal device, 9000: housing, 9001: display portion, 9002: camera, 9003: speaker, 9005: operation key, 9006: connection terminal, 9007: sensor, 9008: microphone, 9050: icon, 9051: information, 9052: information, 9053: information, 9054: information, 9055: hinge, 9101: portable information terminal, 9102: portable information terminal, 9103: tablet terminal, 9200: portable information terminal, 9201: portable information terminal

1. A display device comprising:
a first organic insulating layer;
a first inorganic insulating layer and a second inorganic insulating layer over the first organic insulating layer;
a first light-emitting element;
a second light-emitting element; and
a second organic insulating layer,
wherein the first light-emitting element comprises a first pixel electrode over the first inorganic insulating layer, a first EL layer over the first pixel electrode, and a common electrode over the first EL layer,
wherein the second light-emitting element comprises a second pixel electrode over the second inorganic insulating layer, a second EL layer over the second pixel electrode, and the common electrode over the second EL layer,
wherein the second organic insulating layer is between the first EL layer and the second EL layer,
wherein the common electrode is over the second organic insulating layer,
wherein the first organic insulating layer comprises a depressed portion in a region overlapping with the second organic insulating layer,
wherein the first inorganic insulating layer comprises a first projecting portion overlapping with the depressed portion, and
wherein the second inorganic insulating layer comprises a second projecting portion overlapping with the depressed portion.

2. The display device according to claim 1,
wherein a ratio of a width of the first projecting portion to a thickness of the first EL layer is greater than or equal to 0.3, and
wherein a ratio of a width of the second projecting portion to a thickness of the second EL layer is greater than or equal to 0.3.

3. The display device according to claim 1,
wherein the first EL layer comprises a same material as the second EL layer, and
wherein the first EL layer is separated from the second EL layer.

4. The display device according to claim 1, further comprising an organic layer,
wherein the organic layer is in the depressed portion, and
wherein the second organic insulating layer is over the organic layer.

5. The display device according to claim 4,
wherein the organic layer is separated from the first EL layer and the second EL layer.

6. The display device according to claim 1,
wherein the first EL layer is configured to cover at least a part of a side surface of the first pixel electrode, and
wherein the second EL layer is configured to cover at least a part of a side surface of the second pixel electrode.

7. The display device according to claim 1, further comprising a third inorganic insulating layer,
wherein the third inorganic insulating layer is between the second organic insulating layer and the first organic insulating layer, the first EL layer, and the second EL layer.

8. The display device according to claim 1, further comprising a common layer,
wherein the common layer is between the common electrode and the first EL layer, the second EL layer, and the second organic insulating layer.

9. The display device according to claim 1, further comprising:
a first coloring layer; and
a second coloring layer,
wherein the first coloring layer comprises a region overlapping with the first light-emitting element,
wherein the second coloring layer comprises a region overlapping with the second light-emitting element, and
wherein a color of light transmitted through the first coloring layer is different from a color of light transmitted through the second coloring layer.

10. A method for manufacturing a display device comprising:
forming a first organic insulating layer;
forming an inorganic insulating film over the first organic insulating layer;
forming a conductive film over the inorganic insulating film;
removing a part of the conductive film, so that a first pixel electrode and a second pixel electrode are formed;
removing a part of the inorganic insulating film, so that a first inorganic insulating layer below the first pixel electrode and a second inorganic insulating layer below the second pixel electrode are formed;
forming a depressed portion in a region which is of the first organic insulating layer and is between the first inorganic insulating layer and the second inorganic insulating layer in a plan view, so that a first projecting portion overlapping with the depressed portion is formed in the first inorganic insulating layer and a second projecting portion overlapping with the depressed portion is formed in the second inorganic insulating layer;
forming a first EL layer over the first pixel electrode and a second EL layer over the second pixel electrode;
forming a second organic insulating layer between the first EL layer and the second EL layer to have a region overlapping with the depressed portion; and
forming a common electrode over the first EL layer, the second EL layer, and the second organic insulating layer.

11. The method for manufacturing a display device according to claim 10,
wherein a ratio of a width of the first projecting portion to a thickness of the first EL layer is greater than or equal to 0.3, and
wherein a ratio of a width of the second projecting portion to a thickness of the second EL layer is greater than or equal to 0.3.

12. The method for manufacturing a display device according to claim 10,
wherein the second EL layer is separated from the first EL layer, and
wherein the second EL layer comprises a same material as the first EL layer.

13. The method for manufacturing a display device according to claim 10,
wherein an organic layer is formed in the depressed portion at the time of forming the first EL layer and the second EL layer, and
wherein the second organic insulating layer is formed over the organic layer.

14. The method for manufacturing a display device according to claim 13,
wherein the organic layer is separated from the first EL layer and the second EL layer.

15. The method for manufacturing a display device according to claim 10,
wherein the depressed portion is formed by ashing.

16. The method for manufacturing a display device according to claim 10,
wherein the second organic insulating layer is formed by a photolithography method.

17. The method for manufacturing a display device according to claim 10,
wherein the first EL layer is configured to cover at least a part of a side surface of the first pixel electrode, and
wherein the second EL layer is configured to cover at least a part of a side surface of the second pixel electrode.

18. The method for manufacturing a display device according to claim 10, further comprising:
forming a common layer over the first EL layer, the second EL layer, and the second organic insulating layer after the second organic insulating layer is formed,
wherein the common electrode is over the common layer.

19. The method for manufacturing a display device according to claim 10, further comprising:
forming a first coloring layer comprising a region overlapping with the first pixel electrode and the first EL layer and a second coloring layer comprising a region overlapping with the second pixel electrode and the second EL layer after the common electrode is formed,
wherein a color of light transmitted through the first coloring layer is different from a color of light transmitted through the second coloring layer.
